(19) United States
(12) Patent Application Publication
(10) Pub. No.: US 2023/0324801 A1
(43) Pub. Date: Oct. 12, 2023

(54) UNDERLAYER FILM FORMING COMPOSITION FOR LITHOGRAPHY, UNDERLAYER FILM, AND PATTERN FORMATION METHOD

(71) Applicant: Mitsubishi Gas Chemical Company, Inc., Tokyo (JP)

(72) Inventors: Hiroaki YAMAMOTO, Hiratsuka-shi, Kanagawa (JP); Atsuko IWASAKI, Hiratsuka-shi, Kanagawa (JP); Takashi MAKINOSHIMA, Hiratsuka-shi, Kanagawa (JP); Masatoshi ECHIGO, Tokyo (JP)

(21) Appl. No.: 18/021,160

(22) PCT Filed: Aug. 3, 2021
(86) PCT No.: PCT/JP2021/028785

§ 371 Date: Feb. 13, 2023

(30) Foreign Application Priority Data
Aug. 14, 2020 (JP) 2020-137095
Dec. 10, 2020 (JP) 2020-204846
Dec. 10, 2020 (JP) 2020-204895

(51) Int. Cl. G03F 7/11; C08G 8/10; C08G 8/32; C08G 12/08; C08G 12/40; H01L 21/027; G03F 7/16

(52) U.S. Cl. CPC G03F 7/11; C08G 8/10; C08G 8/32; C08G 12/08; C08G 12/40; H01L 21/0274; G03F 7/162

(57) ABSTRACT

An object of the present invention is to provide a resist underlayer film forming composition for lithography that has features of having excellent smoothing performance on an uneven substrate, good embedding performance into a fine hole pattern, and a smoothed wafer surface after film formation, and the like. The object can be achieved by an underlayer film forming composition for lithography containing a compound having a protecting group.

### TECHNICAL FIELD

The present invention relates to an underlayer film forming composition for lithography, an underlayer film, and a pattern formation method.

### BACKGROUND ART

In the production of semiconductor devices, fine processing is practiced by lithography using photoresist materials. In recent years, further miniaturization based on pattern rules has been demanded along with increase in the integration and speed of LSI (large scale integrated circuits). The light source for lithography used upon forming resist patterns has been shifted to ArF excimer laser (193 nm) having a shorter wavelength from KrF excimer laser (248 nm). The introduction of extreme ultraviolet (EUV, 13.5 nm) is also expected.

However, when the miniaturization of resist patterns proceeds, the problem of resolution or the problem of collapse of resist patterns after development arises. Therefore, resists have been desired to have a thinner film. However, if resists merely have a thinner film, it is difficult to obtain the film thicknesses of resist patterns sufficient for substrate processing. Therefore, there has been a need for a process of preparing a resist underlayer film between a resist and a semiconductor substrate to be processed, and imparting functions as a mask for substrate processing to this resist underlayer film in addition to a resist pattern.

Various resist underlayer films for such a process are currently known. For example, in order to achieve a resist underlayer film for lithography having the selectivity of a dry etching rate smaller than that of resists, a resist underlayer film material comprising a polymer having a specific repeat unit has been suggested (see Patent Literature 1). Furthermore, as a material for realizing resist underlayer films for lithography having the selectivity of a dry etching rate smaller than that of semiconductor substrates, a resist underlayer film material comprising a polymer prepared by copolymerizing a repeat unit of an acenaphthylene and a repeat unit having a substituted or unsubstituted hydroxy group has been suggested (see Patent Literature 2).

Meanwhile, as materials having high etching resistance for this kind of resist underlayer film, amorphous carbon underlayer films formed by chemical vapour deposition (CVD) using methane gas, ethane gas, acetylene gas, or the like as a raw material are well known. However, resist underlayer film materials that can form resist underlayer films by a wet process such as spin coating or screen printing have been demanded from the viewpoint of a process.

The present inventors have also proposed an underlayer film forming composition for lithography containing a compound having a specific structure and an organic solvent (see Patent Literature 3) as a material that is excellent in etching resistance, has high heat resistance, and is soluble in a solvent and applicable to a wet process.

### CITATION LIST

### Patent Literature

Patent Literature 1: Japanese Patent Laid-Open No. 2004-271838
Patent Literature 2: Japanese Patent Laid-Open No. 2005-250434
Patent Literature 3: International Publication No. WO 2013/024779

### SUMMARY OF INVENTION

### Technical Problem

However, an underlayer film forming composition for lithography has been required which has high levels of solubility in organic solvents, etching resistance, and resist pattern formability as an underlayer film forming composition at the same time, and further has a feature of having a smoothed wafer surface after film formation.

Therefore, an object of the present invention is to provide a resist underlayer film forming composition for lithography that has features of having excellent smoothing performance on an uneven substrate, good embedding performance into a fine hole pattern, and a smoothed wafer surface after film formation, and the like.

### Solution to Problem

The inventors have, as a result of devoted examinations to solve the problems described above, found out that a specific underlayer film forming composition is useful, and reached the present invention.

That is, the present invention provides the following various embodiments.

[1]

An underlayer film forming composition for lithography comprising a compound having a protecting group.

[2]

The underlayer film forming composition for lithography according to [1], wherein the compound comprises one or more selected from the group consisting of a polyphenol, an aniline-based compound, and a resin.

[3]

The underlayer film forming composition for lithography according to [1] or [2], wherein the compound comprises a compound and/or resin represented by the following formula (1):

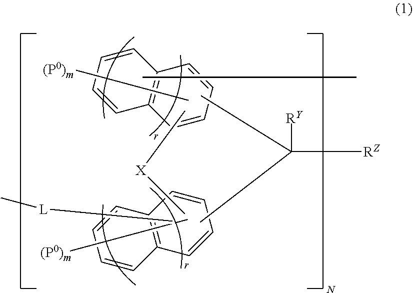

wherein
each R^{Y} is independently a hydrogen atom, a linear, branched, or cyclic alkyl group having 1 to 30 carbon atoms, or an aryl group having 6 to 30 carbon atoms;
R^{Z} is an N-valent group having 1 to 60 carbon atoms or a single bond;
each P⁰ is independently selected from the group consisting of a halogen atom, a nitro group, an alkyl group having 1 to 30 carbon atoms, an alkenyl group having 2 to 30 carbon atoms, an alkynyl group having 2 to 30 carbon atoms, an aryl group having 6 to 40 carbon atoms, a hydroxyl group, an amino group, a group obtained by replacing a hydrogen atom of a hydroxyl group with a protecting group, a group obtained by replacing a hydrogen atom of an amino group with a protecting group, and a functional group of a combination thereof, wherein at least one P⁰ is a group obtained by replacing a hydrogen atom of a hydroxyl group with a protecting group or a group obtained by replacing a hydrogen atom of an amino group with a protecting group, and the protecting group is optionally an eliminatable protecting group;
each X independently represents an oxygen atom or a sulfur atom, or not a crosslink;
L is a single bond, a linear or branched alkylene group having 1 to 30 carbon atoms and optionally having a substituent, or not a crosslink;
each m is independently an integer of 0 to 9, wherein at least one m is an integer of 1 to 9;
N is an integer of 1 to 4; and
each r is independently an integer of 0 to 2.
   [4]

The underlayer film forming composition for lithography according to any one of [1] to [3], wherein the compound comprises a compound and/or resin represented by the following formula (2):

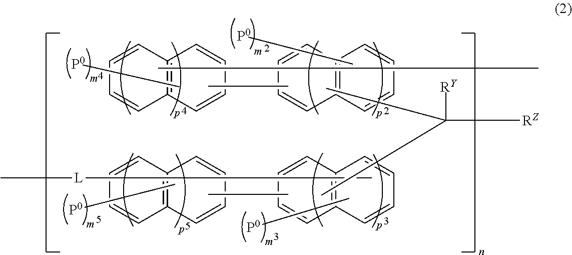

wherein
R^{Y}, R^{Z}, P⁰, and L are synonymous with the definition in the formula (1);
m² and m³ are each independently an integer of 0 to 8, and m⁴ and m⁵ are each independently an integer of 0 to 9, provided that m², m³, m⁴, and m⁵ are not 0 at the same time;
n is as defined in N in the formula (1), wherein when n is an integer of 2 or larger, structural formulas within n parentheses [ ] are the same or different; and
p² to p⁵ are as defined in r in the formula (1).
   [5]

The underlayer film forming composition for lithography according to [1], wherein the compound comprises a compound and/or resin represented by the following formula (3):

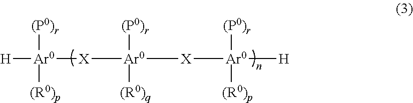

wherein
each P⁰ is independently selected from the group consisting of a halogen atom, a nitro group, an alkyl group having 1 to 30 carbon atoms, an alkenyl group having 2 to 30 carbon atoms, an alkynyl group having 2 to 30 carbon atoms, an aryl group having 6 to 40 carbon atoms, a hydroxyl group, an amino group, a group obtained by replacing a hydrogen atom of a hydroxyl group with a protecting group, a group obtained by replacing a hydrogen atom of an amino group with a protecting group, and a functional group of a combination thereof, wherein at least one P⁰ is a group obtained by replacing a hydrogen atom of a hydroxyl group with a protecting group or a group obtained by replacing a hydrogen atom of an amino group with a protecting group, and the protecting group is optionally an eliminatable protecting group;
each Ar⁰ independently represents a phenylene group, a naphthylene group, an anthrylene group, a phenanthrylene group, a pyrylene group, a fluorirene group, a biphenylene group, a diphenylmethylene group, or a terphenylene group;
R⁰ is a substituent on Ar⁰, and each R⁰ is independently the same or different groups and represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group;
X represents a linear or branched alkylene group or an oxygen atom;
n represents an integer of 0 to 500;
each r independently represents an integer of 1 to 3;
r⁰ represents an integer of 0 to 2;
each p independently represents a positive integer; and
q represents a positive integer.
   [6]

The underlayer film forming composition for lithography according to [5], wherein the compound and/or resin represented by the formula (3) is represented by the following formula (3-1A) or the following formula (3-1B):

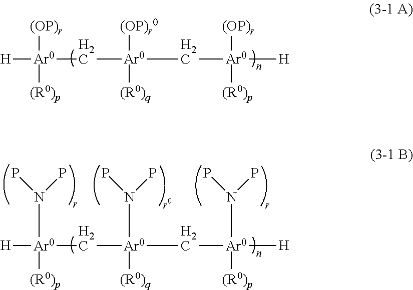

wherein Ar⁰, R⁰, p, q, r, r⁰, and n are synonymous with the definition in the formula (3); and
each P is independently a hydrogen atom or a protecting group, wherein at least one P is the protecting group, and the protecting group is optionally an eliminatable protecting group.
   [7]

The underlayer film forming composition for lithography according to [6], wherein the compound and/or resin represented by the formula (3-1A) or the formula (3-1B) is represented by the following formula (3-2A) or the following formula (3-2B):

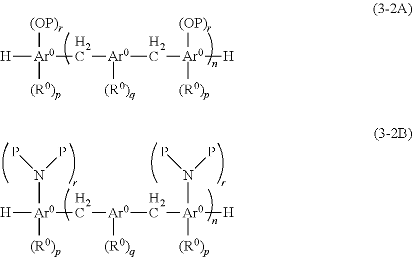

wherein Ar⁰, P, R⁰, p, q, r, and n are synonymous with the definition in the formula (3-1A) or the formula (3-1B).
[8]

The underlayer film forming composition for lithography according to [5], wherein the compound and/or resin represented by the following formula (3) is represented by the following formula (3-10A) or the following formula (3-10B):

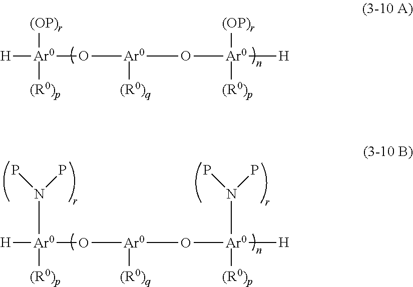

wherein Ar⁰, R⁰, p, q, r, and n are synonymous with the definition in the formula (3); and
each P is independently a hydrogen atom or a protecting group, wherein at least one P is a protecting group, and the protecting group is optionally an eliminatable protecting group.
   [9]

The underlayer film forming composition for lithography according to [5], wherein the compound and/or resin represented by the following formula (3) is represented by the following formula (3-11A) or the following formula (3-11B):

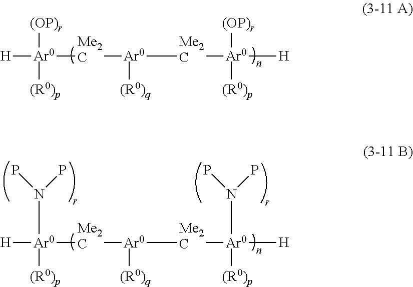

wherein Ar⁰, R⁰, p, q, r, and n are synonymous with the definition in the formula (3); and
each P is independently a hydrogen atom or a protecting group, wherein at least one P is a protecting group, and the protecting group is optionally an eliminatable protecting group.
   [10]

The underlayer film forming composition for lithography according to any one of [1] to [9], wherein the protecting group is an electron-withdrawing protecting group that reduces the electron density at a specific position in a molecule by an inductive effect or a resonance effect; and
the electron-withdrawing protecting group is one or more selected from the group consisting of a carbonyl-based protecting group, a sulfonyl-based protecting group, and an acyl-based protecting group.
   [11]

The underlayer film forming composition for lithography according to [10], wherein the electron-withdrawing protecting group is one or more selected from the group consisting of a substituted or unsubstituted alkylcarbonyl group having 2 to 20 carbon atoms, a substituted or unsubstituted arylcarbonyl group having 6 to 20 carbon atoms, a substituted or unsubstituted alkoxycarbonyl group having 2 to 20 carbon atoms, a substituted or unsubstituted alkylsulfonyl group having 1 to 10 carbon atoms, a substituted or unsubstituted arylsulfonyl group having 6 to 20 carbon atoms, and a substituted or unsubstituted acyl group having 2 to 13 carbon atoms.

[12]

The underlayer film forming composition for lithography according to [10], wherein the electron-withdrawing protecting group is one or more selected from the group consisting of an acetyl group, a trifluoroacetyl group, a benzoyl group, a mesyl group, a nosyl group, and a triflate group.

[13]

The underlayer film forming composition for lithography according to any one of [1] to [9], wherein the protecting group is an electron-donating protecting group that increases the electron density at a specific position in a molecule by an inductive effect or a resonance effect; and
the electron-donating protecting group is one or more selected from the group consisting of an alkyl-based protecting group, a benzyl-based protecting group, an acetal-based protecting group, a trityl-based protecting group, a silyl-based protecting group, and a glycidyl group.
   [14]

The underlayer film forming composition for lithography according to [13], wherein the electron-donating protecting group is one or more selected from the group consisting of a substituted or unsubstituted alkyl group having 1 to 20 carbon atoms, a substituted or unsubstituted benzyl group having 7 to 20 carbon atoms, a substituted or unsubstituted alkoxyalkyl group having 2 to 20 carbon atoms, a substituted or unsubstituted tetrahydropyranyl group having 2 to 20 carbon atoms, a substituted or unsubstituted alkylthioalkyl group having 2 to 20 carbon atoms, a substituted or unsubstituted trityl group having 19 to 30 carbon atoms, a substituted or unsubstituted silyl group having 3 to 20 carbon atoms, and a glycidyl group.

[15]

The underlayer film forming composition for lithography according to [13], wherein the electron-donating protecting group is one or more selected from the group consisting of a methyl group, a tert-butyl group, a normal hexyl group, an octyl group, an ethoxyethyl group, an ethoxypropyl group, and a glycidyl group.

[16]

The underlayer film forming composition for lithography according to any one of [1] to [15], wherein the compound has a weight average molecular weight of 500 to 10,000.

[17]

The underlayer film forming composition for lithography according to any one of [1] to [16], wherein a weight ratio of a low molecular weight component having a molecular weight of less than 500 is less than 1% in the compound.

[18]

The underlayer film forming composition for lithography according to any one of [1] to [17], further comprising an acid generating agent.

[19]

The underlayer film forming composition for lithography according to any one of [1] to [18], further comprising a crosslinking agent.

[20]

The compound and/or resin used in the underlayer film forming composition for lithography according to any one of [1] to [19].

[21]

An underlayer film for lithography obtained by using the underlayer film forming composition for lithography according to any one of [1] to [19].

[22]

A method for forming a resist pattern, comprising the steps of:
forming an underlayer film on a substrate using the underlayer film forming composition for lithography according to any one of [1] to [19];
forming at least one photoresist layer on the underlayer film; and
irradiating a predetermined region of the photoresist layer with radiation for development.
   [23]

A method for forming a circuit pattern comprising the steps of:
forming an underlayer film on a substrate using the underlayer film forming composition for lithography according to any one of [1] to [19];
forming an intermediate layer film on the underlayer film using a resist intermediate layer film material containing a silicon atom;
forming at least one photoresist layer on the intermediate layer film;
irradiating a predetermined region of the photoresist layer with radiation for development, thereby forming a resist pattern;
etching the intermediate layer film with the resist pattern as a mask;
etching the underlayer film with the obtained intermediate layer film pattern as an etching mask; and
etching the substrate with the obtained underlayer film pattern as an etching mask, thereby forming a pattern on the substrate.
   [24]

A method for forming an underlayer film for lithography, comprising a step of applying the underlayer film forming composition for lithography according to any one of [1] to [19] to an uneven substrate.

[25]

The formation method according to [24], wherein the underlayer film forming composition for lithography has a viscosity of 0.01 to 1.00 Pa·s.

[26]

The formation method according to [24] or [25], wherein the underlayer film forming composition for lithography has a softening point of −50 to 100° C.

### Advantageous Effect of Invention

The present embodiment can provide a useful underlayer film forming composition for lithography that is excellent in embedding properties to an uneven substrate and smoothing properties, and the like.

### DESCRIPTION OF EMBODIMENTS

Hereinafter, an embodiment of the present invention will be described (hereinafter, also referred to as the “present embodiment”). Herein, the embodiments described below are given merely for illustrating the present invention. The present invention is not limited only by these embodiments. That is, the present invention can be arbitrarily modified and implemented without departing from the gist of the present invention. In the present specification, for example, the description of the numerical value range of “1 to 100” includes both the lower limit value “1” and the upper limit value “100”. The same applies to the description of other numerical value ranges.

As the underlayer film forming composition for lithography of the present embodiment, a composition containing a compound (hereinafter, also referred to as the underlayer film forming composition for lithography) that has a protecting group (preferably a protecting group that reduces or increases the electron density at a specific position in a molecule by an inductive effect or a resonance effect) is used. Here, the compound having a protecting group may be a low molecular compound having a molecular weight of 10,000 or less, an oligomer, a prepolymer, a resin, or a mixture of any combination selected from these.

The amount of the compound having a protecting group contained in the underlayer film forming composition for lithography is not particularly limited, and may be, for example, 50 to 100% by mass, 60 to 95% by mass, or 70 to 90% by mass based on the total mass of the total components (excluding the solvent) contained in the composition.

The underlayer film forming composition for lithography used herein contains a compound having a protecting group and is applicable to a wet process although it has a relatively low molecular weight. When the compound having a protecting group includes an aromatic ring in the structure thereof, the compound has high heat resistance due to the aromaticity thereof, so that the compound is not only excellent in heat resistance and etching resistance, but also causes a cross-linking reaction to occur by itself by high temperature baking and exhibits high heat resistance. As a result, deterioration of the film upon baking at a high temperature is suppressed and an underlayer film also excellent in etching resistance to oxygen plasma etching and the like can be formed. Furthermore, when the compound having a protecting group includes an aromatic ring in the structure thereof, the underlayer film forming composition for lithography has a high solubility in an organic solvent, a high solubility in a safe solvent, and good stability of product quality even though having an aromatic structure. In addition, the composition for underlayer film for lithography of the present embodiment used herein is also excellent in adhesiveness to a resist layer and a resist intermediate layer film material, and can therefore produce an excellent resist pattern.

In the compound having a protecting group of the present embodiment, since a part of the hydroxyl group or the amino group or all hydrogen atoms are replaced with other substituents (that is, protected), the intermolecular force (hydrogen bond) between the compounds is reduced. Therefore, the viscosity of the composition is reduced as compared with that of the composition in which the hydroxyl group or the amino group is not protected, so that the embedding properties and smoothing properties tend to be good. At this time, as the protecting group to be introduced has a lower polarity, the viscosity is likely to be lower. However, when the polarity of the whole molecule becomes too low, the solubility is reduced relative to polar solvents such as propylene glycol monomethyl ether and propylene glycol monomethyl ether acetate. Regarding such a reduction in the solubility along with the introduction of the protecting group, the control of the introduction rate of the protecting group enables the achievement of both low viscosity and solubility.

For example, the acetyl group which is an electron-withdrawing protecting group is relatively hardly deprotected and keeps a low viscosity state for a long time in the calcination process. Moreover, since the acetyl group reduces the nucleophilicity of the reaction point due to its electron-withdrawing properties, the crosslinking rate between molecules is reduced, allowing a low viscosity state to be maintained for a long time, so that an underlayer film having small unevenness and significantly excellent embedding properties and smoothing properties can be obtained. Similar to the acetyl group, the mesyl group maintains a low viscosity state for a long time due to its electron-withdrawing properties, and subsequently, the protecting group is eliminated. A calcined film from which components including hydrogen and oxygen are eliminated has a high carbon density, allowing an underlayer film having good smoothing properties and also having etching resistance to be obtained. Since the decomposed protecting group has a sufficiently low molecular weight and is turned into gas, it is not included in the sublimate that solidifies in an apparatus and does not contaminate the apparatus.

For example, the alkyl group which is an electron-donating protecting group is relatively hardly deprotected and keeps a low viscosity state for a long time in the calcination process. Moreover, the alkyl group exhibits sufficient crosslinkability due to its electron-donating properties, although it is a protecting group. In addition, since easily volatilizing low molecular weight components are rapidly polymerized, the sublimate that solidifies in an apparatus is unlikely to occur. For example, the ethoxyethyl group is likely to be deprotected in the calcination process and excellent in crosslinkability. Furthermore, the decomposed protecting group is turned into gas and is not included in the sublimate that solidifies in an apparatus. As a result, the calcined film has a high carbon density and improved etching resistance, allowing an underlayer film having good smoothing properties and also having low sublimation properties and etching resistance to be obtained. On the other hand, for example, the trityl group has a relatively high amount of increased molecular weight of the protected compound and/or resin as compared with that in the alkyl protecting group, and thus the sublimate derived from low molecular weight components is unlikely to occur. In addition, the trityl group is likely to be deprotected in the calcination process and excellent in crosslinkability. Furthermore, the decomposed protecting group is turned into gas and is not included in the sublimate that solidifies in an apparatus. As a result, the calcined film has a high carbon density and improved etching resistance, allowing an underlayer film having good smoothing properties and also having low sublimation properties and etching resistance to be obtained.

Since an oxidation reaction occurs under high temperatures during firing, a molecular structure constituted from oxygen atoms, quaternary carbons, and aromatic rings that are hardly oxidized is hardly decomposed and is unlikely to cause a problem of apparatus contamination due to the volatilization of decomposition products. In such a case, the decomposition properties of the resin can be reduced by forming a large number of structures in which aromatic rings are bonded via a quaternary carbon or an oxygen atom, or directly bonded to each other.

The compound having a protecting group of the present embodiment is not particularly limited, but when an underlayer film is obtained using the underlayer film forming composition for lithography, the production of the sublimate that solidifies in an apparatus may be a problem. Since the sublimate is caused by low molecular components having a weight average molecular weight Mw of 500 or less, a film having smoothing properties while preventing the occurrence of the sublimate can be obtained by controlling the molecular weight range. The molecular weight is preferably Mw=500 to 10,000 as a molecular weight in terms of polystyrene, and from the viewpoint of the balance between embedding smoothness and heat resistance, more preferably Mw=800 to 8,000, further preferably, Mw=1,000 to 5,000, and particularly preferably Mw=1,000 to 2,000.

The compound having a protecting group of the present embodiment preferably has dispersibility (weight average molecular weight Mw/number average molecular weight Mn) within the range of 1.1 to 5.0, and more preferably has dispersibility within the range of 1.1 to 2.0, from the viewpoint of enhancing crosslinking efficiency while suppressing volatile components during baking. The above Mw, Mn, and dispersibility can be determined by a method described in Examples mentioned later.

The sublimate is caused by low molecular components having a molecular weight of 500 or less, and thus in the compound having a protecting group in the present embodiment, the weight ratio of the low molecular weight component having a molecular weight of less than 500 is preferably less than 1% based on the total weight of the compound.

The compound having a protecting group of the present embodiment has a relatively low molecular weight and low viscosity, and therefore facilitates enhancing the flatness of the under layer film to be obtained while uniformly and completely filling even the steps of an uneven substrate (particularly having fine space, hole pattern, etc.). Thus, the underlayer film formed from the underlayer film forming composition for lithography of the present embodiment is excellent in not only smoothing properties, but also embedding properties. In addition, the compound having a protecting group of the present embodiment has a relatively high carbon concentration, and can therefore exhibit high etching resistance, as well.

Here, as for structural formulas described in the present specification, for example, when a line indicating a bond to C is in contact with a ring A and a ring B as described below, C is meant to be bonded to any one or both of the ring A and the ring B.

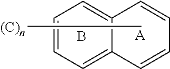

The underlayer film forming composition for lithography of the present embodiment preferably contains a compound and/or resin represented by the following formula (1).

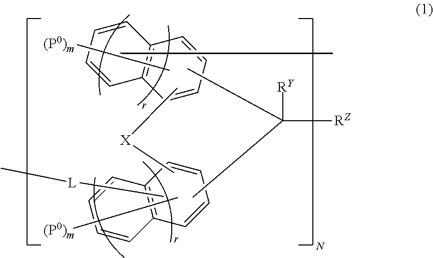

(In the formula (1),
each R^{Y} is independently a hydrogen atom, a linear, branched, or cyclic alkyl group having 1 to 30 carbon atoms, or an aryl group having 6 to 30 carbon atoms;
R^{Z} is an N-valent group having 1 to 60 carbon atoms or a single bond;
each P⁰ is independently selected from the group consisting of a halogen atom, a nitro group, an alkyl group having 1 to 30 carbon atoms, an alkenyl group having 2 to 30 carbon atoms, an alkynyl group having 2 to 30 carbon atoms, an aryl group having 6 to 40 carbon atoms, a hydroxyl group, an amino group, a group obtained by replacing a hydrogen atom of a hydroxyl group with a protecting group, a group obtained by replacing a hydrogen atom of an amino group with a protecting group, and a functional group of a combination thereof, wherein at least one P⁰ is a group obtained by replacing a hydrogen atom of a hydroxyl group with a protecting group or a group obtained by replacing a hydrogen atom of an amino group with a protecting group, and the protecting group is optionally an eliminatable protecting group;
each X independently represents an oxygen atom or a sulfur atom, or not a crosslink;
L is a single bond, a linear or branched alkylene group having 1 to 30 carbon atoms and optionally having a substituent, or not a crosslink;
each m is independently an integer of 0 to 9, wherein at least one m is an integer of 1 to 9;
N is an integer of 1 to 4; and
each r is independently an integer of 0 to 2.)

The compound and/or resin represented by the above formula (1) is preferably represented by the following formula (1-1). The compound having a protecting group of the present embodiment constituted as described above has high heat resistance and high solvent solubility.

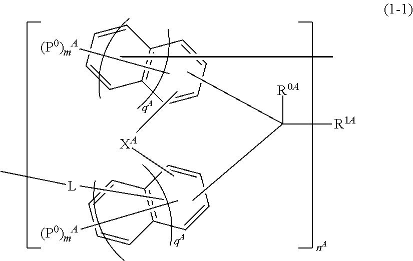

(In the formula (1-1),
L and P⁰ are synonymous with the definition in the above formula (1);
R^{0A} is a hydrogen atom;
R^{1A} is an n^{A}-valent group having 1 to 30 carbon atoms or a single bond;
n^{A} is an integer of 1 to 4, wherein when n^{A} is an integer of 2 or larger in the formulas (1-1), n^{A} structural formulas within the parentheses [ ] are the same or different;
each X^{A} is preferably an oxygen atom or a sulfur atom and more preferably an oxygen atom, because there is a tendency to exhibit excellent heat resistance;
each m^{A} is independently an integer of 0 to 6, wherein at least one m^{A} is an integer of 1 to 6; and
each q^{A} is independently 0 or 1.)

The N-valent group refers to an alkyl group having 1 to 60 carbon atoms when N is 1, an alkylene group having 1 to 30 carbon atoms when N is 2, an alkanepropayl group having 2 to 60 carbon atoms when N is 3, and an alkanetetrayl group having 3 to 60 carbon atoms when N is 4. The n^{A}-valent group refers to an alkyl group having 1 to 60 carbon atoms when n^{A} is 1, an alkylene group having 1 to 30 carbon atoms when n^{A} is 2, an alkanepropayl group having 2 to 60 carbon atoms when n^{A} is 3, and an alkanetetrayl group having 3 to 60 carbon atoms when n^{A} is 4. Examples of the above N-valent group and n^{A}-valent group include groups having a linear hydrocarbon group, a branched hydrocarbon group, and an alicyclic hydrocarbon group. Herein, the above alicyclic hydrocarbon group also includes a bridged alicyclic hydrocarbon group. Also, the above N-valent group and n^{A}-valent group may have an aromatic group having 6 to 60 carbon atoms.

In addition, the above N-valent hydrocarbon group may have an alicyclic hydrocarbon group, a double bond, a heteroatom, or an aromatic group having 6 to 60 carbon atoms. Herein, the above alicyclic hydrocarbon group also includes a bridged alicyclic hydrocarbon group.

In addition, the above n^{A}-valent hydrocarbon group may have an alicyclic hydrocarbon group, a double bond, a heteroatom, or an aromatic group having 6 to 30 carbon atoms. Herein, the above alicyclic hydrocarbon group also includes a bridged alicyclic hydrocarbon group.

The compound and/or resin represented by the above formula (1-1) is preferably a compound and/or resin represented by the following formula (1-2A) or the following formula (1-2B) from the viewpoint of easy crosslinking and solubility in an organic solvent.

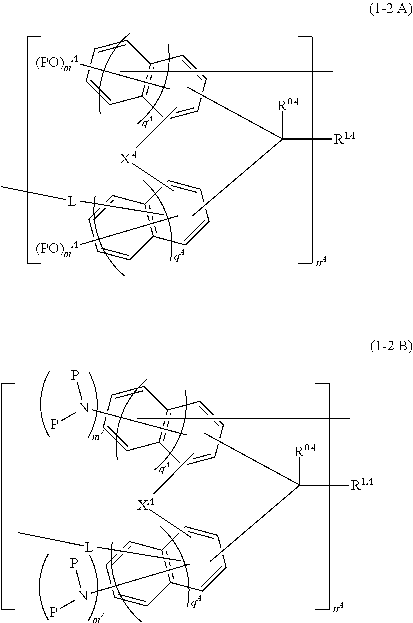

(In the formulas (1-2A) and (1-2B),
L, R^{0A}, R^{1A}, m^{A}, n^{A}, q^{A}, and X^{A} are as defined in the description of the above formula (1-1);
each P is independently a hydrogen atom or a protecting group, wherein at least one P is a protecting group; and the protecting group is optionally an eliminatable protecting group.)

The compound and/or resin represented by the above formula (1-2A) or (1-2B) is preferably a compound and/or resin represented by the following formula (1-3A) or the following formula (1-3B) from the viewpoint of the supply of raw materials.

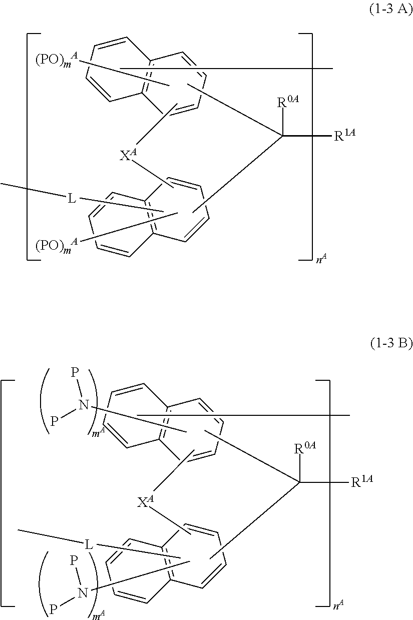

(In the above formulas (1-3A) and (1-3B),
L, P, X^{A}, R^{0A}, R^{1A}, m^{A}, and n^{A} are as defined in the description of the above formulas (1-2A) and (1-2B).)

The compound and/or resin represented by the above formula (1) is preferably a compound and/or resin represented by the following formula (2). The compound and/or resin is constituted as described below and therefore has high heat resistance and also high solvent solubility.

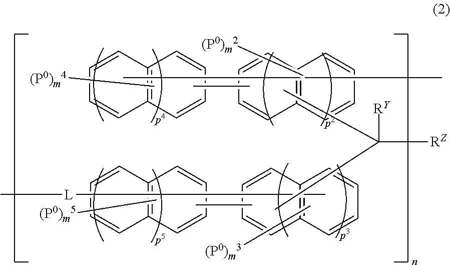

(In the formula (2),
R^{Y}, R^{Z}, P⁰, and L are synonymous with the definition in the above formula (1);
m² and m³ are each independently an integer of 0 to 8, and m⁴ and m⁵ are each independently an integer of 0 to 9, provided that m², m³, m⁴, and m⁵ are not 0 at the same time;
n is as defined in N in the above formula (1), wherein when n is an integer of 2 or larger, structural formulas within n parentheses [ ] are the same or different; and
p² to p⁵ are as defined in r in the above formula (1).)

The n-valent group refers to an alkyl group having 1 to 60 carbon atoms when n is 1, an alkylene group having 1 to 30 carbon atoms when n is 2, an alkanepropayl group having 2 to 60 carbon atoms when n is 3, and an alkanetetrayl group having 3 to 60 carbon atoms when n is 4. Examples of the above n-valent group include groups having a linear hydrocarbon group, a branched hydrocarbon group, and an alicyclic hydrocarbon group. Herein, the above alicyclic hydrocarbon group also includes a bridged alicyclic hydrocarbon group. Also, the above n-valent group may have an aromatic group having 6 to 60 carbon atoms.

In addition, the above n-valent hydrocarbon group may have an alicyclic hydrocarbon group, a double bond, a heteroatom, or an aromatic group having 6 to 60 carbon atoms. Herein, the above alicyclic hydrocarbon group also includes a bridged alicyclic hydrocarbon group.

The compound and/or resin represented by the above formula (1) or (2) has a relatively low thermal fluid temperature and a low viscosity when turned into a solution, and thus can enhance the flatness of the under layer film to be obtained and can be used under high temperature baking conditions since it has high heat resistance due to the rigidity of the structure thereof while having a relatively low molecular weight. In addition, the compound and/or resin represented by the above formula (1) or (2) has high solubility in a safe solvent, suppressed crystalline, and good heat resistance and etching resistance, and relatively suppresses the production of sublimates by heat treatment in a wide range from low temperature to high temperature, and therefore facilitates enhancing the flatness of the film while uniformly and completely filling even the steps of an uneven substrate (particularly having fine space, hole pattern, etc.).

The compound and/or resin represented by the above formula (2) is preferably a compound and/or resin represented by the following formula (2-1A) or the following formula (2-1B) from the viewpoint of easy crosslinking and solubility in an organic solvent.

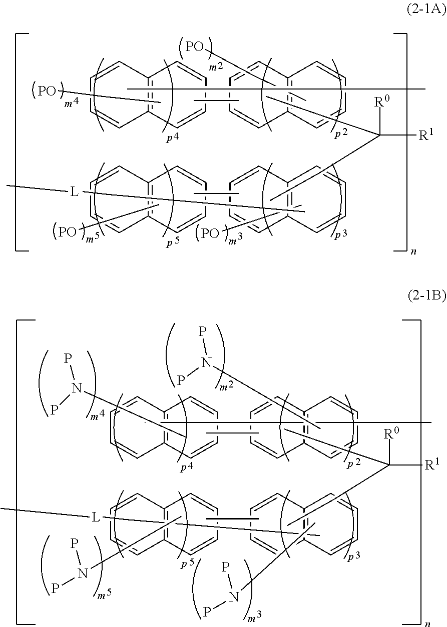

(In the above formulas (2-1A) and (2-1B),
R⁰ is as defined in R^{Y} in the above formula (1);
R¹ is as defined in R^{Z} in the above formula (1);
L is as defined in L in the above formula (1);
n is as defined in N in the above formula (1);
p² to p⁵ are as defined in r in the above formula (1);
m² and m³ are each independently an integer of 0 to 4, and m⁴ and m⁵ are each independently an integer of 0 to 5, provided that m², m³, m⁴, and m⁵ are not 0 at the same time;
each P is independently a hydrogen atom or a protecting group, wherein at least one P is a protecting group; and the protecting group is optionally an eliminatable protecting group.)

The compound and/or resin represented by the above formula (2) is preferably the compound and/or resin represented by the following formula (2-2A) or (2-2B) from the viewpoint of the supply of raw materials.

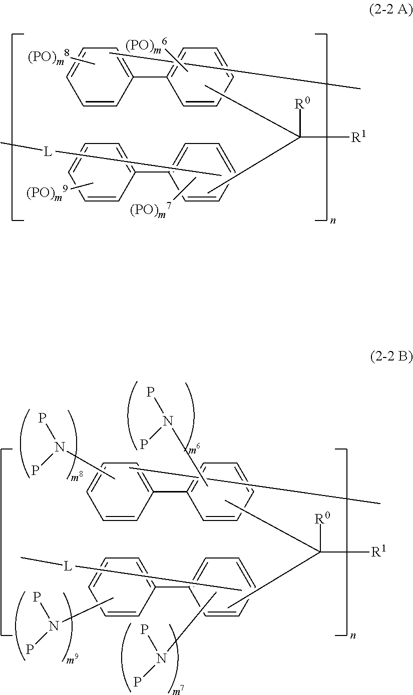

(In the above formulas (2-2A) and (2-2B),
L, P, R⁰, R¹, and n are as defined in the description of the above formula (2-1A) or (2-1B), m⁶ and m⁷ are each independently an integer of 0 to 4, m⁸ and m⁹ are each independently an integer of 0 to 5, provided that m⁶, m⁷, m⁸, and m⁹ are not 0 at the same time.)

In the present specification, at least one P⁰ is a group obtained by replacing a hydrogen atom of a hydroxyl group with a protecting group or a group obtained by replacing a hydrogen atom of an amino group with a protecting group, and P is a protecting group. The protecting group is a functional group that reduces or increases the electron density at a specific position in a molecule by an inductive effect or a resonance effect.

Representative examples of the electron-withdrawing protecting group that reduces the electron density at a specific position in a molecule by an inductive effect or a resonance effect include, but are not limited to, a carbonyl-based protecting group (e.g., a substituted or unsubstituted alkylcarbonyl group having 2 to 20 carbon atoms, a substituted or unsubstituted arylcarbonyl group having 6 to 20 carbon atoms, and a substituted or unsubstituted alkoxycarbonyl group having 2 to 20 carbon atoms); a sulfonyl-based protecting group (e.g., a substituted or unsubstituted alkylsulfonyl group having 1 to 10 carbon atoms and a substituted or unsubstituted arylsulfonyl group having 6 to 20 carbon atoms); and an acyl-based protecting group obtained by removing the hydroxy group from an oxoacid (e.g., a substituted or unsubstituted acyl group having 2 to 13 carbon atoms). Specific examples of the electron-withdrawing protecting group include, but are not limited to, a tert-butoxycarbonyl group, a trichloroethoxycarbonyl group, a trimethylsilyl ethoxycarbonyl group, a benzyloxycarbonyl group, a mesyl group, a tosyl group, a nosyl group, a triflate group, an acetyl group, a trifluoroacetyl group, a pivaloyl group, a normal butyryl group, a toluoyl group, an isobutyryl group, a pentanoyl group, a propionyl group, a benzoyl group, a (meth)acryloyl group, an epoxy (meth)acryloyl group, and a urethane (meth)acryloyl group. The electron-withdrawing protecting group is preferably an acetyl group, a trifluoroacetyl group, a benzoyl group, a mesyl group, a nosyl group, or a triflate group, and particularly preferably an acetyl group, a mesyl group, or a triflate group.

It is found that the introduction of an electron-withdrawing protecting group enables an effect of inhibiting intermolecular forces such as hydrogen bonding to be obtained and enables the formation of a smooth film with low viscosity and good fluidity. Furthermore, the reduction of the nucleophilicity of the reaction point adjacent to a functional group by the electron-withdrawing effect of the protecting group reduces the crosslinking rate during the formation of a cured film and enables a low viscosity state to be maintained for a long time, so that an underlayer film having small unevenness and significantly excellent smoothing properties can be obtained. When the electron-withdrawing protecting group is an eliminatable protecting group that is eliminated by the action of heat or light, the carbon content and film density of the formed film are improved and an underlayer film having high dry etching resistance can be obtained.

Representative examples of the electron-donating protecting group that increases the electron density at a specific position in a molecule by an inductive effect or a resonance effect include, but are not limited to, an alkyl-based protecting group (e.g., a substituted or unsubstituted alkyl group having 1 to 20 carbon atoms); a benzyl-based protecting group (e.g., a substituted or unsubstituted benzyl group having 7 to 20 carbon atoms); an acetal-based protecting group (e.g., a substituted or unsubstituted alkoxyalkyl group having 2 to 20 carbon atoms, a substituted or unsubstituted tetrahydropyranyl group having 2 to 20 carbon atoms, and a substituted or unsubstituted alkylthioalkyl group having 2 to 20 carbon atoms); a trityl-based protecting group (e.g., a substituted or unsubstituted trityl group having 19 to 30 carbon atoms); a silyl-based protecting group (e.g., a substituted or unsubstituted silyl group having 3 to 20 carbon atoms); and a glycidyl group. Specific examples of the electron-donating protecting group include, but are not limited to, a methyl group, an ethyl group, a normal propyl group, an isopropyl group, a normal butyl group, an isobutyl group, a tert-butyl group, a pentyl group, a hexyl group, a heptyl group, an octyl group, a benzyl group, a methoxybenzyl group, a dimethoxybenzyl group, a methylbenzyl group, a methoxymethyl group, an ethoxyethyl group, an ethoxypropyl group, a tetrahydropyranyl group, a methylthiomethyl group, a benzyloxymethyl group, a methoxyethoxymethyl group, a trityl group, a monomethoxytrityl group, a dimethoxytrityl group, a trimethylsilyl group, a triethylsilyl group, a triisopropylsilyl group, a tert-butyldimethylsilyl group, a tert-butyldiphenylsilyl group, and a glycidyl group. The electron-donating protecting group is preferably a methyl group, a tert-butyl group, a normal hexyl group, an octyl group, an ethoxyethyl group, an ethoxypropyl group, or a glycidyl group, and further preferably a tert-butyl group, an ethoxyethyl group, or a glycidyl group.

The introduction of an electron-donating protecting group enables an increase of the crosslinking rate during baking, and an underlayer film that has small unevenness and less occurrence of the sublimate can be obtained by rapidly hardening the smooth film with low viscosity and good fluidity. When the electron-donating protecting group is an eliminatable protecting group that is eliminated by the action of heat or light, not only the crosslinking rate is further improved, but also the carbon content and film density of the formed film are improved, and an underlayer film having high dry etching resistance can be obtained.

The underlayer film forming composition for lithography of the present embodiment preferably contains a compound and/or resin represented by the following formula (3).

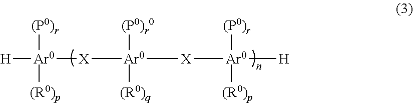

(In the formula (3),
P⁰ is synonymous with the definition in the above formula (1);
each Ar⁰ independently represents a phenylene group, a naphthylene group, an anthrylene group, a phenanthrylene group, a pyrylene group, a fluorirene group, a biphenylene group, a diphenylmethylene group, or a terphenylene group;
R⁰ is a substituent on Ar⁰, and each R⁰ is independently the same or different groups and represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group;
X represents a linear or branched alkylene group or an oxygen atom;
n represents an integer of 0 to 500;
each r independently represents an integer of 1 to 3;
r⁰ represents an integer of 0 to 2;
each p independently represents a positive integer; and
q represents a positive integer.)

R⁰ is a substituent on Ar⁰, and each R⁰ is independently the same or different groups, and represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group, and is preferably a hydrogen atom or an alkyl group having 1 to 30 carbon atoms and optionally having a substituent.

X represents a linear or branched alkylene group, and is specifically a methylene group, an ethylene group, a n-propylene group, an i-propylene group, a n-butylene group, an i-butylene group, or a tert-butylene group, preferably a methylene group, an ethylene group, a n-propylene group, or a n-butylene group, further preferably a methylene group or a n-propylene group, and most preferably a methylene group. Alternatively, X is an oxygen atom.

In the above formula (3), n is an integer of 0 to 500, preferably an integer of 1 to 500, and more preferably an integer of 1 to 50.

In the above formula (3), r represents an integer of 1 to 3.

In the above formula (3), p represents a positive integer. p arbitrarily varies according to the kind of Ar⁰.

In the above formula (3), q represents a positive integer. q arbitrarily varies according to the kind of Ar⁰.

The compound and/or resin represented by the above formula (3) has a relatively low thermal fluid temperature and a low viscosity when turned into a solution, and thus has flatness and can be used under high temperature baking conditions since it has high heat resistance due to the rigidity of its structure while having a relatively low molecular weight. In addition, the compound and/or resin has high solubility in a safe solvent, suppressed crystalline, and good heat resistance and etching resistance, and relatively suppresses the occurrence of the sublimate by heat treatment in a wide range from low temperature to high temperature, and therefore facilitates enhancing the flatness of the film while uniformly and completely filling even the steps of an uneven substrate (particularly having fine space, hole pattern, etc.).

In the underlayer film forming composition for lithography of the present embodiment, the compound and/or resin represented by the above formula (3) is preferably a compound and/or resin represented by the following formula (3-1A) or (3-1B) from the viewpoint of curing properties and raw material availability.

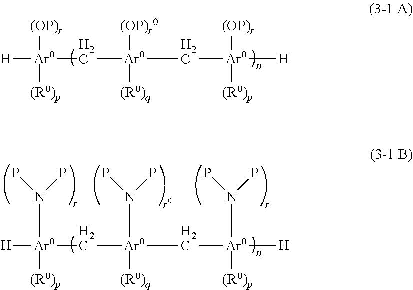

(In the formulas (3-1A) and (3-1B),
Ar⁰, R⁰, p, q, r, r⁰, and n are synonymous with the definition in the above formula (3); and
each P is independently a hydrogen atom or a protecting group, wherein at least one P is a protecting group, and the protecting group is optionally an eliminatable protecting group, or each P independently represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, a crosslinkable group optionally having a substituent, or a dissociable group optionally having a substituent, wherein at least one P may be an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, a crosslinkable group optionally having a substituent, or a dissociable group optionally having a substituent.)

P is a hydrogen atom or a protecting group.

Specific examples of the electron-withdrawing protecting group include, but are not limited to, a tert-butoxycarbonyl group, a trichloroethoxycarbonyl group, a trimethylsilyl ethoxycarbonyl group, a benzyloxycarbonyl group, a mesyl group, a tosyl group, a nosyl group, a triflate group, an acetyl group, a trifluoroacetyl group, a pivaloyl group, a normal butyryl group, a toluoyl group, an isobutyryl group, a pentanoyl group, a propionyl group, a benzoyl group, a (meth)acryloyl group, an epoxy (meth)acryloyl group, and a urethane (meth)acryloyl group. The electron-withdrawing protecting group is preferably an acetyl group, a trifluoroacetyl group, a benzoyl group, a mesyl group, a nosyl group, or a triflate group, and particularly preferably an acetyl group, a mesyl group, or a triflate group.

Specific examples of the electron-donating protecting group include, but are not limited to, a methyl group, an ethyl group, a normal propyl group, an isopropyl group, a normal butyl group, an isobutyl group, a tert-butyl group, a pentyl group, a hexyl group, a heptyl group, an octyl group, a benzyl group, a methoxybenzyl group, a dimethoxybenzyl group, a methylbenzyl group, a methoxymethyl group, an ethoxyethyl group, an ethoxypropyl group, a tetrahydropyranyl group, a methylthiomethyl group, a benzyloxymethyl group, a methoxyethoxymethyl group, a trityl group, a monomethoxytrityl group, a dimethoxytrityl group, a trimethylsilyl group, a triethylsilyl group, a triisopropylsilyl group, a tert-butyldimethylsilyl group, a tert-butyldiphenylsilyl group, and a glycidyl group. The electron-donating protecting group is preferably a methyl group, a tert-butyl group, a normal hexyl group, an octyl group, an ethoxyethyl group, an ethoxypropyl group, or a glycidyl group, and further preferably a tert-butyl group, an ethoxyethyl group, or a glycidyl group.

The compound and/or resin represented by the above formula (3-1A) or (3-1B) is preferably a compound and/or resin represented by the following formula (3-2A) or the following formula (3-2B) from the viewpoint of availability of raw materials.

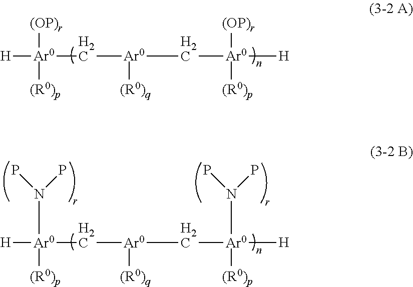

(In the formulas (3-2A) and (3-2B),
Ar⁰, P, R⁰, p, q, r, and n are synonymous with the definition in the above formula (3-1A) or (3-1B).)

In the underlayer film forming composition for lithography of the present embodiment, the compound and/or resin represented by the above formula (3-2A) or (3-2B) is preferably a compound and/or resin represented by the following formula (3-3A) or (3-3B) from the viewpoint of impartment of solubility and heat resistance.

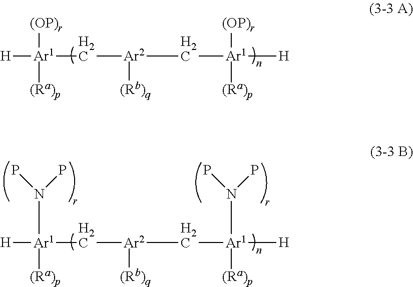

(In the above formulas (3-3A) and (3-3B),
P is synonymous with the definition in the above formula (3-2A) or formula (3-2B);
each Ar² independently represents a phenylene group, a naphthylene group, or a biphenylene group, and Ar¹ represents a naphthylene group or a biphenylene group when Ar² is a phenylene group, and Ar¹ represents a phenylene group, a naphthylene group, or a biphenylene group when Ar² is a naphthylene group or a biphenylene group;
R^{a} is a substituent on Ar¹, and each R^{a} is independently the same or different groups and represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group;
R^{b} is a substituent on Ar², and each R^{b} is independently the same or different groups and represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group;
n represents an integer of 0 to 500;
each r independently represents an integer of 1 to 3;
each p independently represents a positive integer; and
q represents a positive integer.)

In the underlayer film forming composition for lithography of the present embodiment, the compound and/or resin represented by the above formula (3-3A) or (3-3B) is preferably a compound and/or resin represented by the following formula (3-4A) or (3-4B) from the viewpoint of heat resistance and etching resistance.

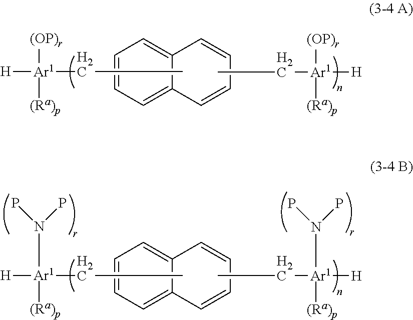

(In the above formulas (3-4A) and (3-4B),
Ar¹, P, R^{a}, r, p, and n are synonymous with the definition in the above formula (3-3A) or (3-3B).)

In the underlayer film forming composition for lithography of the present embodiment, the compound and/or resin represented by the above formula (3-3A) or (3-3B) is preferably a compound and/or resin represented by the following formula (3-5A) or (3-5B) from the viewpoint of heat resistance and etching resistance.

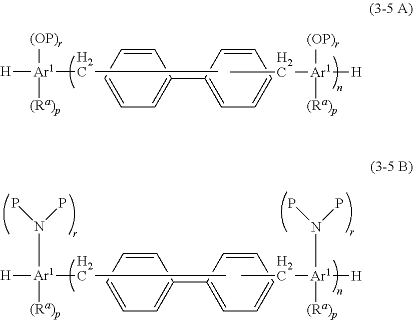

(In the formula (3-5A) and the formula (3-5B),
Ar¹, P, R^{a}, r, p, and n are synonymous with the definition in the above formula (3-3A) or (3-3B).)

In the underlayer film forming composition for lithography of the present embodiment, the compound and/or resin represented by the above formula (3-4A) or (3-4B) is preferably a compound and/or resin represented by the following formula (3-6A) or (3-6B) from the viewpoint of heat resistance and etching resistance.

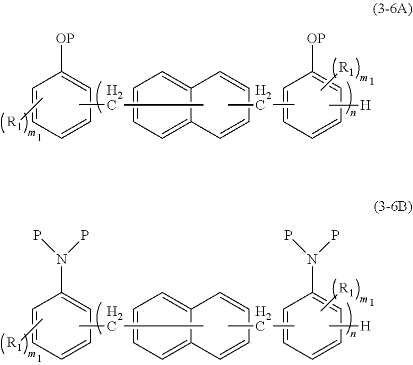

(In the formula (3-6A) and the formula (3-6B),
P is synonymous with the definition in the above formula (3-2A) or (3-2B);
each R₁ independently represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group;
each m₁ independently represents an integer of 1 to 3; and
n represents an integer of 1 to 50.)

In the underlayer film forming composition for lithography of the present embodiment, the compound and/or resin represented by the above formula (3-5A) or (3-5B) is further preferably a compound and/or resin represented by the following formula (3-7A) or (3-7B) from the viewpoint of flatness and thermal fluid properties.

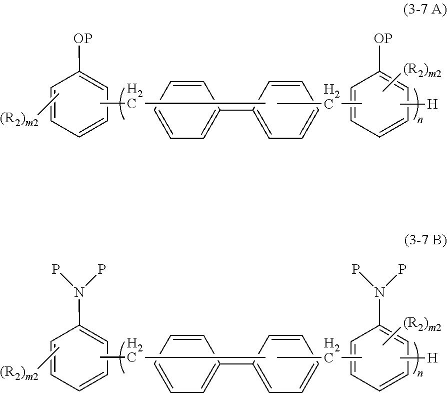

(In the formula (3-7A) and the formula (3-7B);
P is synonymous with the definition in the above formula (3-2A) or (3-2B);
each R₂ independently represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group;
each m₂ independently represents an integer of 1 to 3; and
n represents an integer of 1 to 50.)

In the underlayer film forming composition for lithography of the present embodiment, the compound and/or resin represented by the above formula (3-4A) or (3-4B) is further preferably a compound and/or resin represented by the following formula (3-8A) or (3-8B) from the viewpoint of heat resistance.

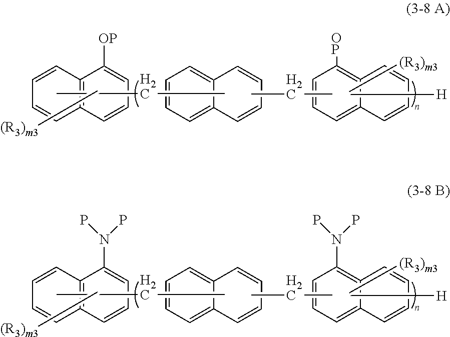

(In the formula (3-8A) and the formula (3-8B);
P is synonymous with the definition in the above formula (3-2A) or (3-2B);
each R₃ independently represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group;
each m₃ independently represents an integer of 1 to 5; and
n represents an integer of 1 to 50.)

In the underlayer film forming composition for lithography of the present embodiment, the compound and/or resin represented by the above formula (3-5A) or (3-5B) is further preferably a compound and/or resin represented by the following formula (3-9A) or (3-9B) from the viewpoint of curing properties and heat resistance.

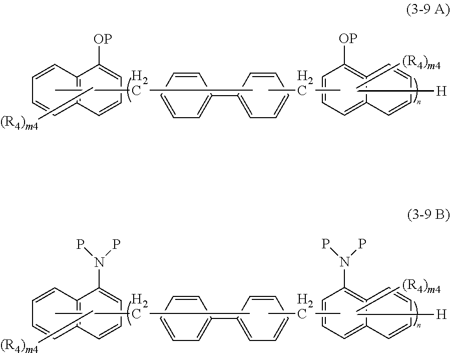

(In the formula (3-9A) and the formula (3-9B);
P is as defined in the above formula (3-2A) or (3-2B);
each R₄ independently represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group;
each m₄ independently represents an integer of 1 to 5; and
n represents an integer of 1 to 50.)

The compound and/or resin represented by the above formula (3) is preferably a compound and/or resin represented by the following formula (3-10A) or the following formula (3-10B) from the viewpoint of reducing decomposition properties.

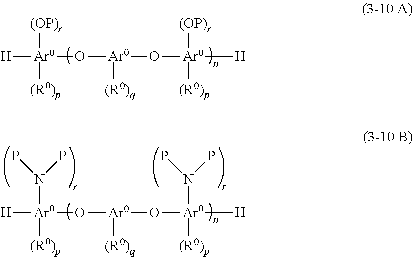

(In the formulas (3-10A) and (3-10B); Ar⁰, P, R⁰, p, q, r, and n are synonymous with the definition in the formula (3-1A) or the formula (3-1B).)

The compound and/or resin represented by the above formula (3) is preferably a compound and/or resin represented by the following formula (3-11A) or the following formula (3-11B).

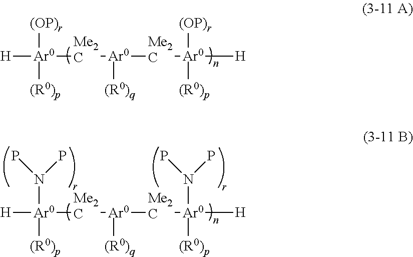

(In the formulas (3-11A) and (3-11B); Ar⁰, P, R⁰, p, q, r, and n are synonymous with the definition in the formula (3-1A) or the formula (3-1B).)

In the present embodiment, a substituent may further be introduced, in addition to the protecting group. Unless otherwise defined, the term “substituted” means that one or more hydrogen atoms in a functional group are replaced with a substituent. Examples of the “substituent” include, but are not particularly limited to, a halogen atom, a hydroxyl group, a cyano group, a nitro group, a thiol group, or a heterocyclic group, an alkyl group having 1 to 30 carbon atoms, an aryl group having 6 to 20 carbon atoms, an alkoxyl group having 1 to 30 carbon atoms, an alkenyl group having 2 to 30 carbon atoms, an alkynyl group having 2 to 30 carbon atoms, an acyl group having 1 to 30 carbon atoms, and an amino group having 0 to 30 carbon atoms. The alkyl group may be in any aspect of a linear aliphatic hydrocarbon group, a branched aliphatic hydrocarbon group, and a cyclic aliphatic hydrocarbon group.

The “crosslinkable group” in the present embodiment refers to a group that crosslinks in the presence of a catalyst or without a catalyst. Examples of such a crosslinkable group include a group that crosslinks in the presence of a catalyst or without a catalyst, among an alkoxy group having 1 to 20 carbon atoms, a group having an allyl group, a group having a (meth)acryloyl group, a group having an epoxy (meth)acryloyl group, a group having a hydroxy group, a group having a urethane (meth)acryloyl group, a group having a glycidyl group, a group having a vinyl containing phenylmethyl group, a group having various alkynyl groups, a group having a carbon-carbon double bond, a group having a carbon-carbon triple bond, and a group containing these groups. As the above “group containing these groups”, an alkoxy group represented by-ORx (Rx is a group having an allyl group, a group having a (meth)acryloyl group, a group having an epoxy (meth)acryloyl group, a group having a hydroxy group, a group having a urethane (meth)acryloyl group, a group having a glycidyl group, a group having a vinyl containing phenylmethyl group, a group having a group having various alkynyl groups, a group having a carbon-carbon double bond, a group having a carbon-carbon triple bond, or a group containing these groups) is preferable. In the present embodiment, when each functional group (excluding crosslinkable groups) described above as a constituent of the compound is overlapped with a crosslinkable group, those having no crosslinkability are treated as corresponding to each functional group and those having crosslinkability are treated as corresponding to crosslinkable groups, based on the presence or absence of crosslinkability.

Examples of the alkoxy group having 1 to 20 carbon atoms include a methoxy group, an ethoxy group, a propoxy group, an isopropoxy group, a n-butoxy group, an isobutoxy group, a tert-butoxy group, n-hexanoxy group and a 2-methylpropoxy group.

Examples of the group having an allyl group include groups represented by the formulas (X-1a) and (X-1b).

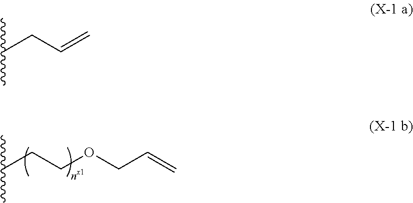

In the formula (X-1b), n^{x1} is an integer of 1 to 5.

Examples of the group having a (meth)acryloyl group include groups represented by the formulas (X-2a) to (X-2c).

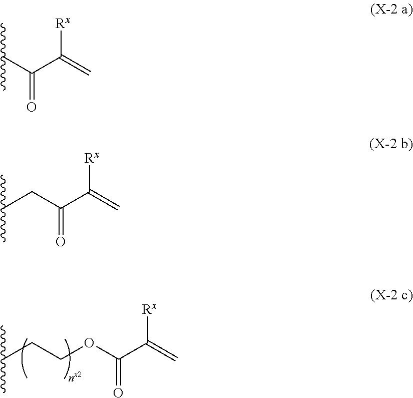

In the formula (X-2c), n^{X2} is an integer of 1 to 5, and in the formulas (X-2a) to (X-2c), R^{X} is a hydrogen atom or a methyl group.

Examples of the group having an epoxy (meth)acryloyl group include a group represented by the following formula (X-3). The epoxy (meth)acryloyl group refers to a group generated through a reaction between an epoxy (meth)acrylate and a hydroxy group.

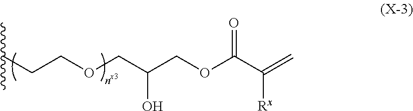

In the formula (X-3), n^{x3} is an integer of 0 to 5, and preferably 0 since excellent heat resistance and etching resistance can be obtained. R^{X} is a hydrogen atom or a methyl group, and preferably a methyl group since excellent curing properties can be obtained.

Examples of the group having a urethane (meth)acryloyl group include a group represented by the formula (X-4).

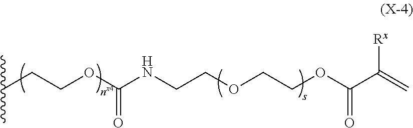

In the formula (X-4), n^{x4} is an integer of 0 to 5, and preferably 0 since excellent heat resistance and etching resistance can be obtained. s is an integer of 0 to 3, and preferably 0 since excellent heat resistance and etching resistance can be obtained. R^{X} is a hydrogen atom or a methyl group, and preferably a methyl group since excellent curing properties can be obtained.

Examples of the group having a hydroxyl group include groups represented by the following formulas (X-5a) to (X-5e).

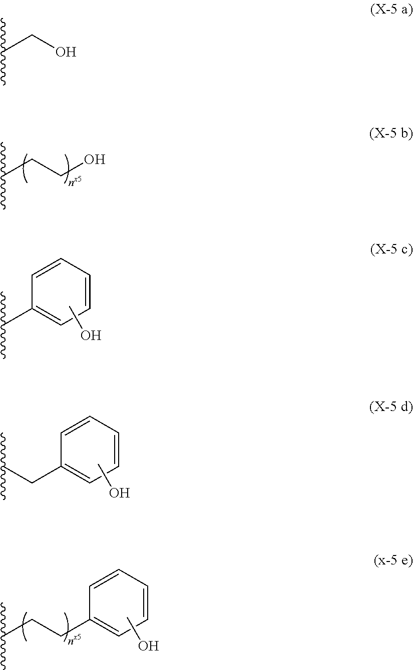

In the formulas (X-5b) and (X-5e), n^{x5} is an integer of 1 to 5, and preferably 1 since excellent heat resistance and etching resistance can be obtained.

Examples of the group having a glycidyl group include groups represented by the formulas (X-6a) to (X-6c).

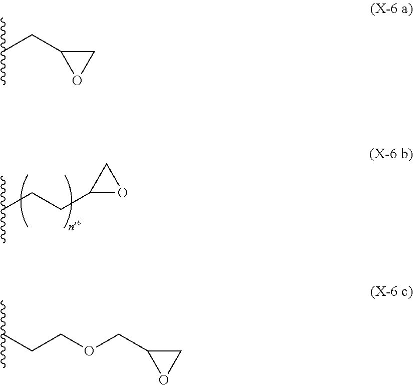

In the formula (X-6b), n^{x6} is an integer of 1 to 5.

Examples of the group having a vinyl phenylmethyl-containing group include groups represented by the formulas (X-7a) and (X-7b).

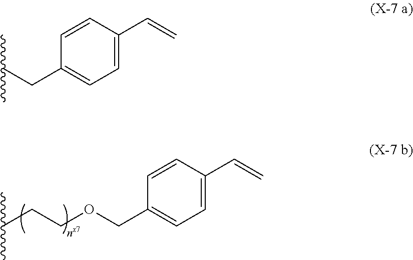

In the formula (X-7b), n^{x7} is an integer of 1 to 5, and preferably 1 since excellent heat resistance and etching resistance can be obtained.

Examples of groups having each alkynyl group include groups represented by the following formulas (X-8a) to (X-8h).

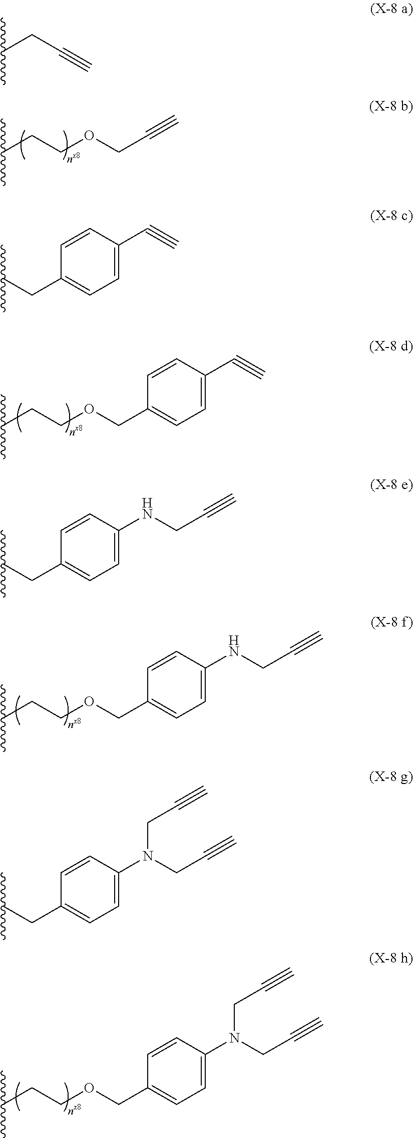

In the formulas (X-8b), (X-8d), (X-8f), and (X-8h), n^{x8} is an integer of 1 to 5.

Examples of the carbon-carbon double bond containing group include a (meth)acryloyl group, a substituted or unsubstituted vinyl phenyl group, and a group represented by the formula (X-9).

In addition, examples of the carbon-carbon triple bond containing group include a substituted or unsubstituted ethynyl group, a substituted or unsubstituted propargyl group, and groups represented by the formulas (X-10a) and (X-10b).

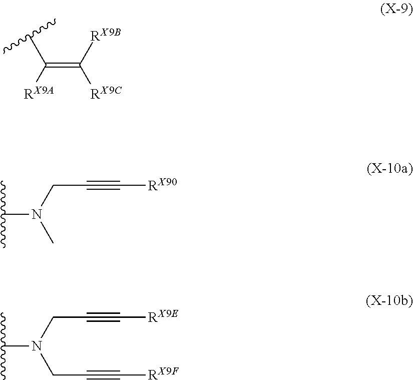

In the formula (X-9), R^{X9A}, R^{X9B} and R^{X9}c are each independently a hydrogen atom or a monovalent hydrocarbon group having 1 to 20 carbon atoms. In the formulas (X-10a) and (X-10b), R^{X9D}, R^{X9E} and R^{X9F} are each independently a hydrogen atom or a monovalent hydrocarbon group having 1 to 20 carbon atoms.

The “dissociable group” in the present embodiment refers to a group that dissociates in the presence of a catalyst or without a catalyst. Among dissociable groups, the acid dissociation group refers to a group that is cleaved in the presence of an acid to cause a change into an alkali soluble group or the like.

Examples of the alkali soluble group include a phenolic hydroxy group, a carboxy group, a sulfonic acid group, and a hexafluoroisopropanol group. Among them, from the viewpoint of ease in obtaining introducing reagents, a phenolic hydroxy group and a carboxy group are preferable, and a phenolic hydroxy group is more preferable.

The acid dissociable group preferably has the property of causing chained cleavage reaction in the presence of an acid, for achieving pattern formation with high sensitivity and high resolution.

The acid dissociation group can be arbitrarily selected for use from among, for example, those proposed in hydroxystyrene resins, (meth)acrylic acid resins, and the like for use in chemically amplified resist compositions for KrF or ArF.

Examples of the acid dissociation group include, for example, those described in International Publication No. WO 2016/158168. Examples of the acid dissociation group include a 1-substituted ethyl group, a 1-substituted n-propyl group, a 1-branched alkyl group, a silyl group, an acyl group, a 1-substituted alkoxymethyl group, a cyclic ether group, a thioether group, a trityl group, an alkoxycarbonyl group (e.g., —C(O)OC(CH₃)₃), and an alkoxycarbonylalkyl group (e.g., —(CH₂)ₙC(O)OC(CH₃)₃, provided that n=1 to 4). In the present embodiment, when each functional group (excluding dissociable groups) described above as a constituent of the compound is overlapped with a dissociable group, those having no dissociation properties are treated as corresponding to each functional group and those having dissociation properties are treated as corresponding to dissociable groups, based on the presence or absence of dissociation properties.

Examples of the substituent for the dissociable group include a halogen atom, an alkyl group, an aryl group, an aralkyl group, an alkynyl group, an alkenyl group, an acyl group, an alkoxycarbonyl group, an alkyloyloxy group, an aryloyloxy group, a cyano group, and a nitro group. These groups may have a heteroatom.

Examples of the halogen atom include a fluorine atom, a chlorine atom, a bromine atom, and an iodine atom.

For the alkyl group, the above description can be referred to, and examples thereof include an alkyl group having 1 to 10 carbon atoms such as a methyl group, a tert-butyl group, a cyclohexyl group, and an adamantyl group.

For the aryl group, the above description can be referred to, and an aryl group having 6 to 20 carbon atoms is preferable. The aryl group may further have a substituent such as a halogen atom and an alkyl group having 1 to 5 carbon atoms.

Examples of the aralkyl group include a benzyl group and a phenethyl group. The aralkyl group may further have a substituent such as a halogen atom and an alkyl group having 1 to 5 carbon atoms.

For the alkynyl group, the above description can be referred to.

Examples of the acyl group include an aliphatic acyl group having 1 to 6 carbon atoms such as a formyl group and an acetyl group, and an aromatic acyl group such as a benzoyl group.

Examples of the alkoxycarbonyl group include an alkoxycarbonyl group having 2 to 5 carbon atoms such as a methoxycarbonyl group.

Examples of the alkyloyloxy group include an acetoxy group.

Examples of the aryloxy group include a benzoyloxy group.

Examples of the heteroatom include an oxygen atom, a sulfur atom, a selenium atom, a nitrogen atom, and a phosphorus atom. A carbon atom of each group may be substituted with the heteroatom.

In the case where each group includes a substituent, the number of carbon atoms in each group described in the present embodiment is the total number of carbon atoms including the substituent thereof.

Hereinafter, structure examples of compounds and/or resin included in the underlayer film forming composition for lithography of the present embodiment will be described, but are not limited to the followings.

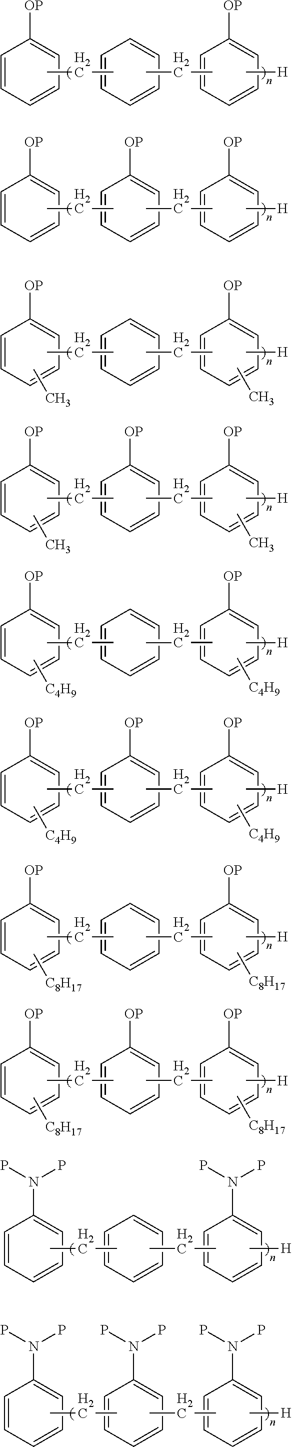

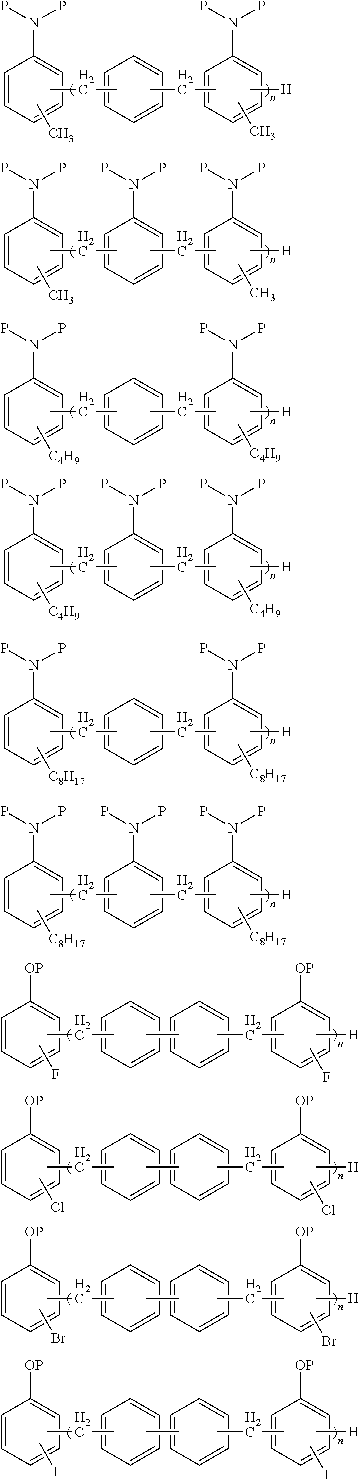

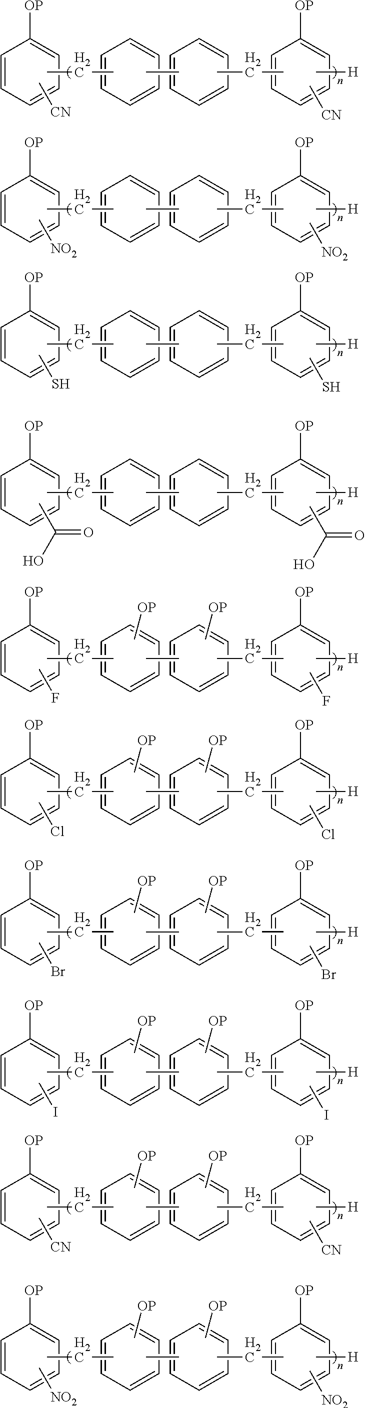

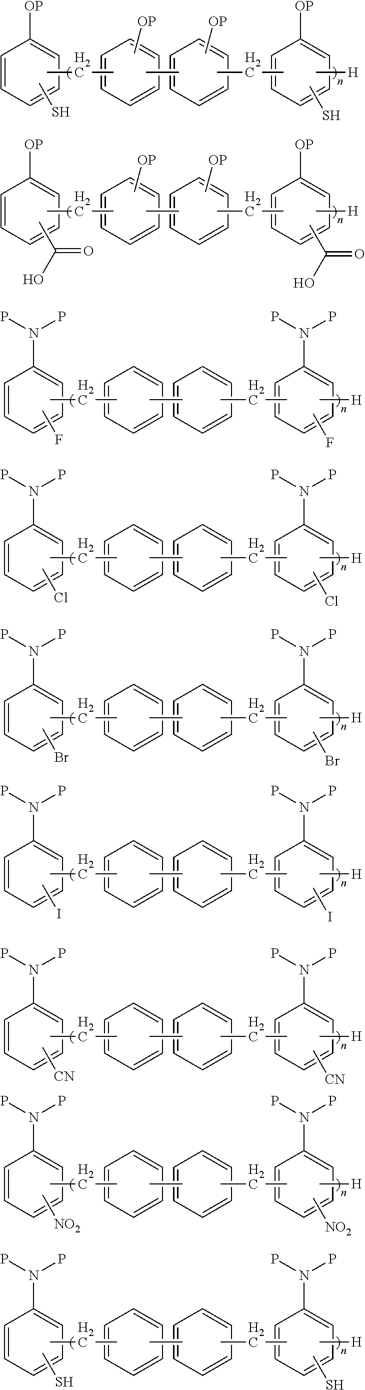

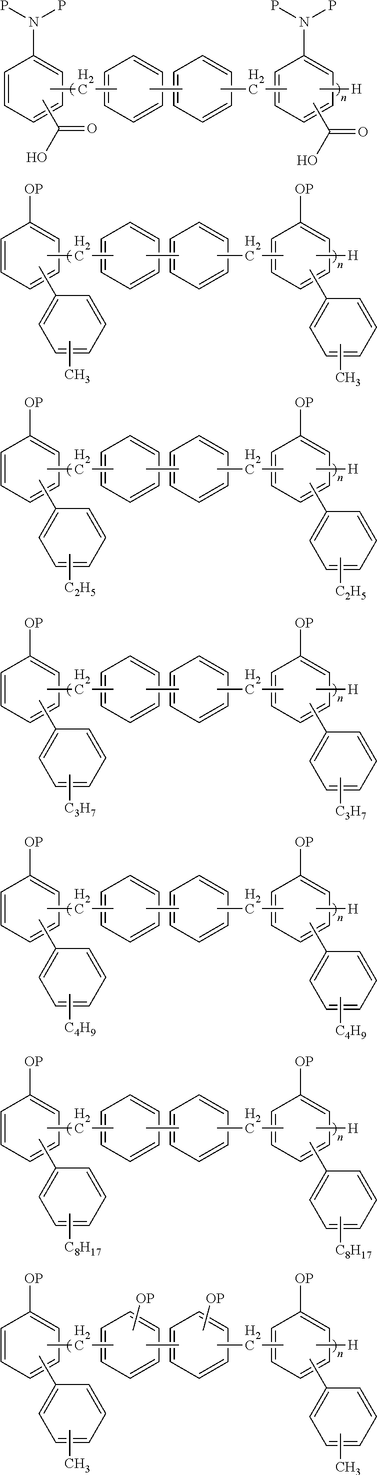

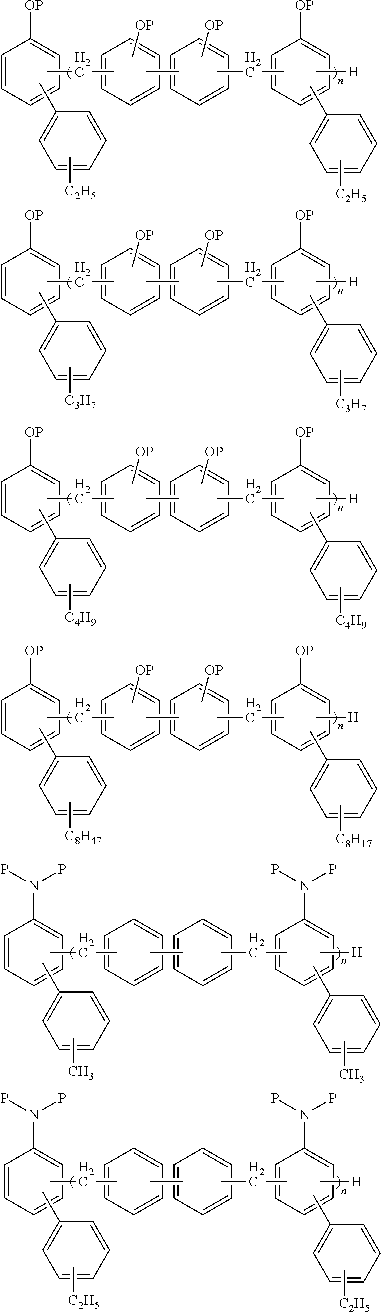

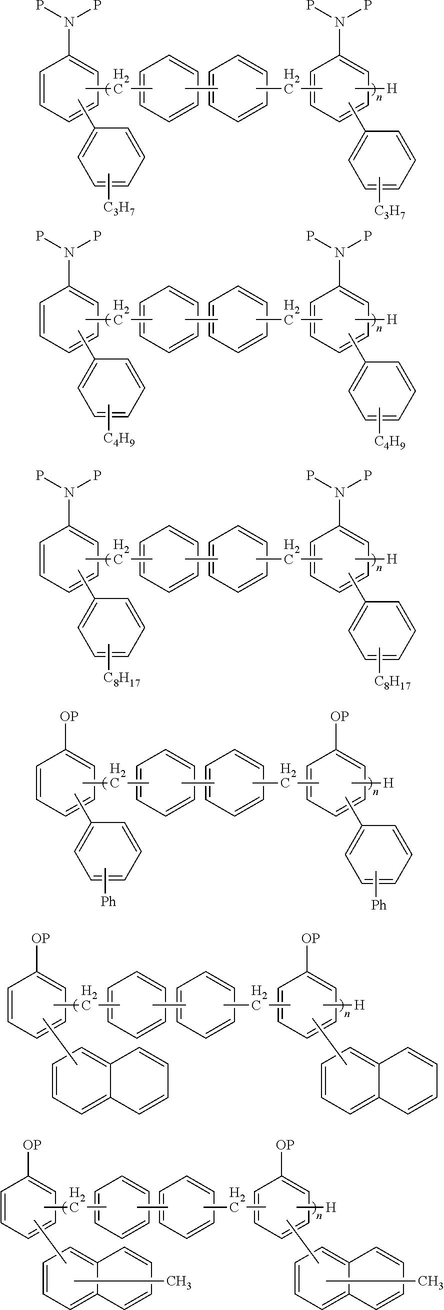

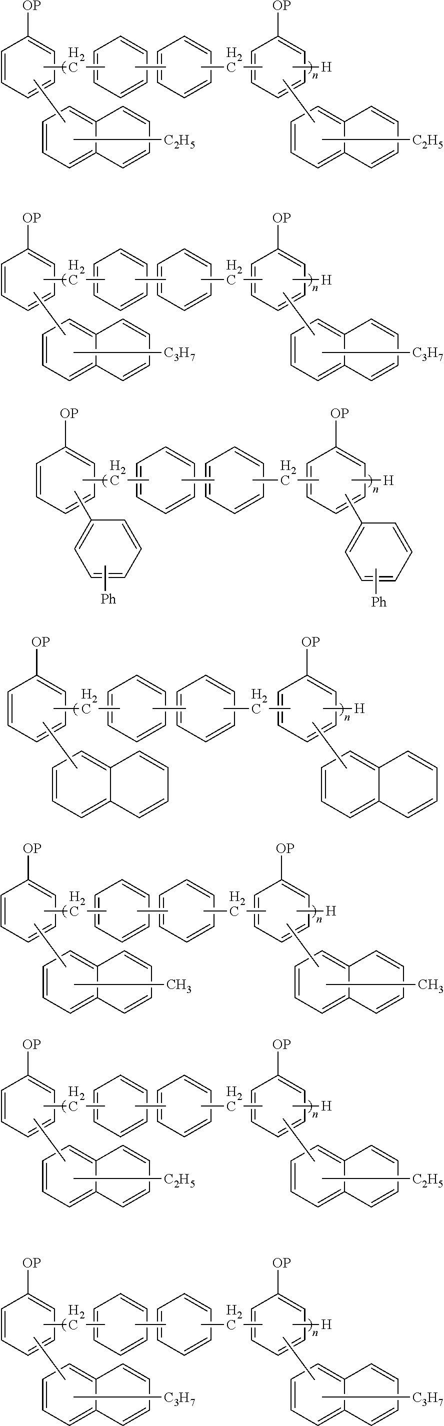

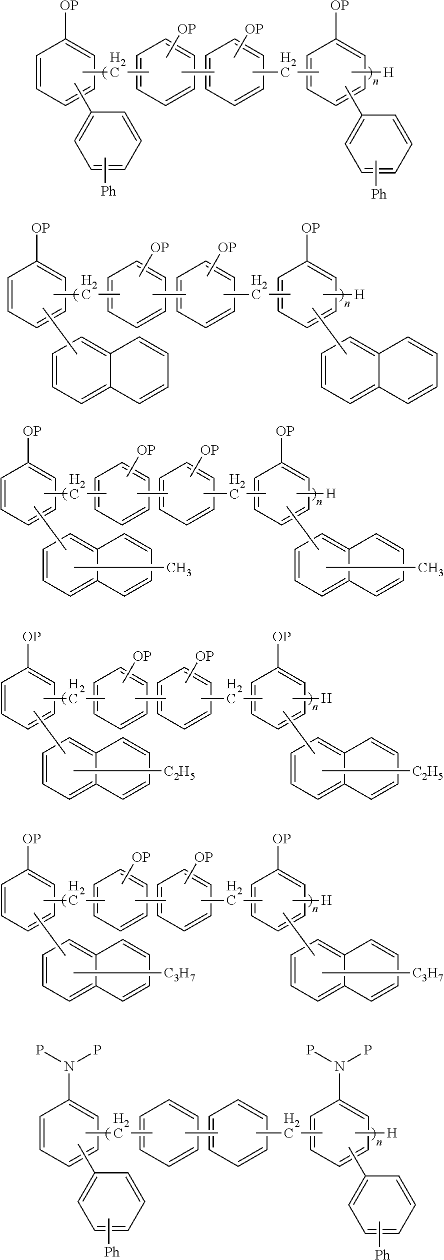

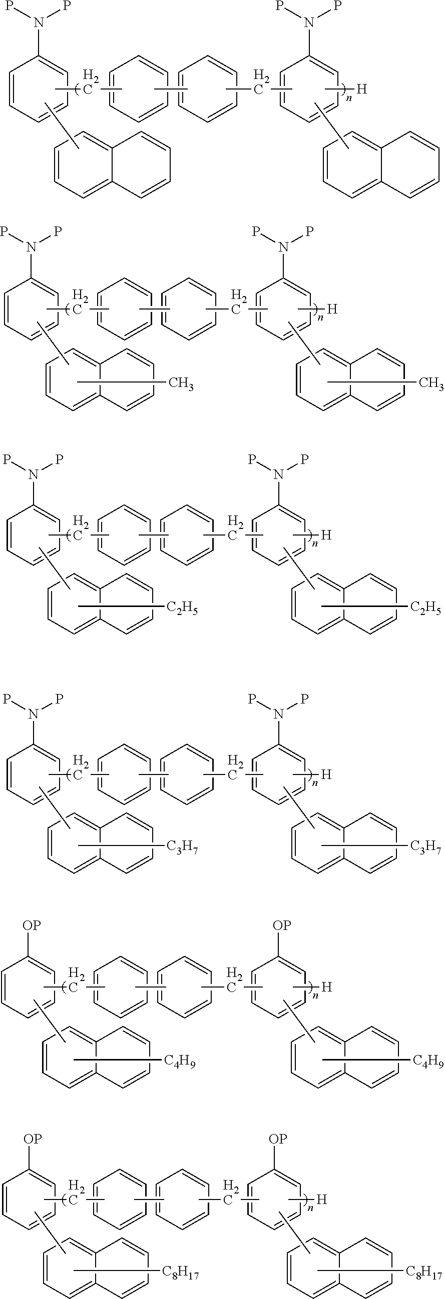

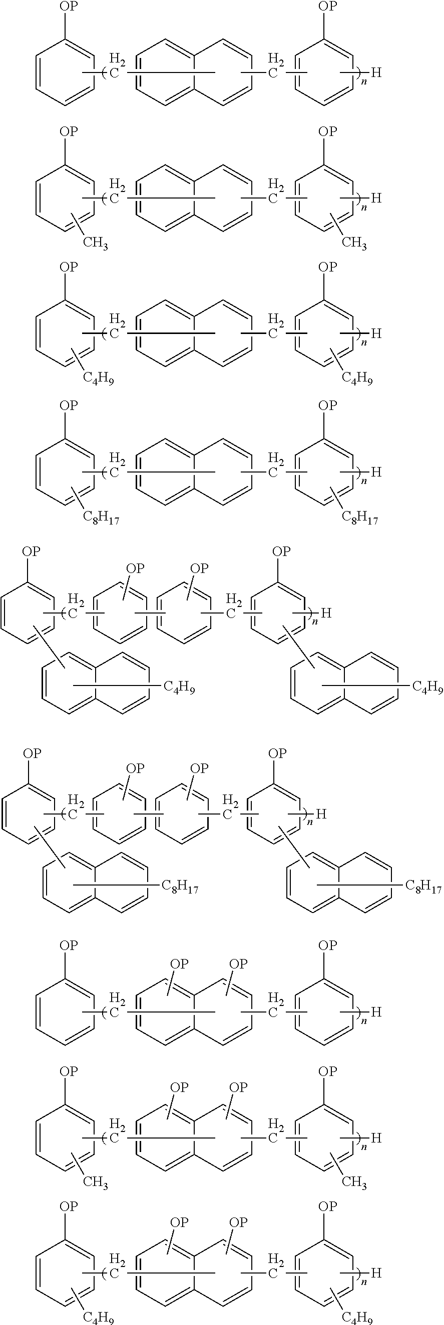

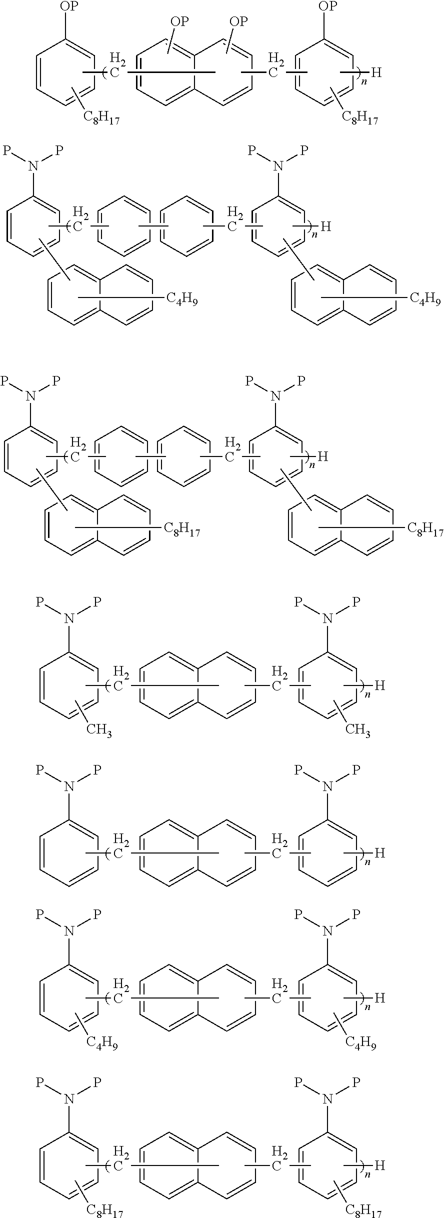

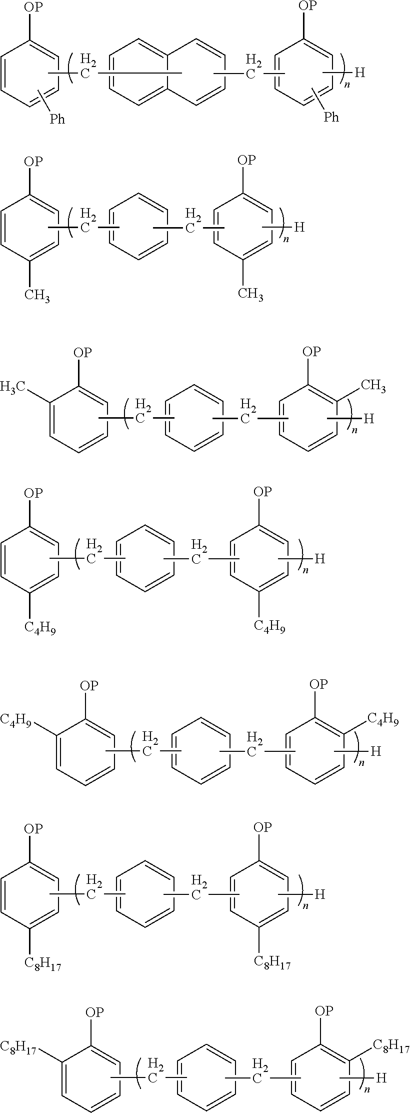

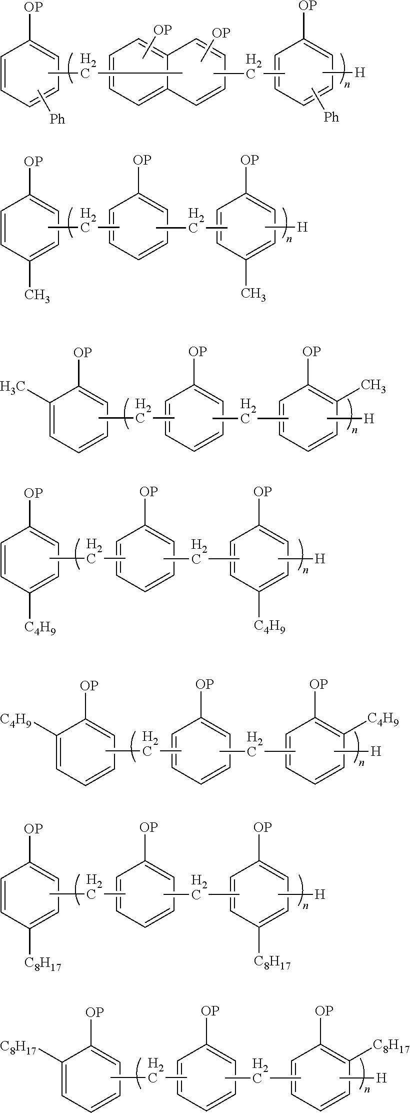

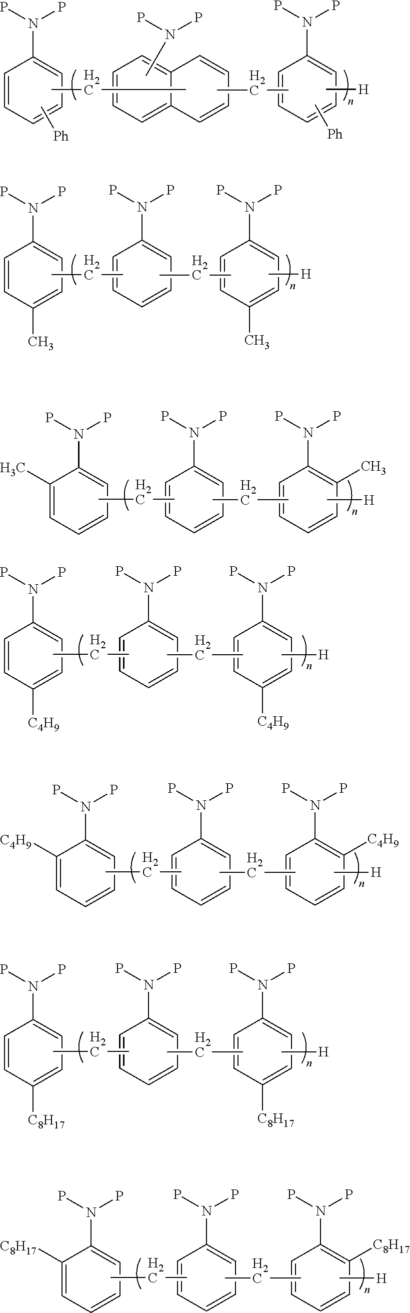

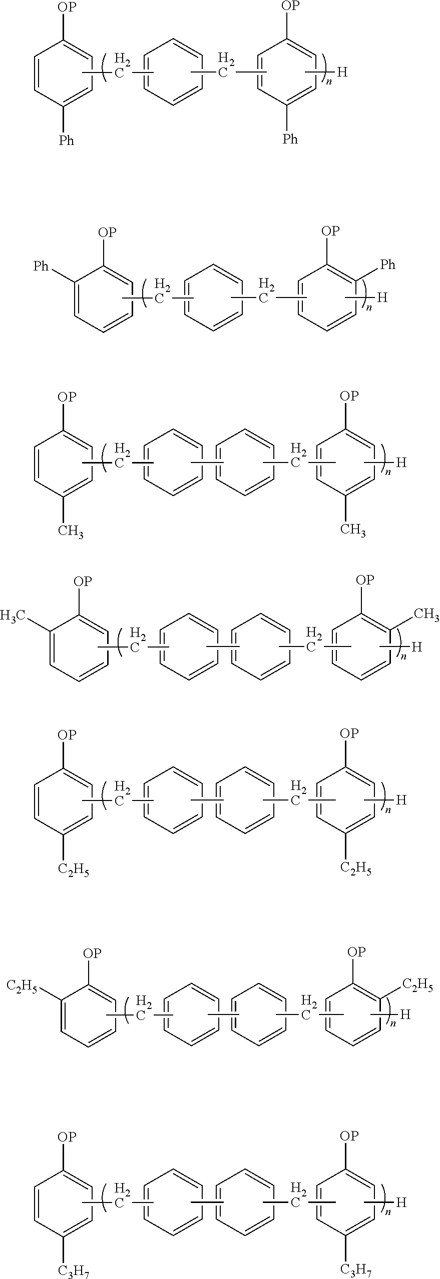

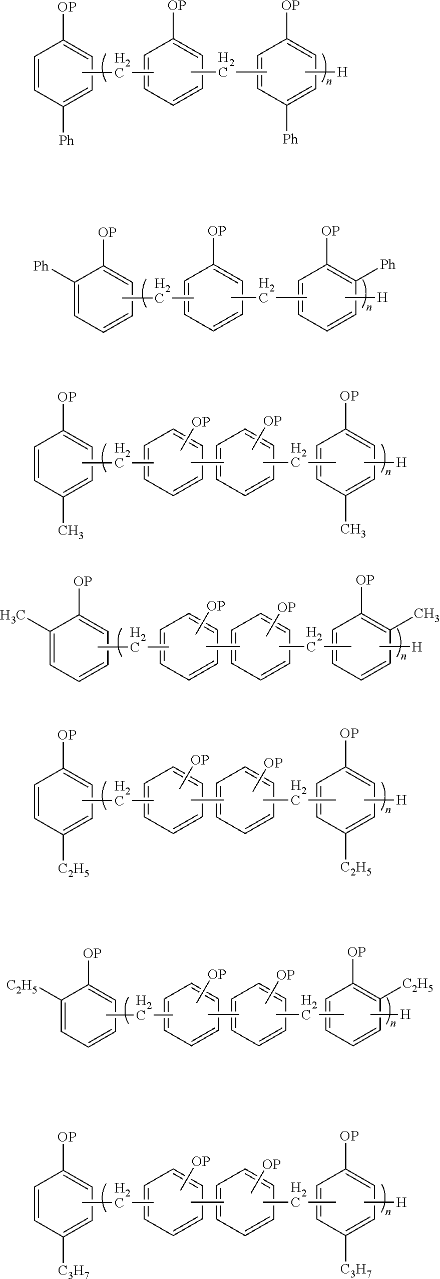

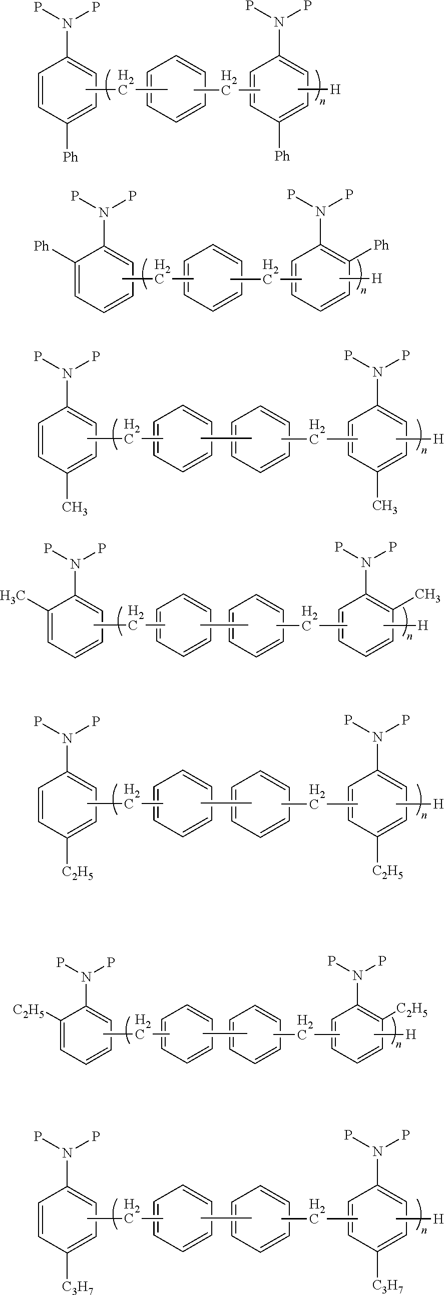

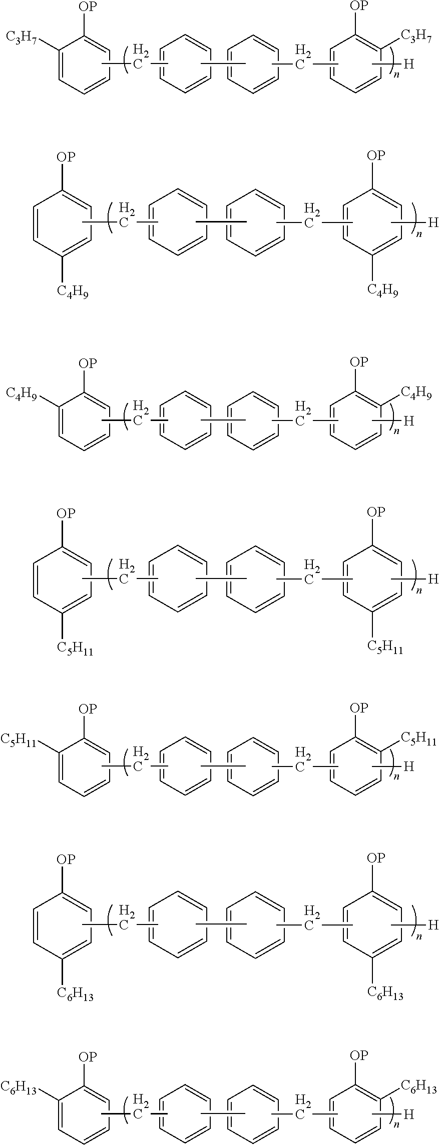

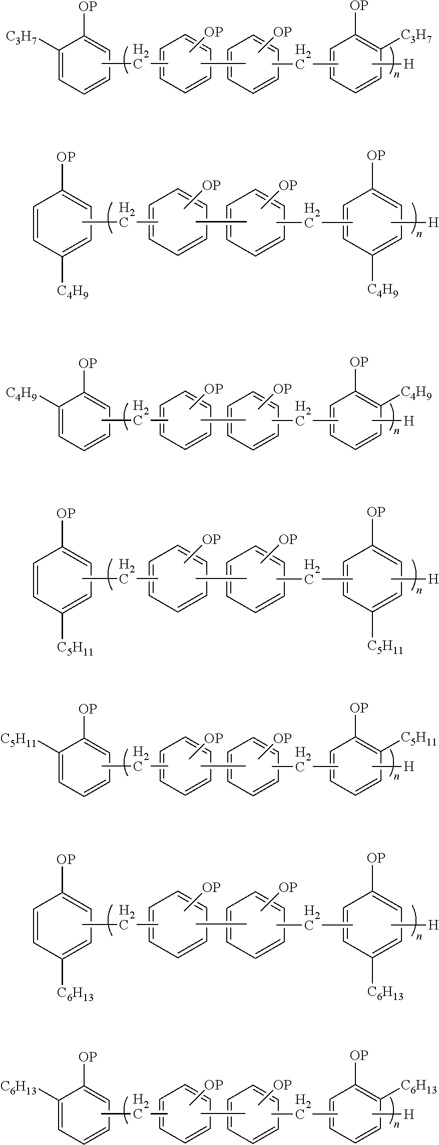

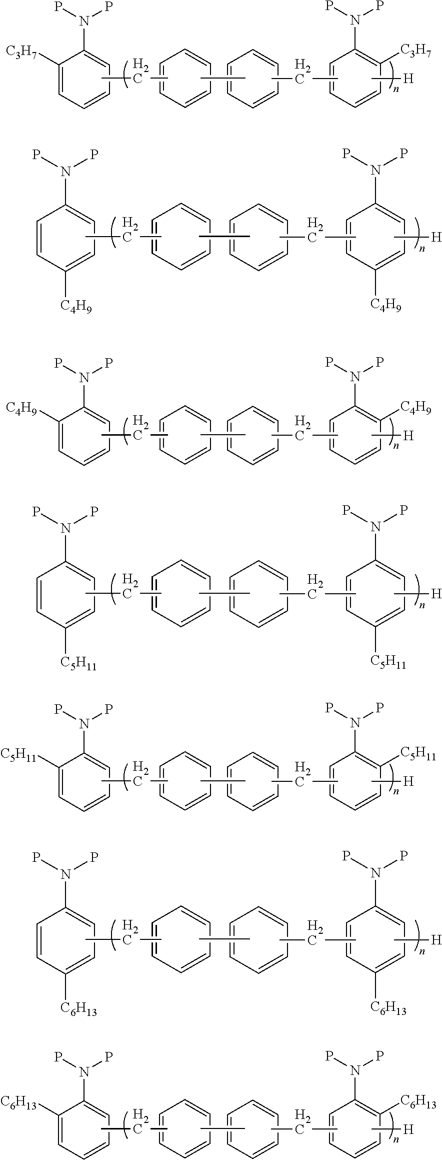

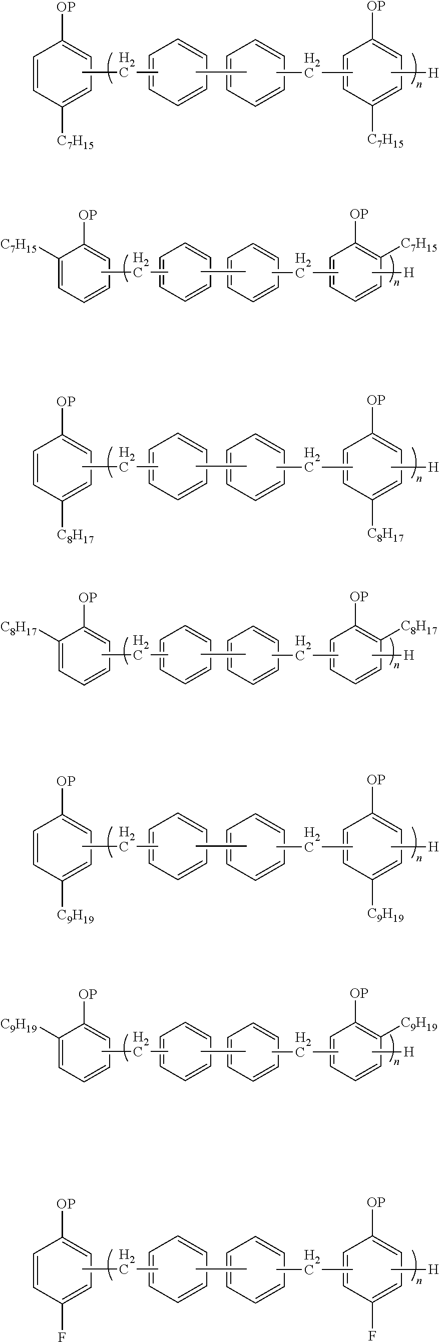

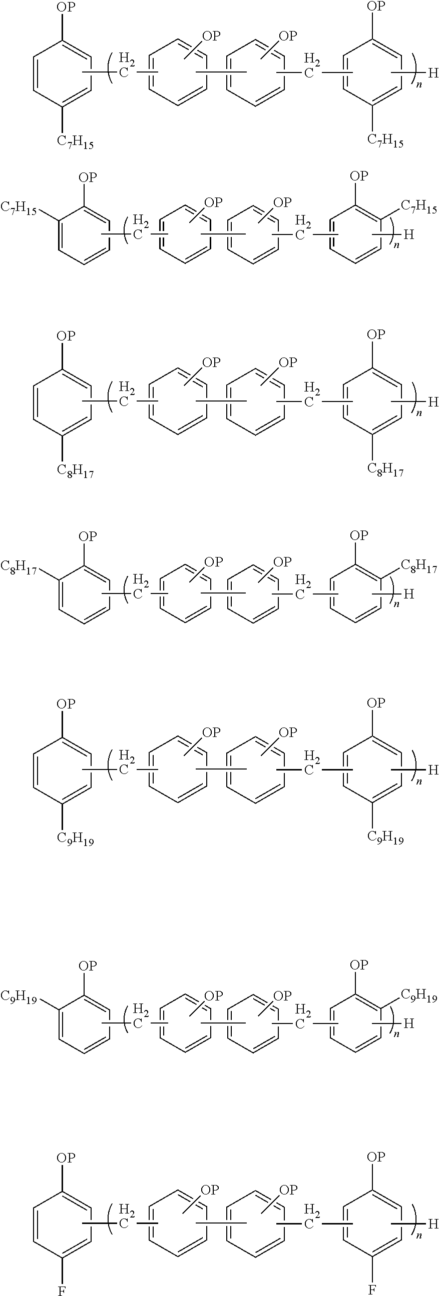

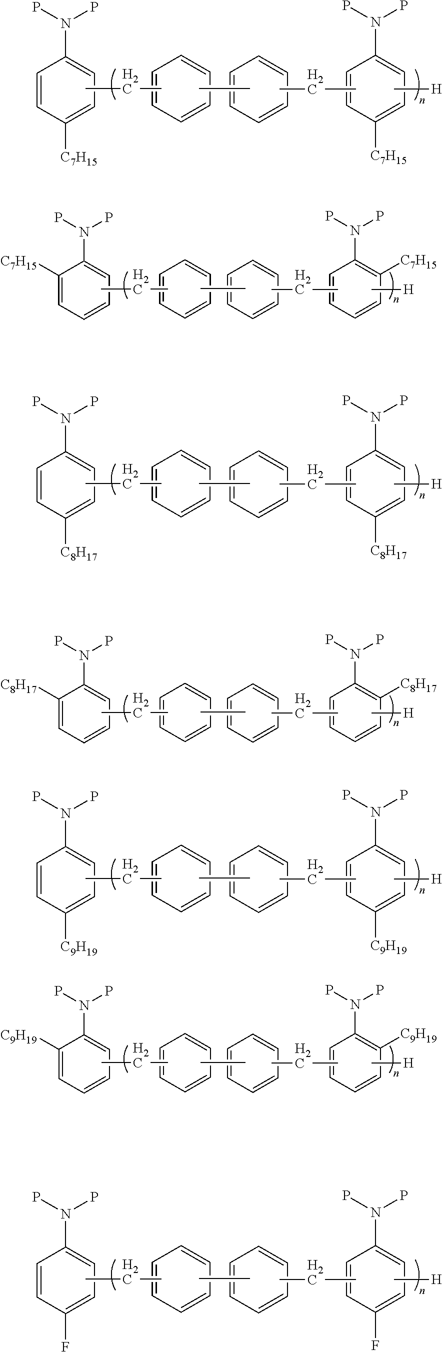

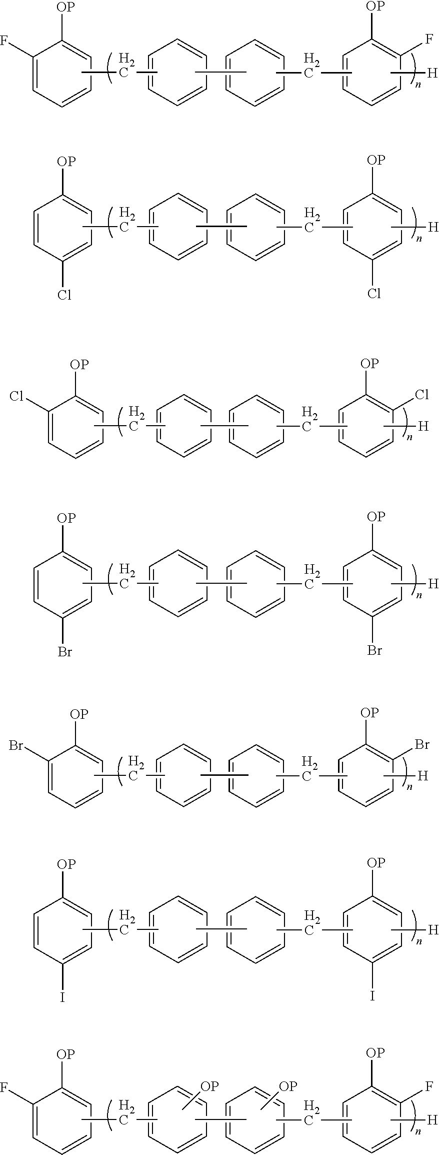

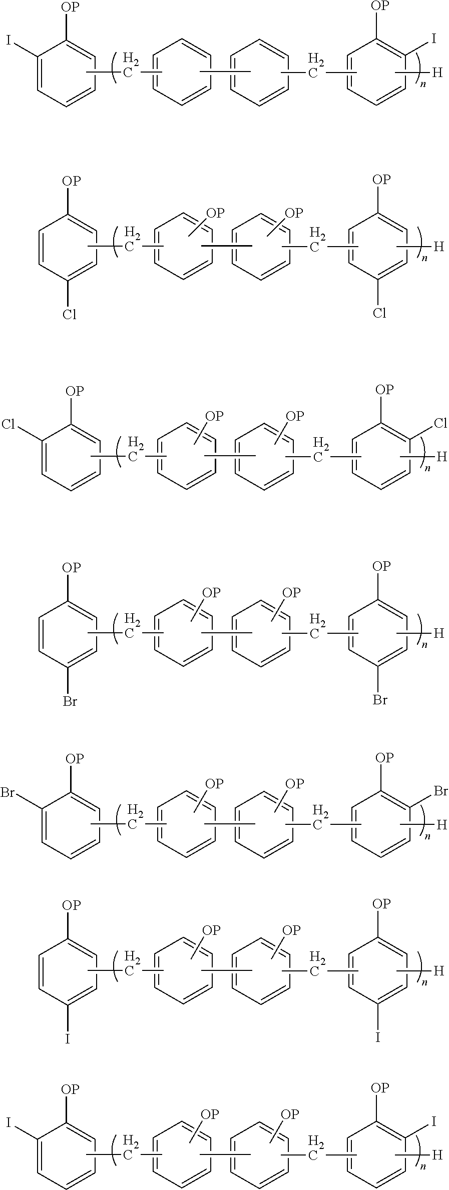

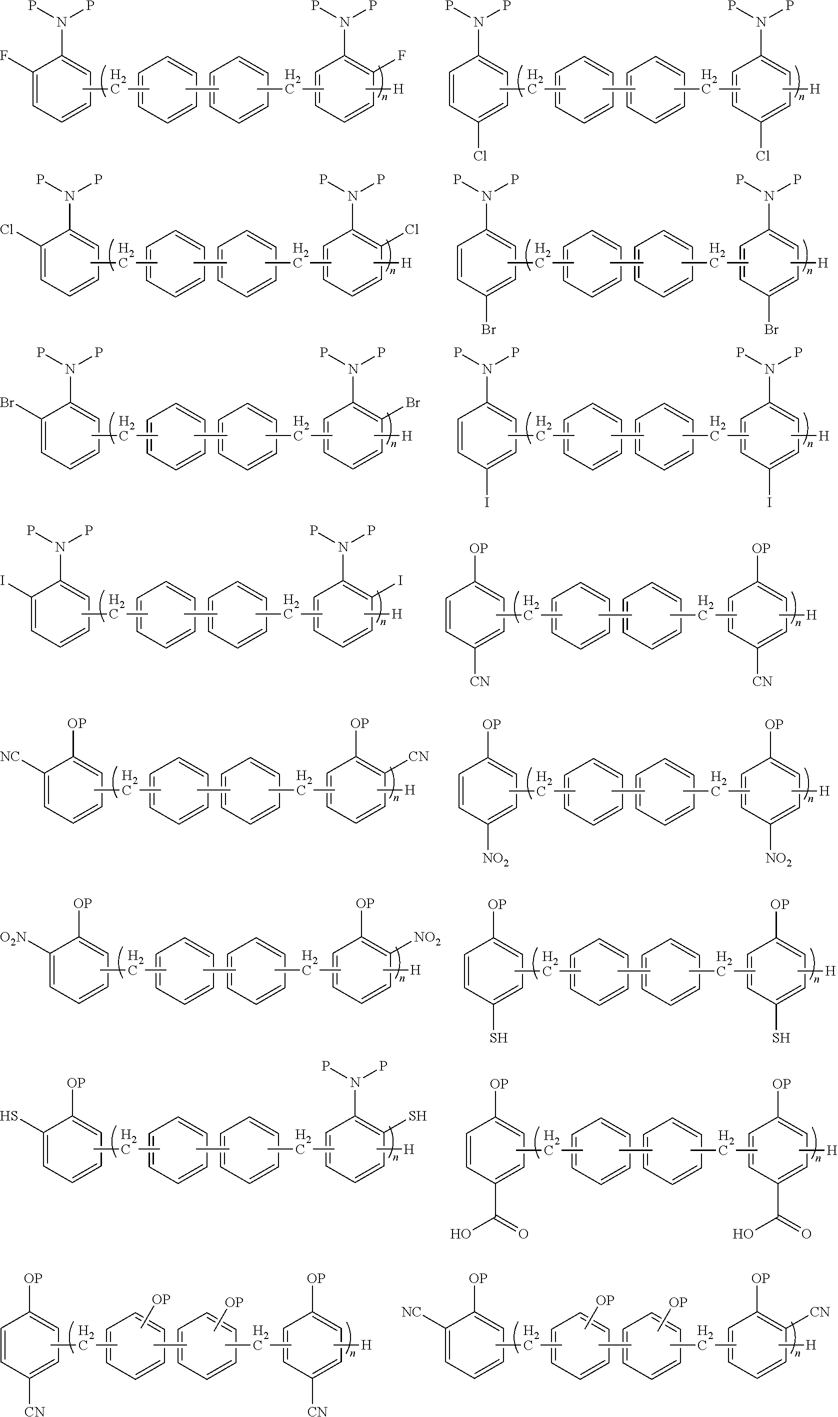

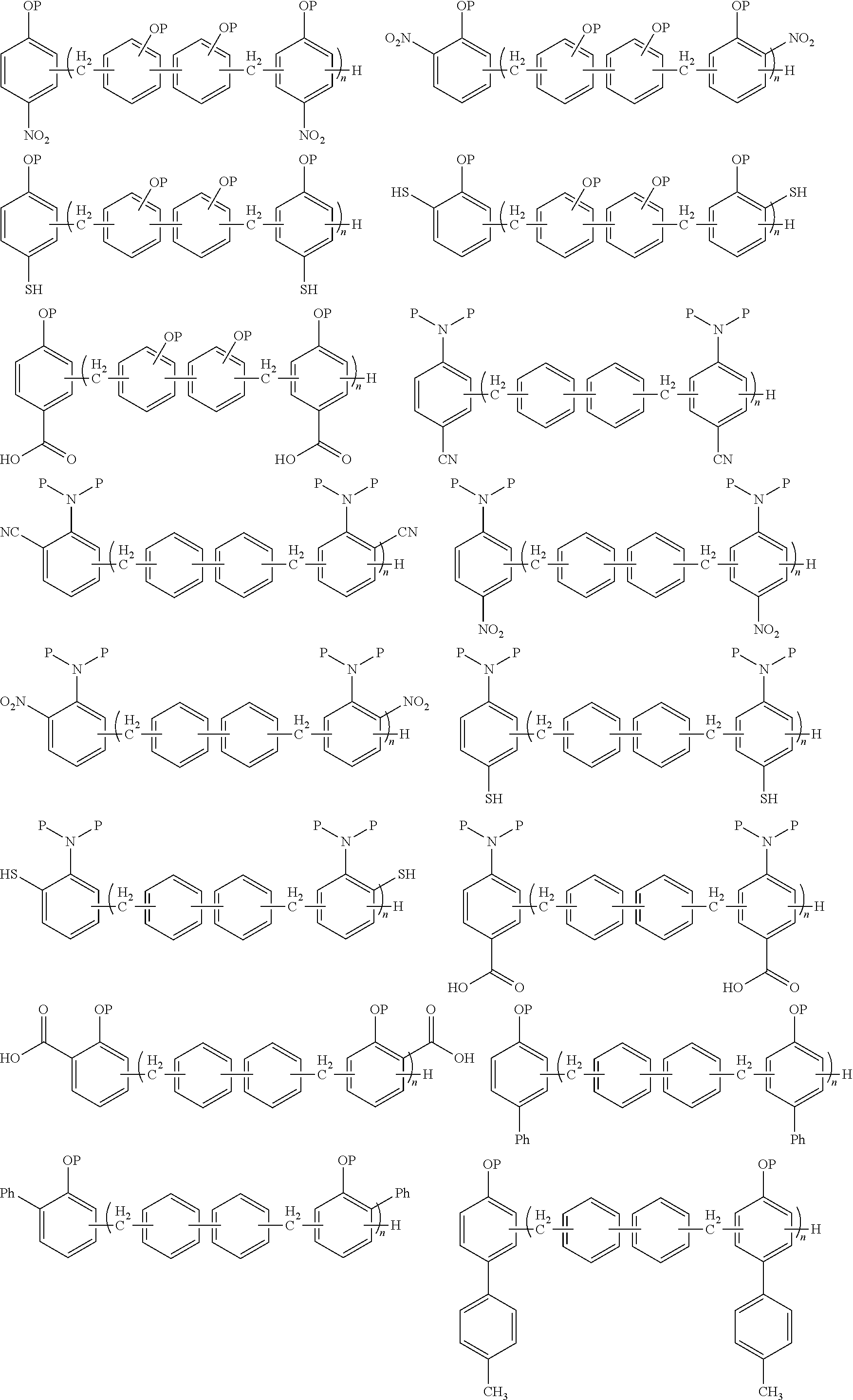

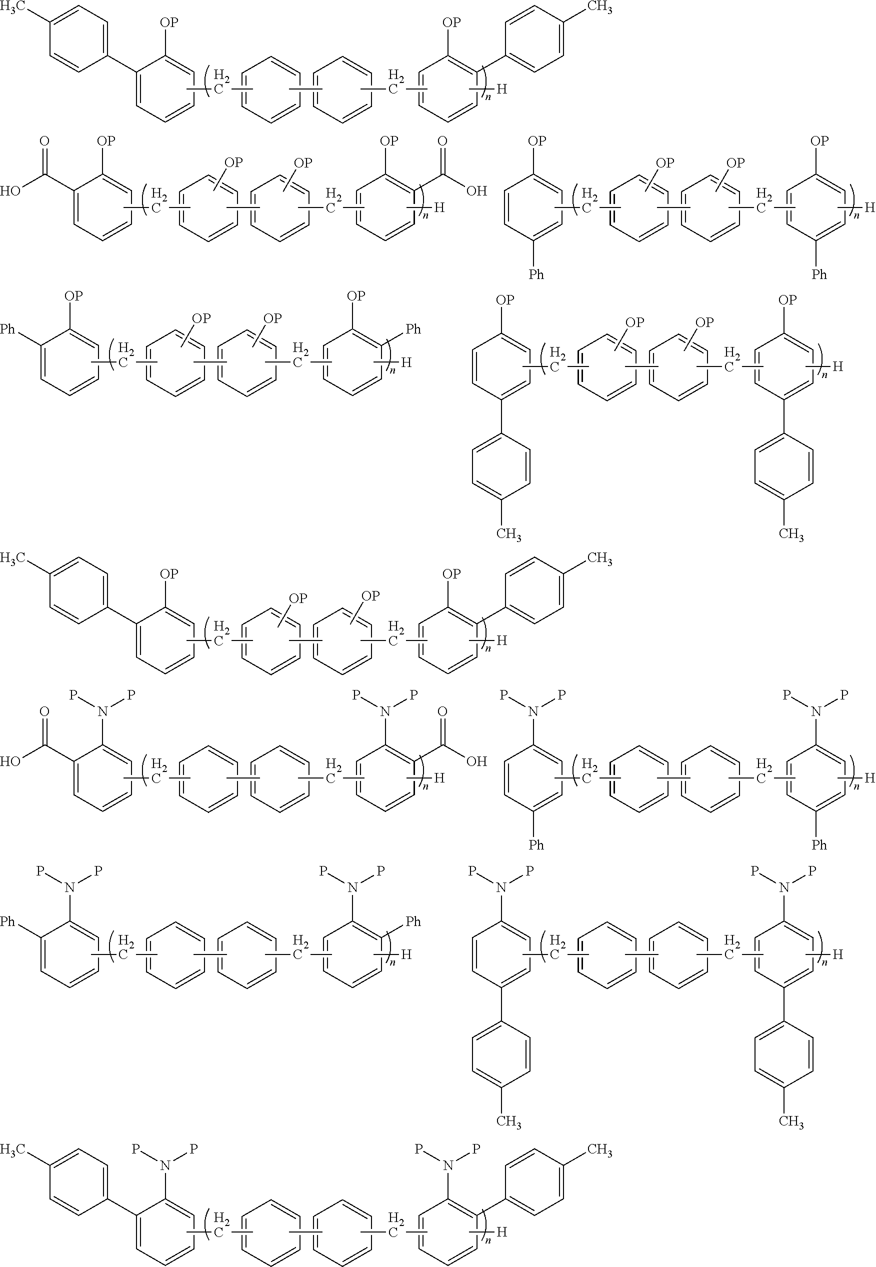

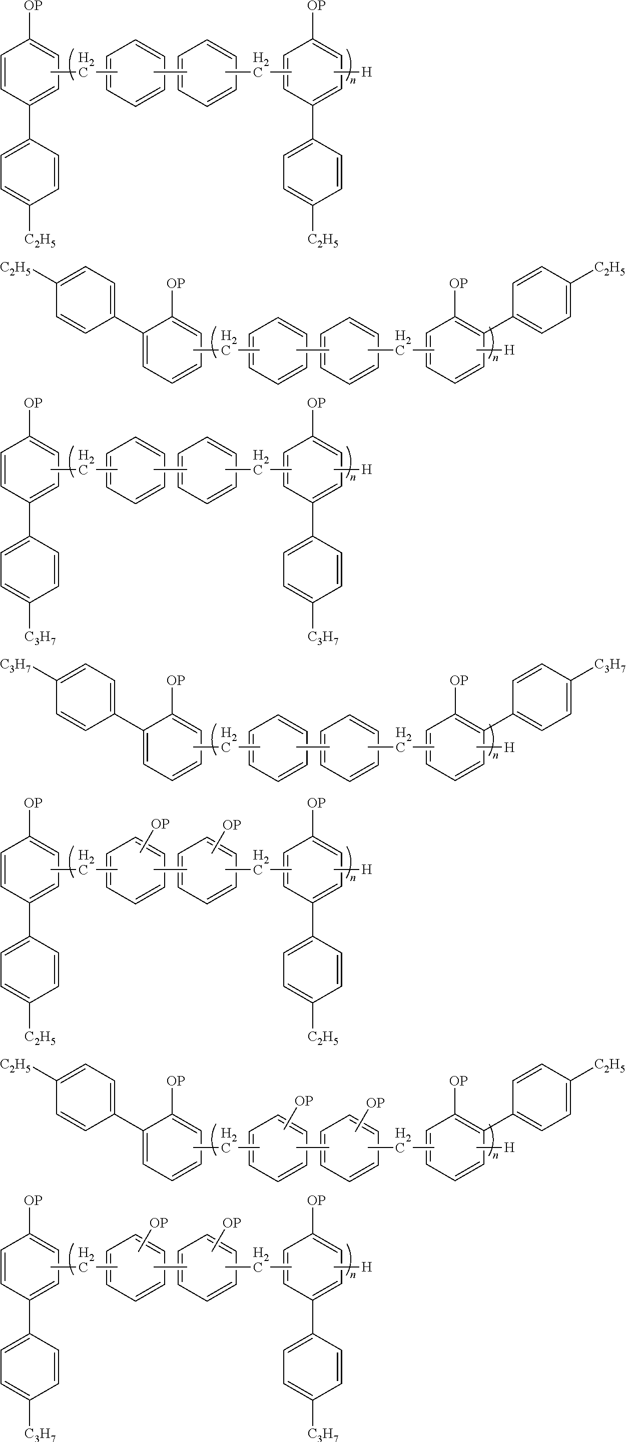

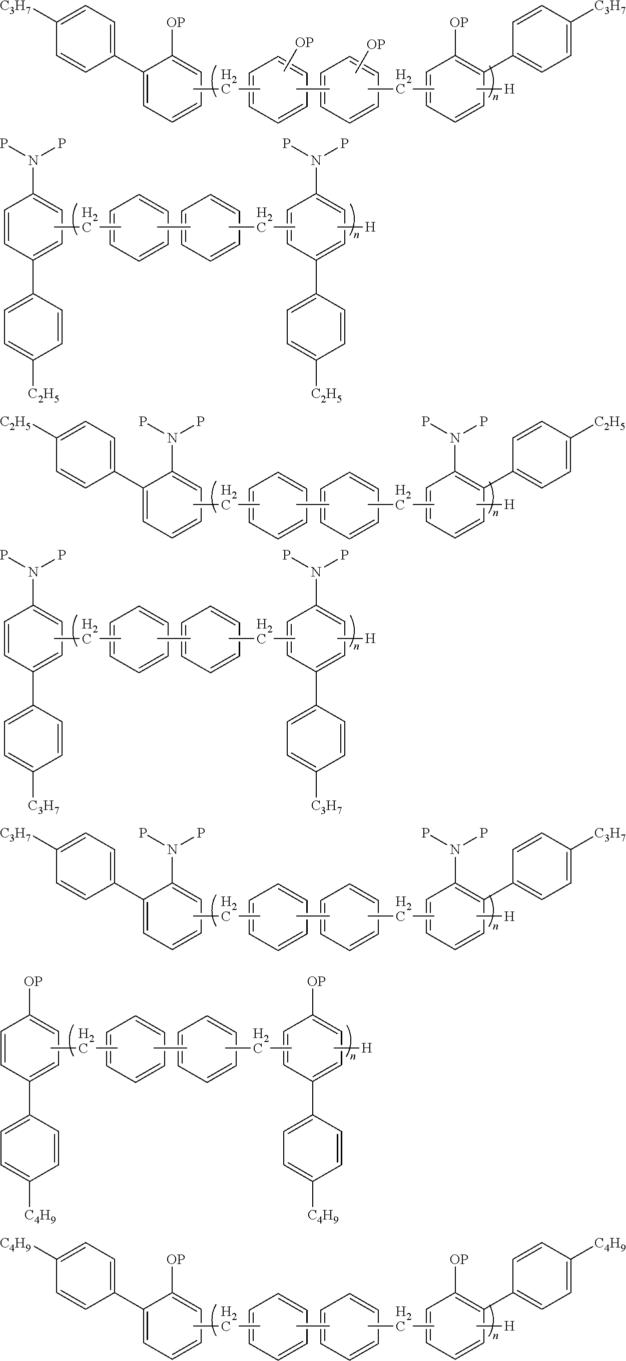

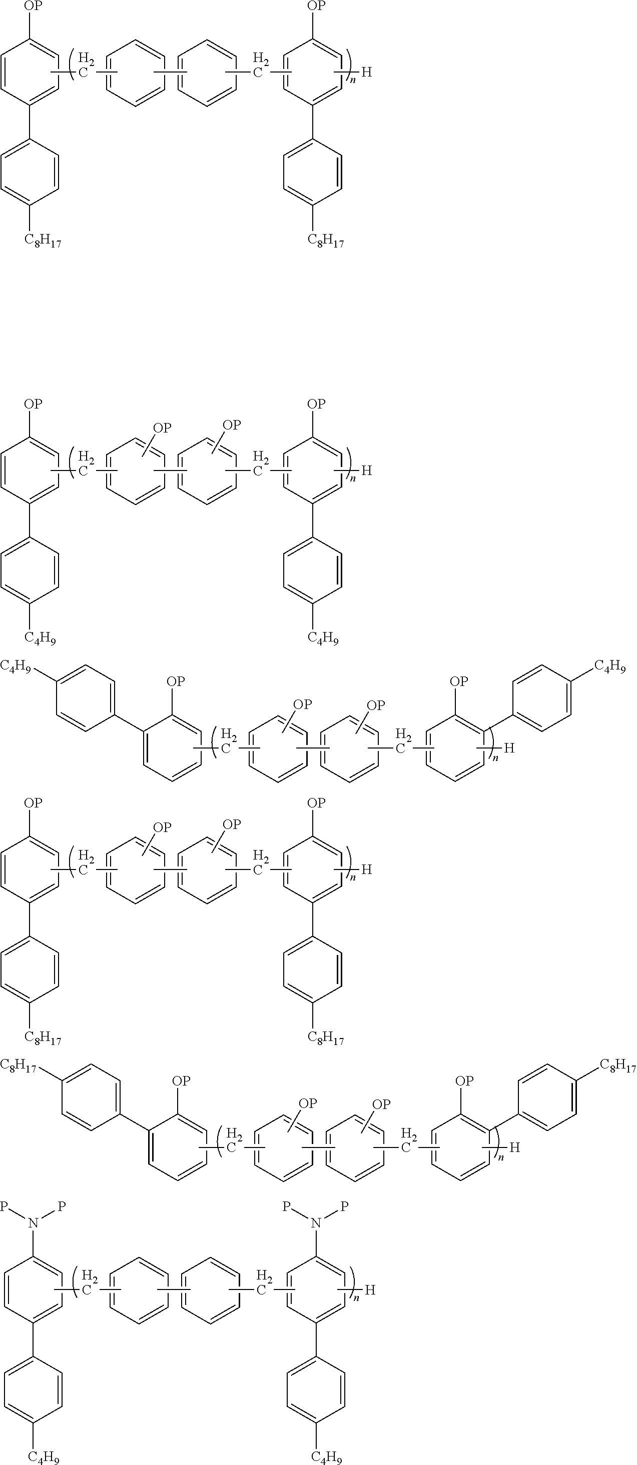

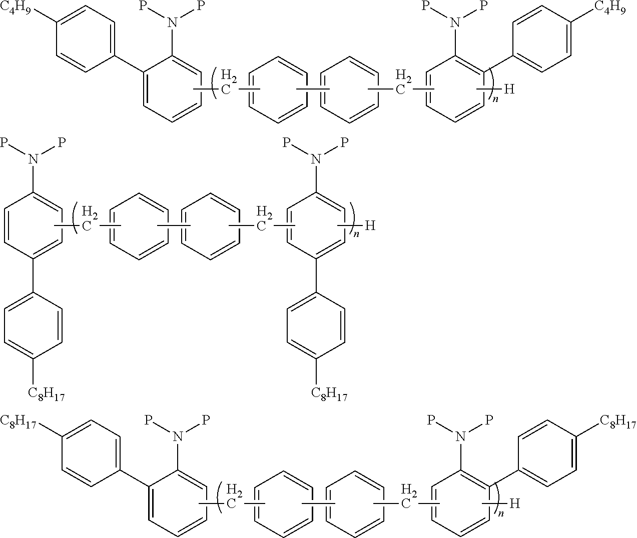

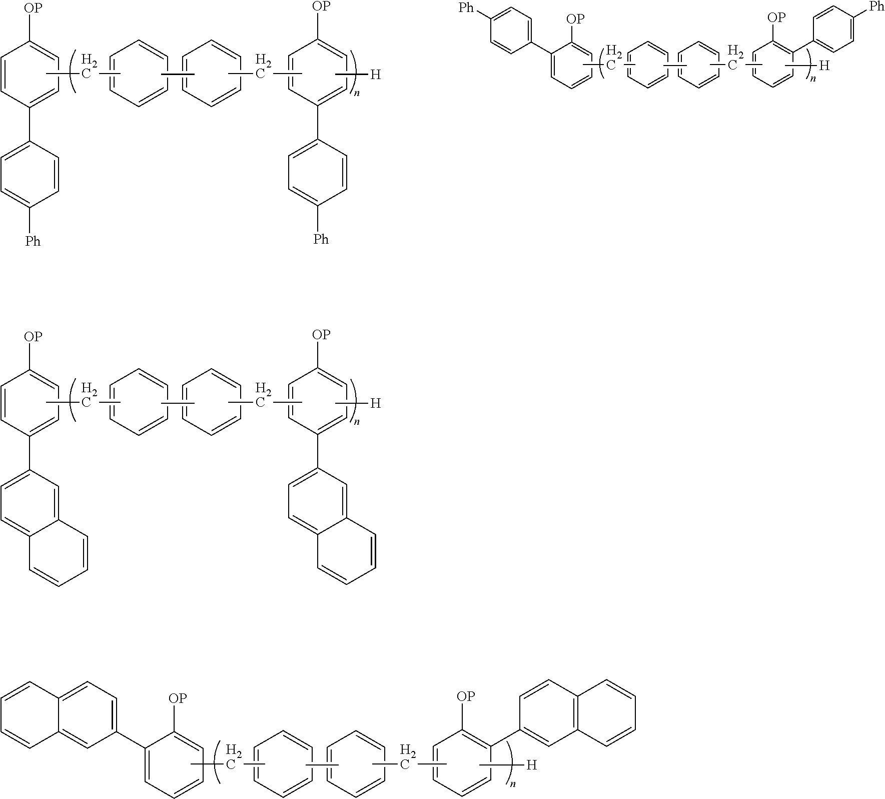

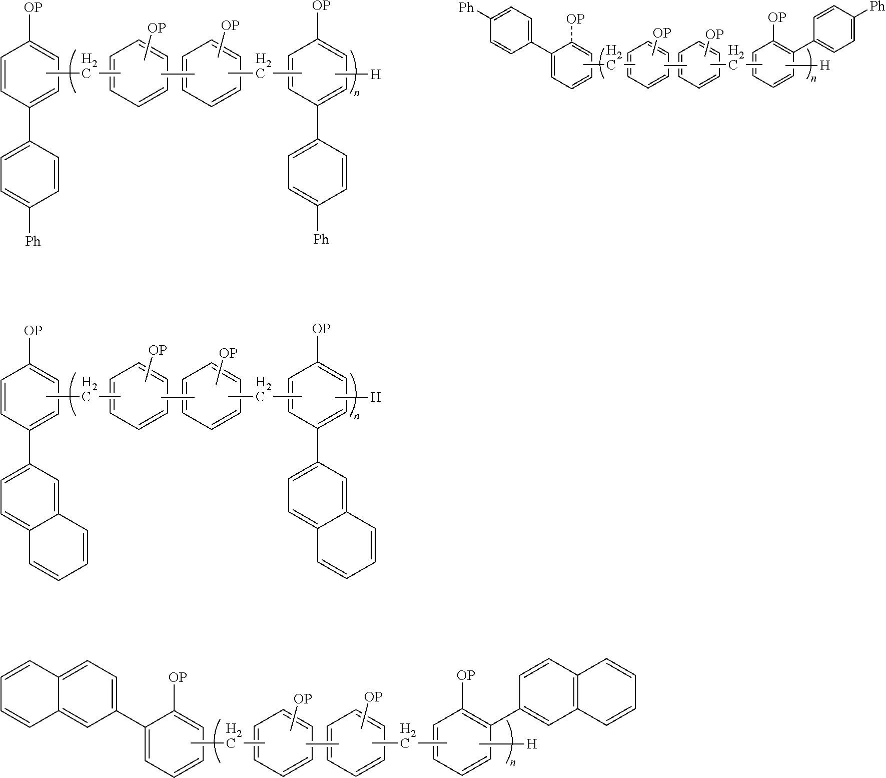

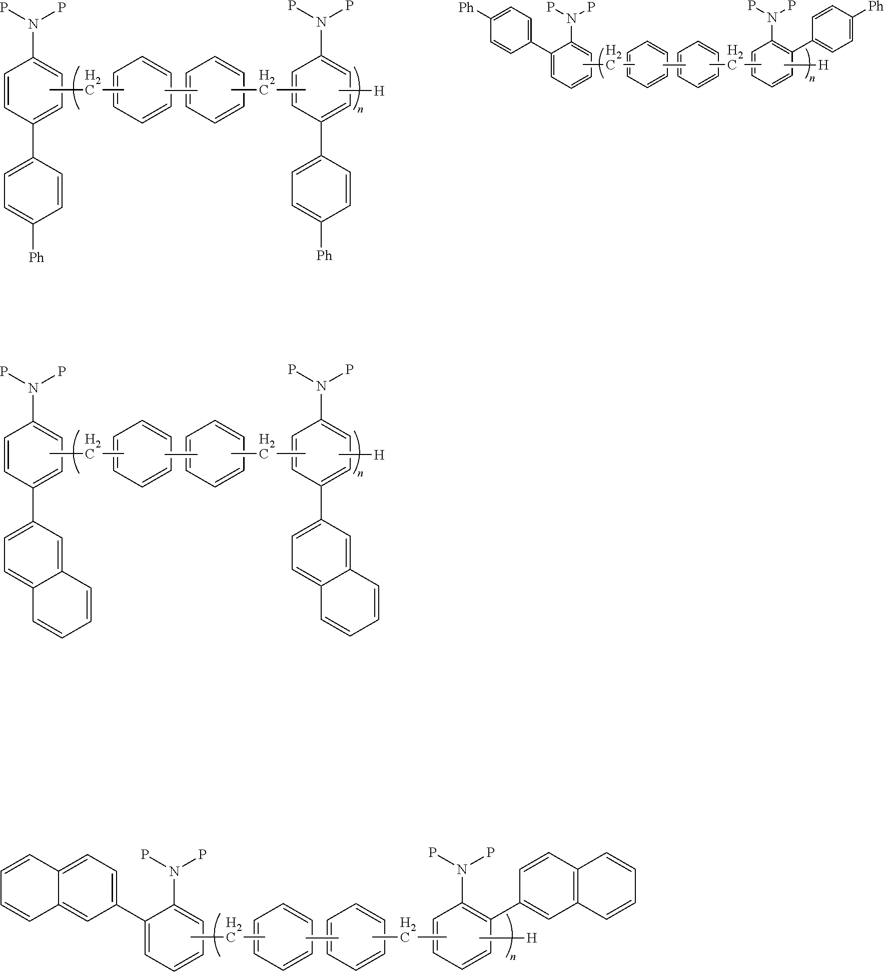

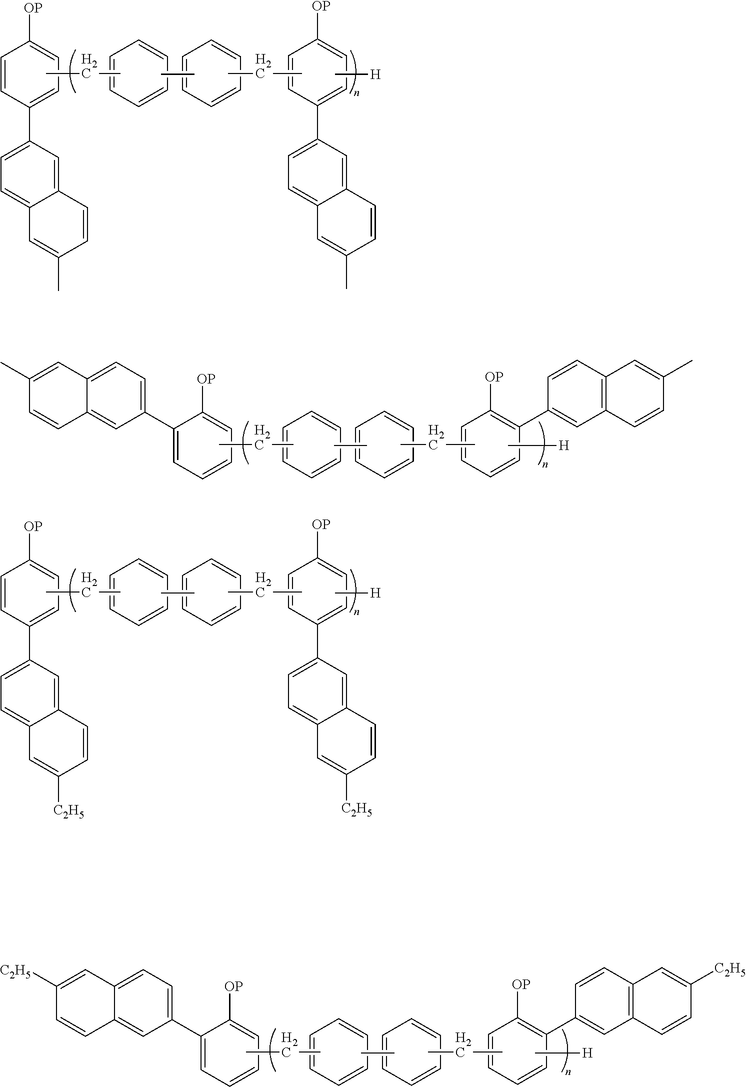

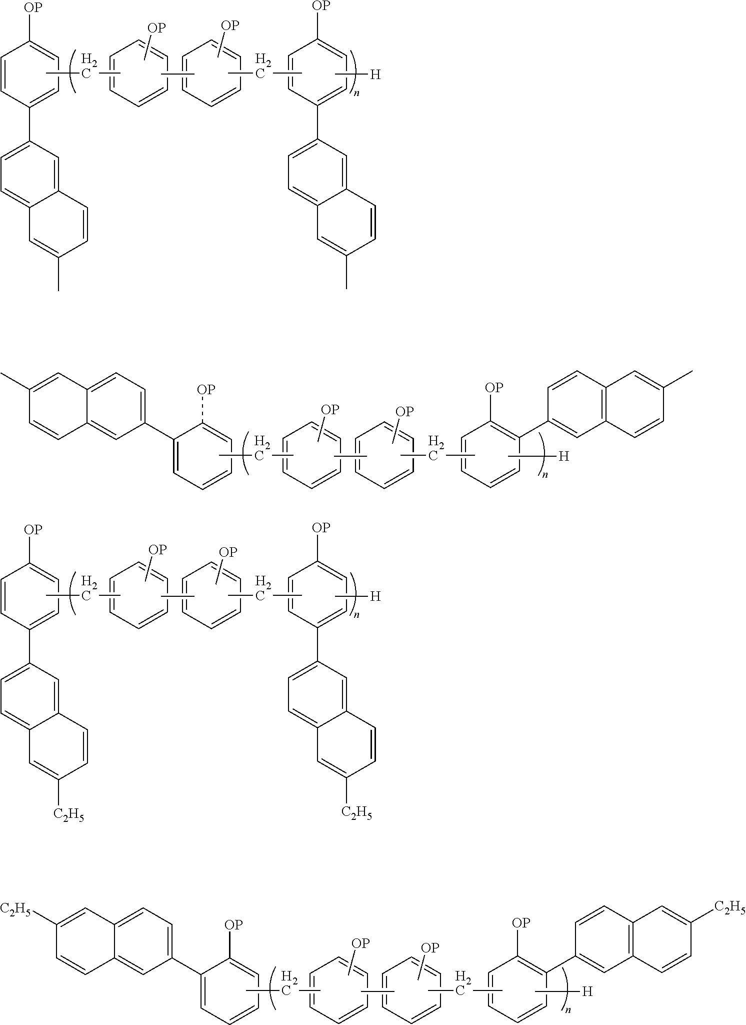

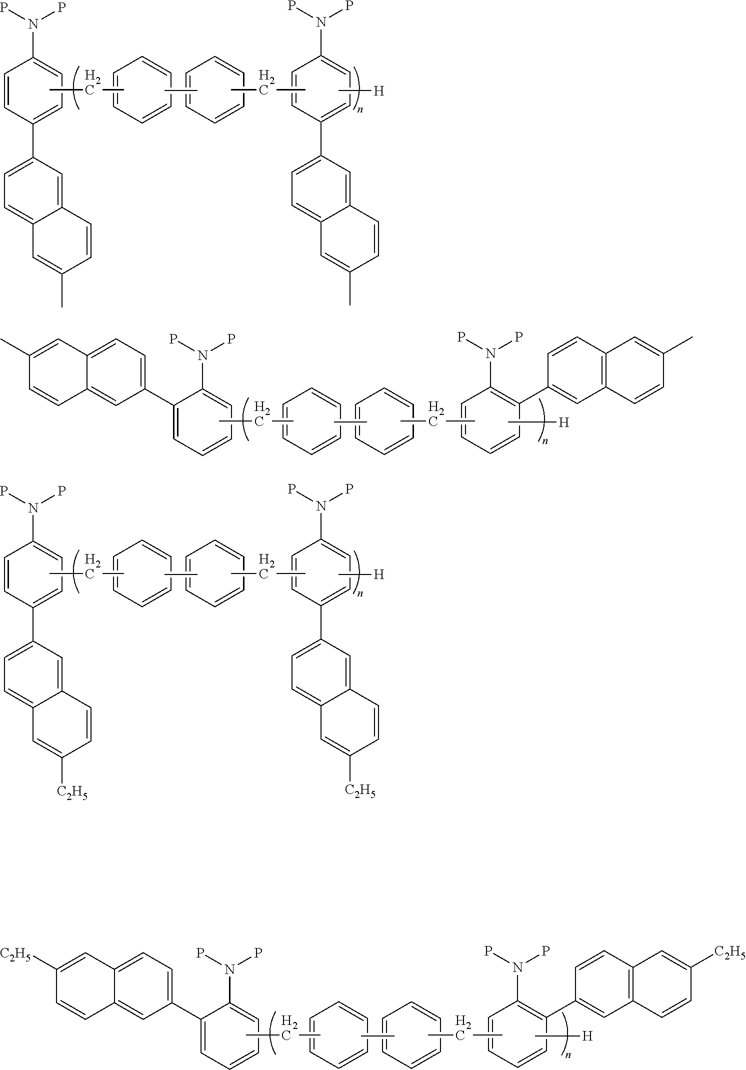

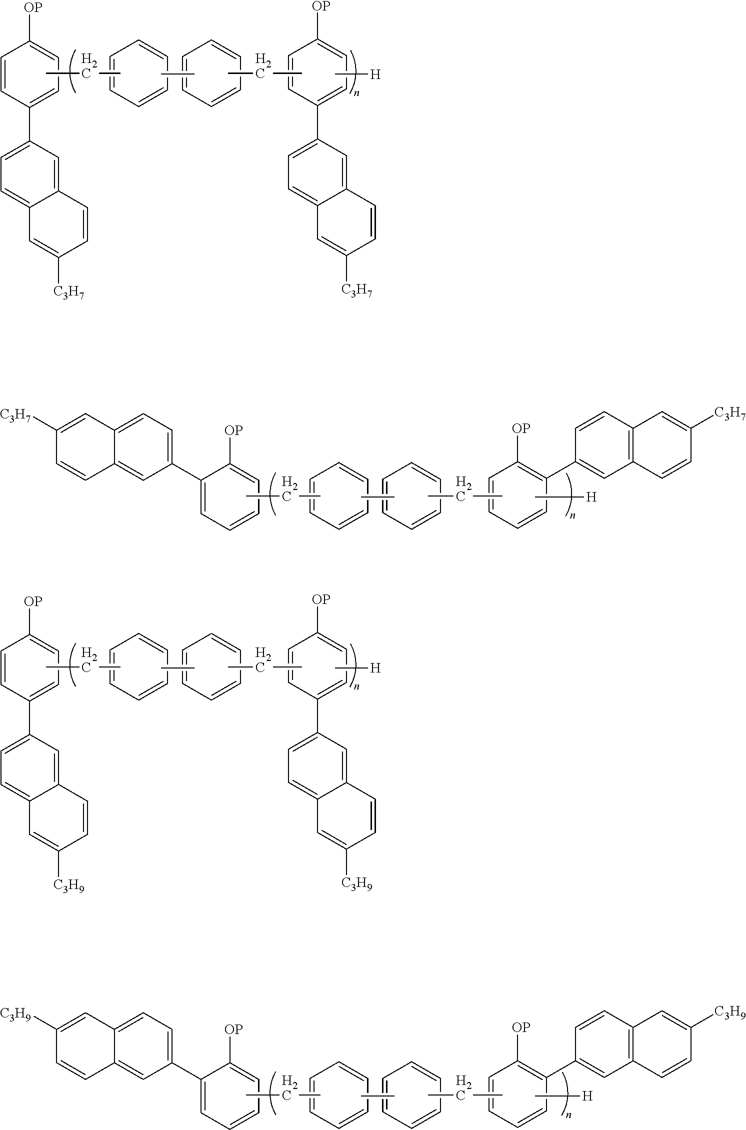

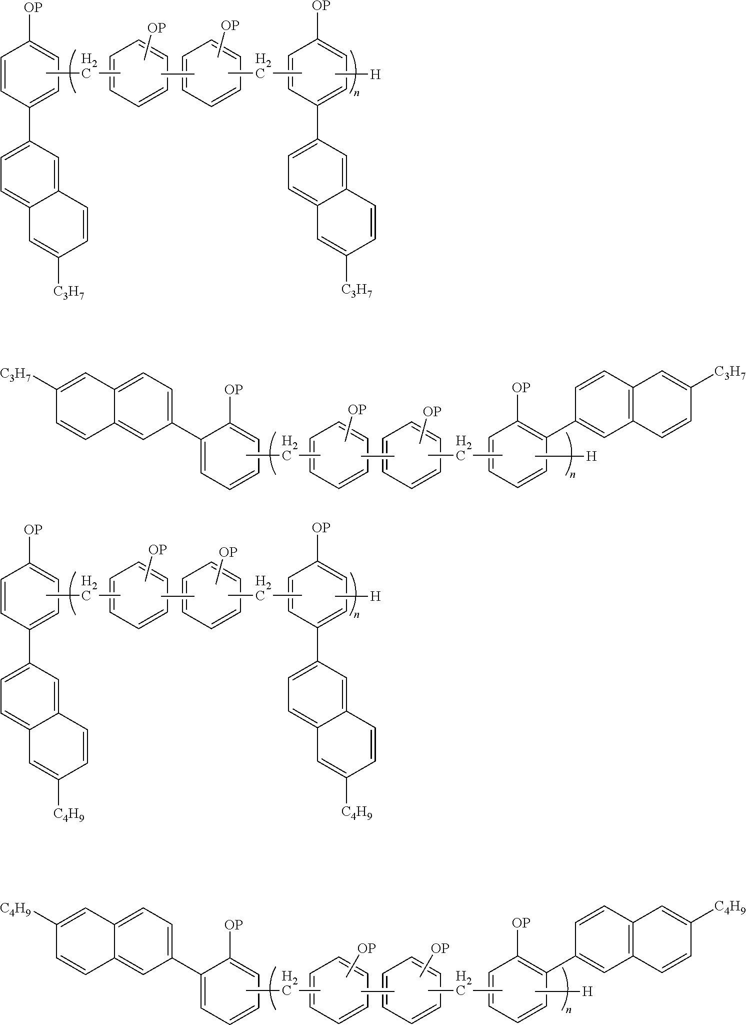

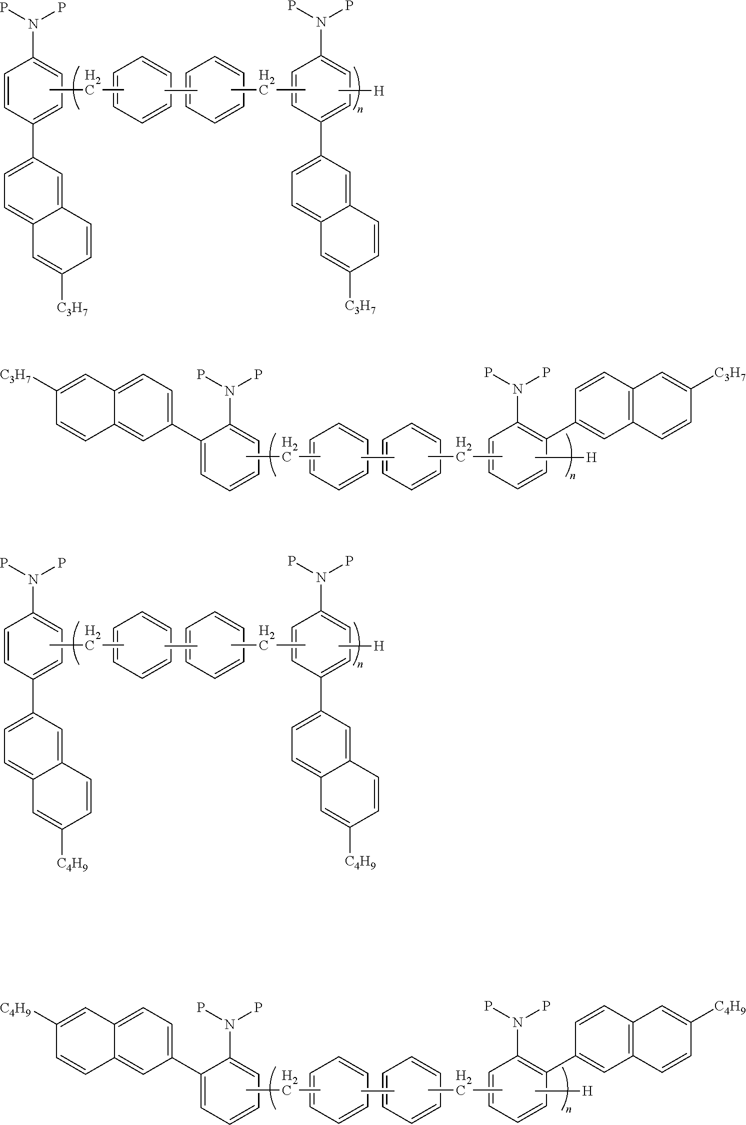

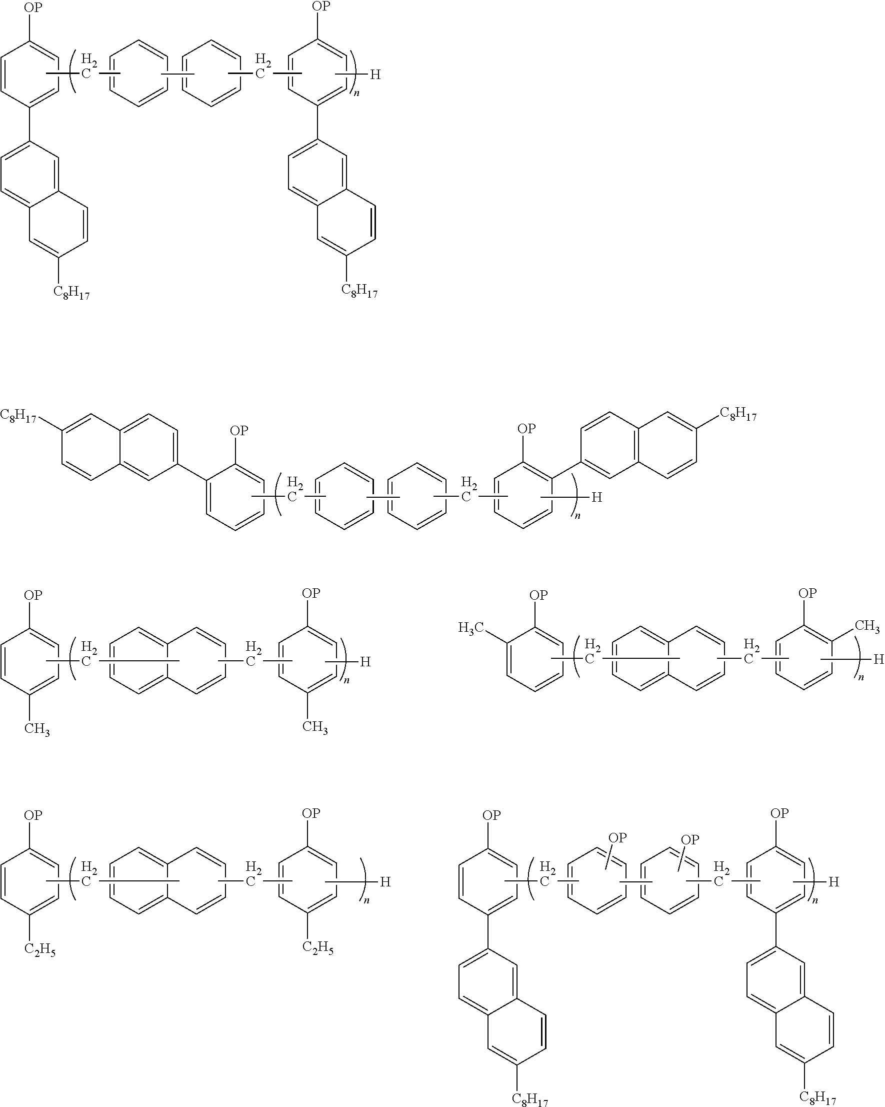

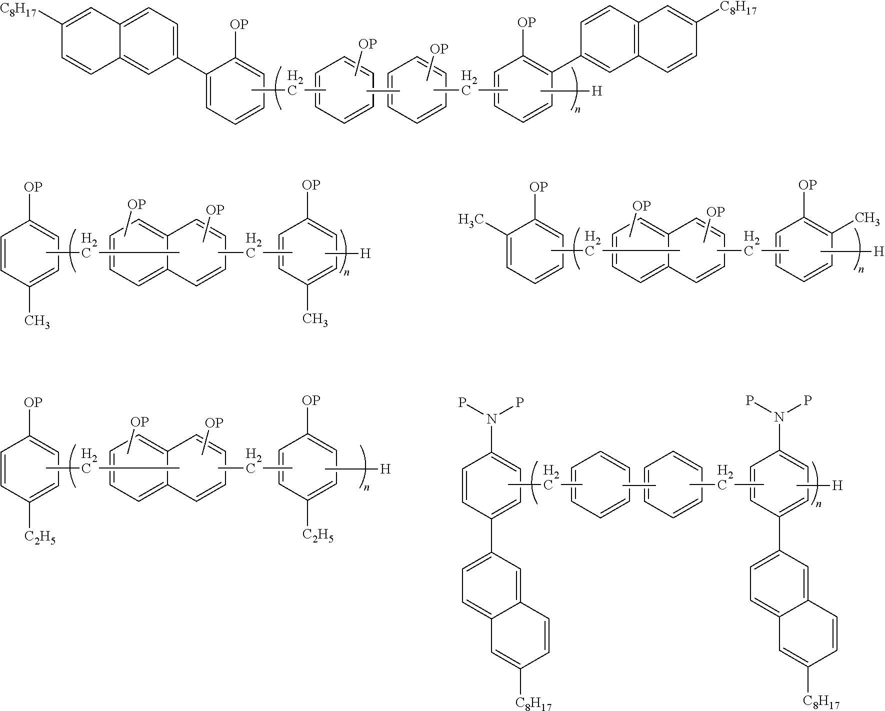

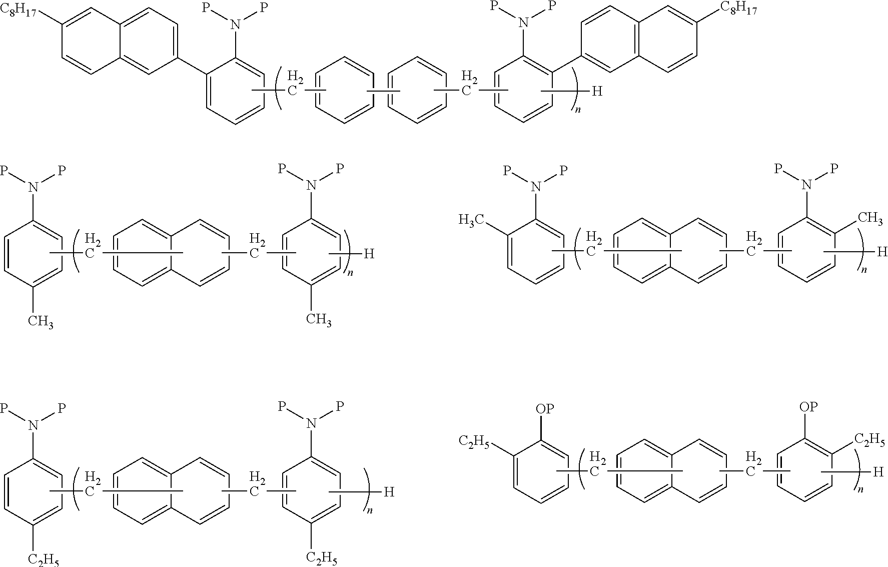

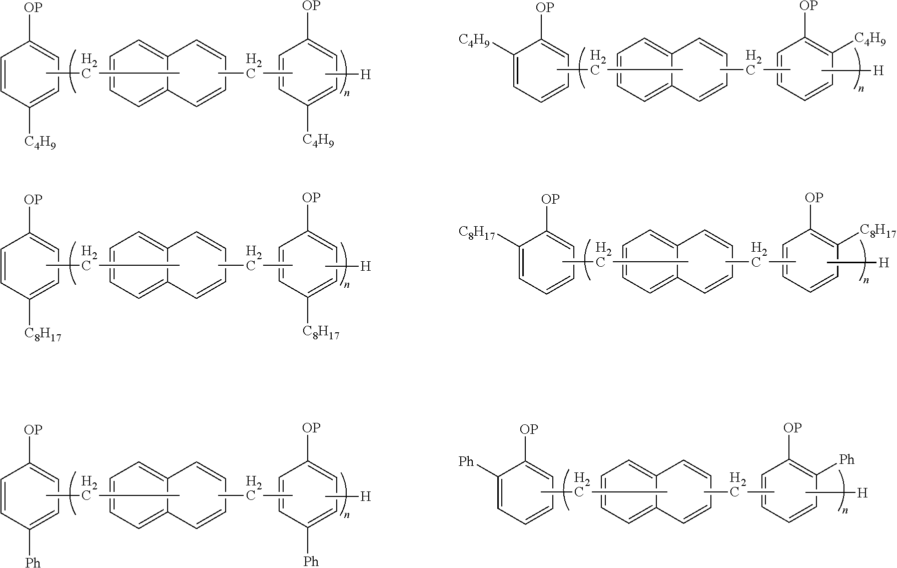

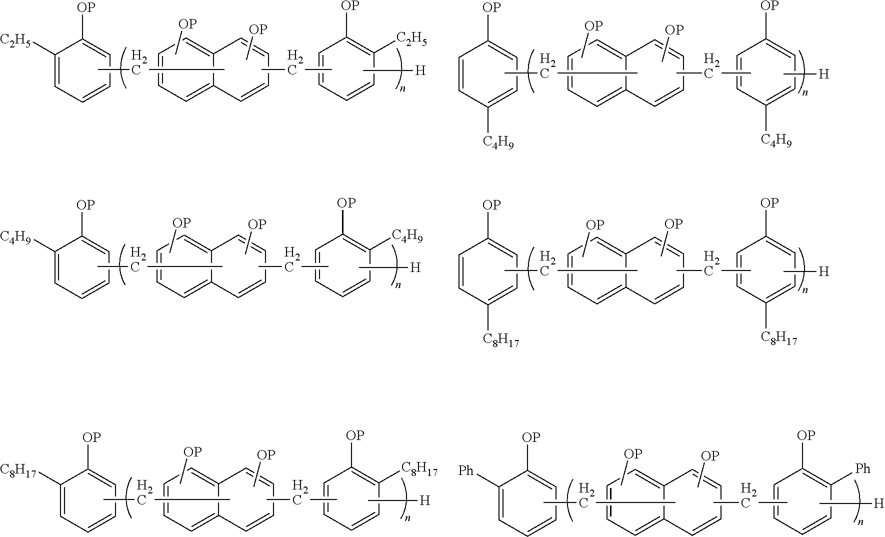

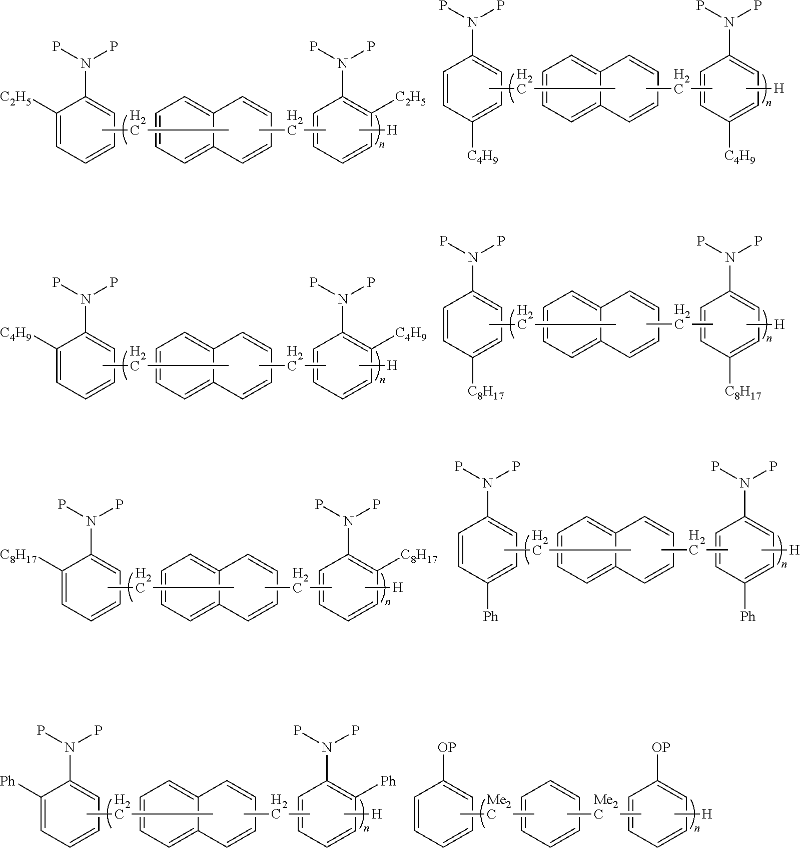

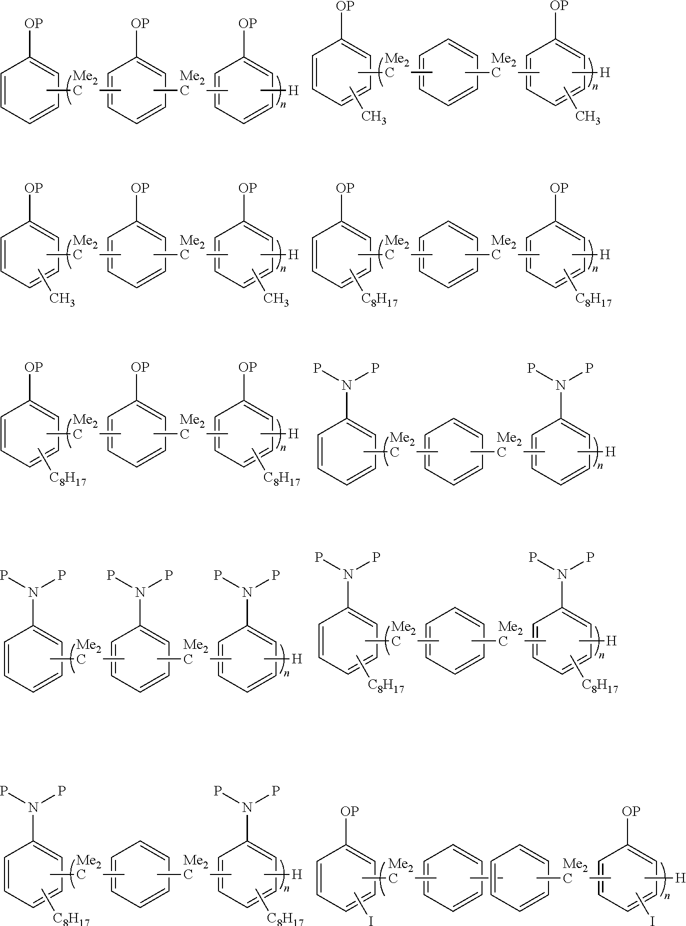

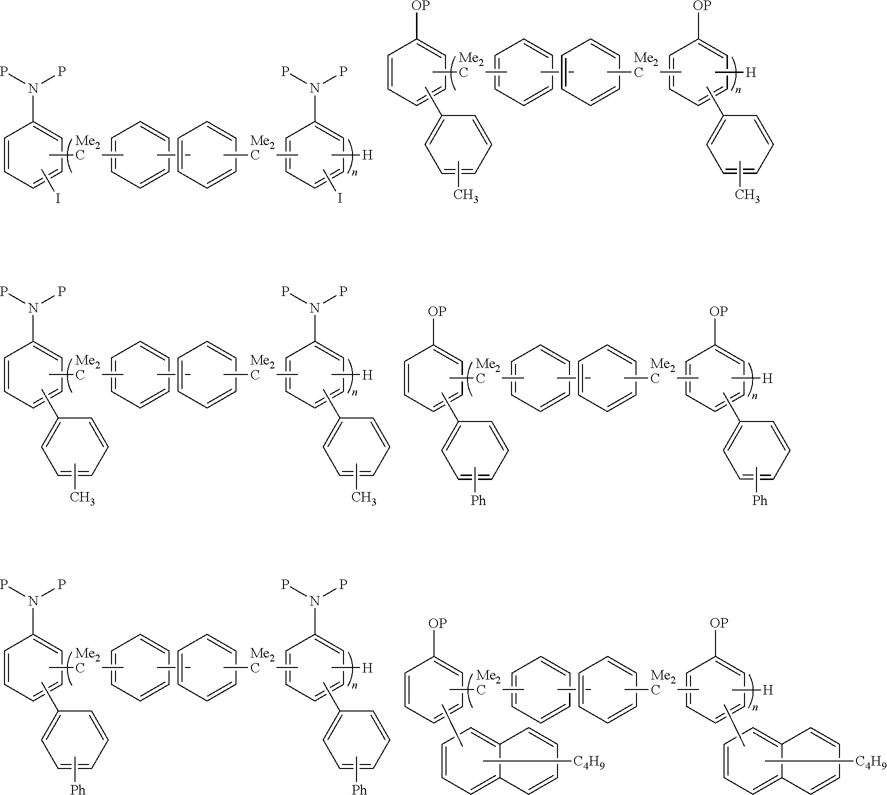

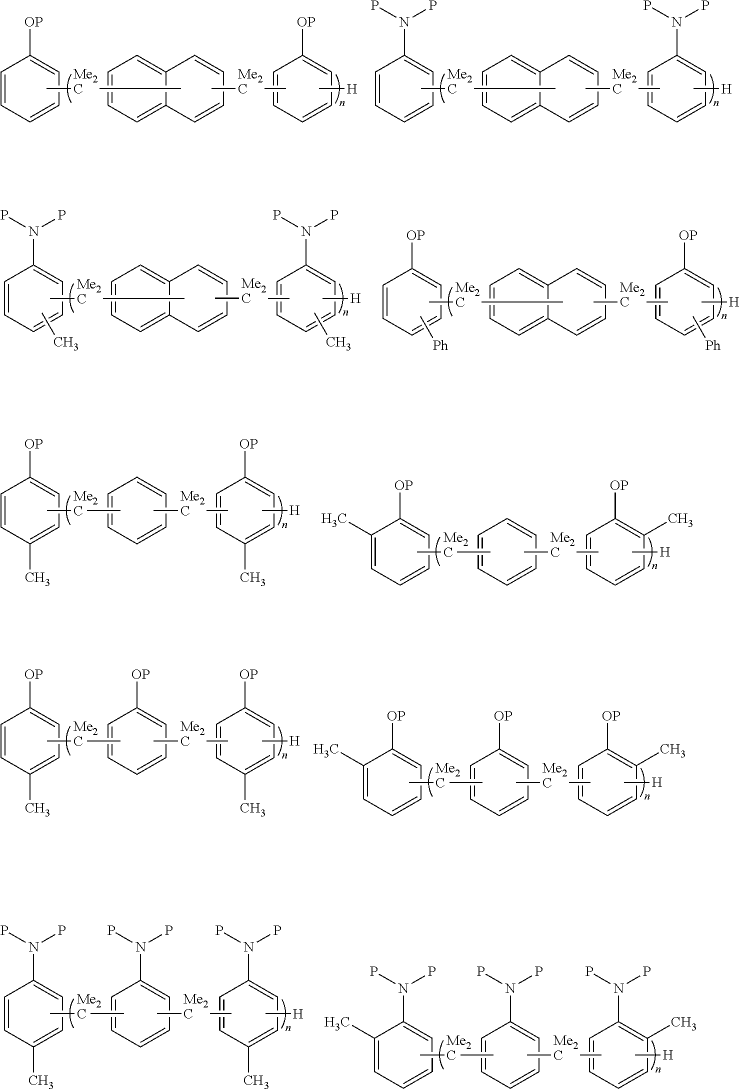

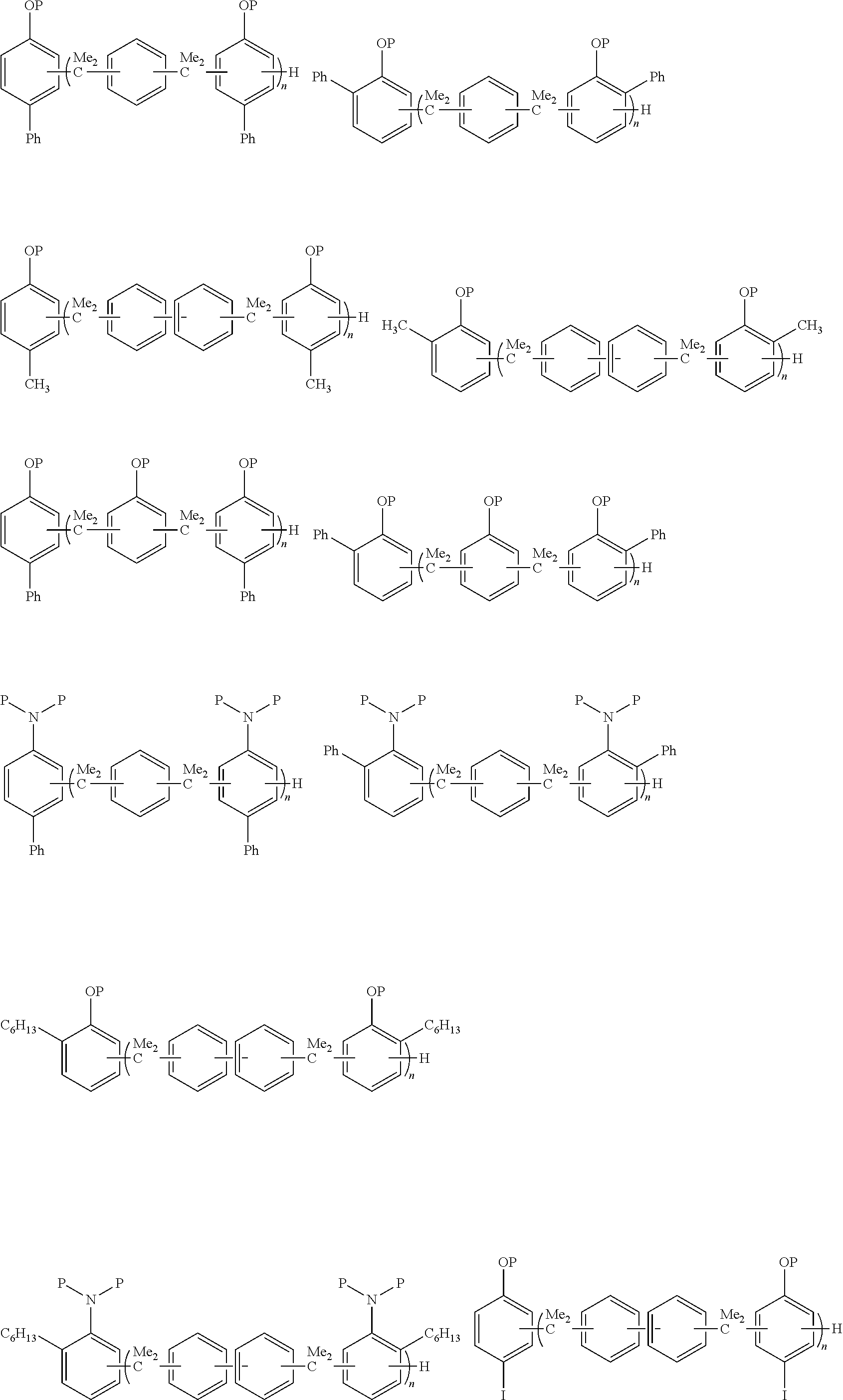

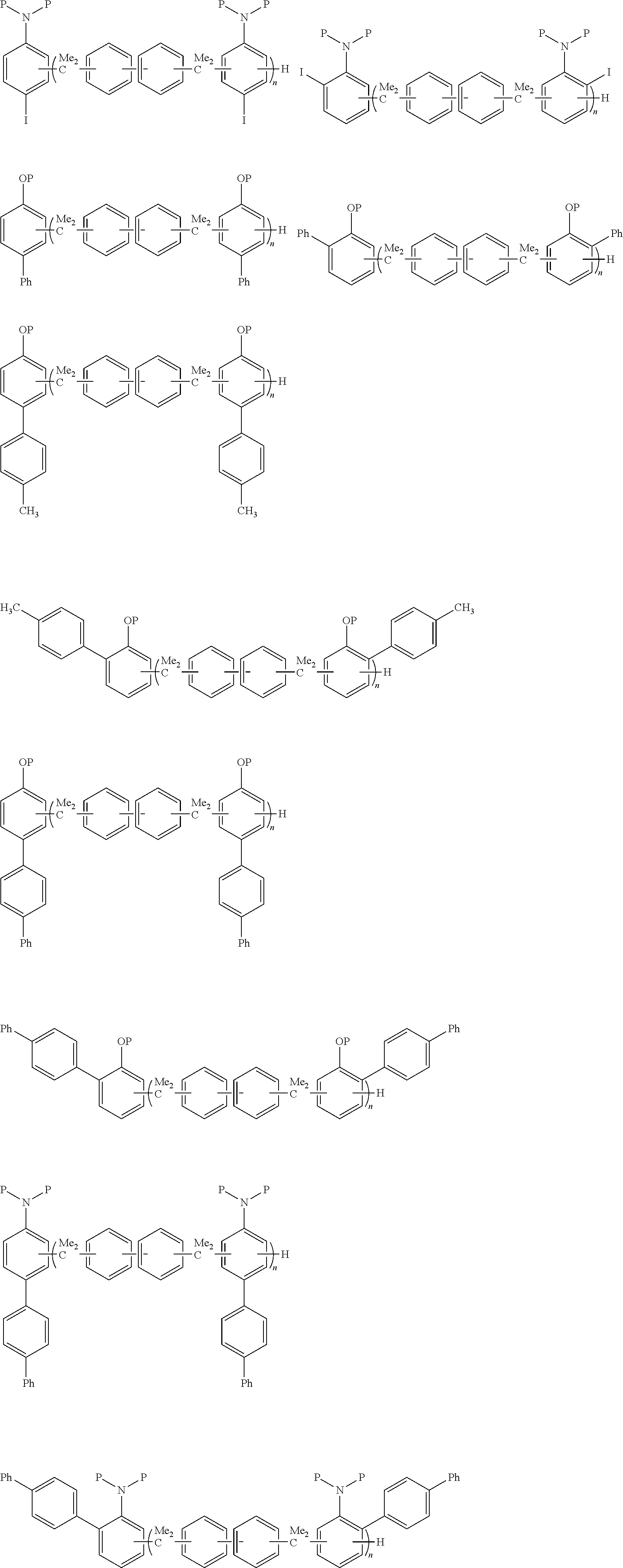

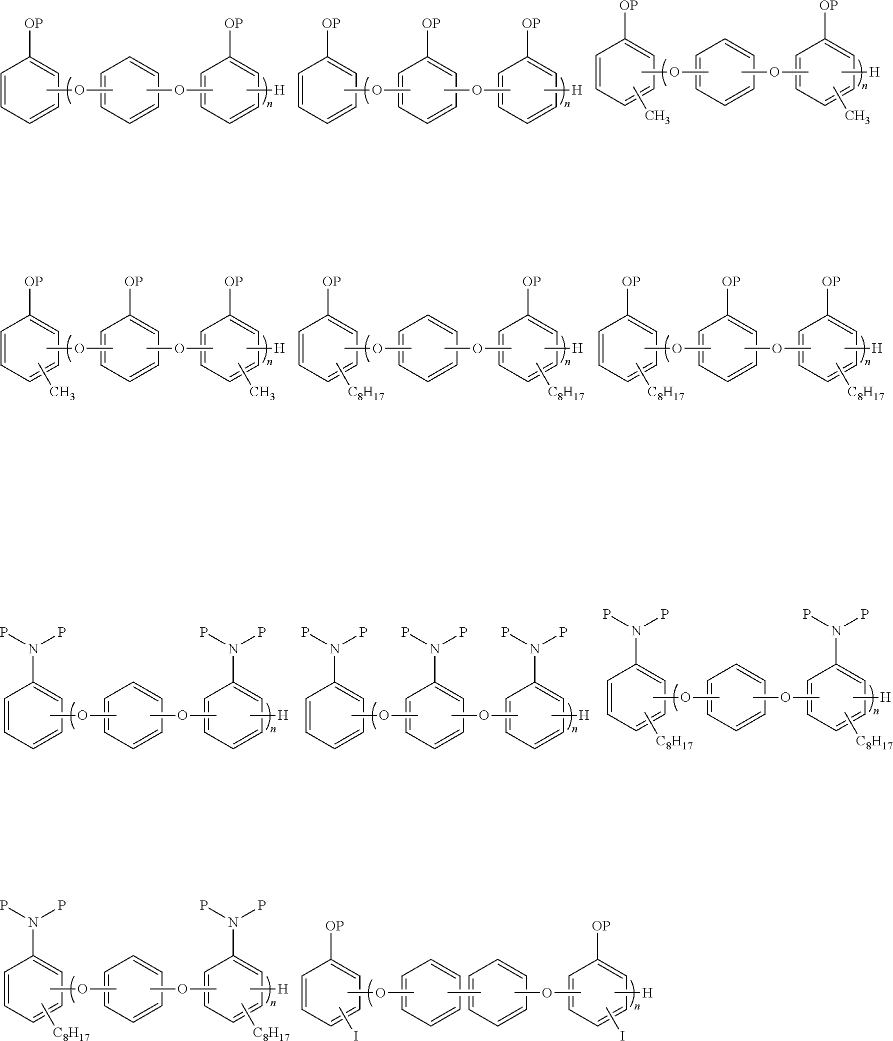

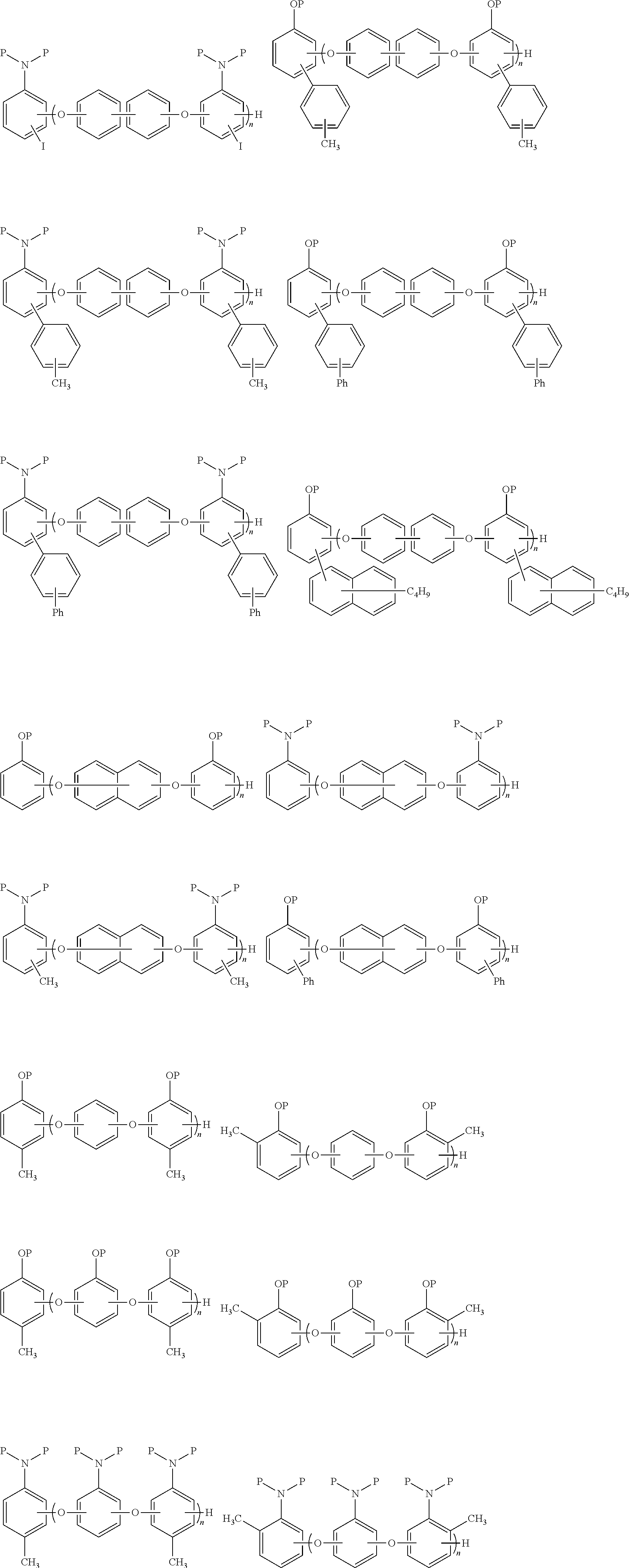

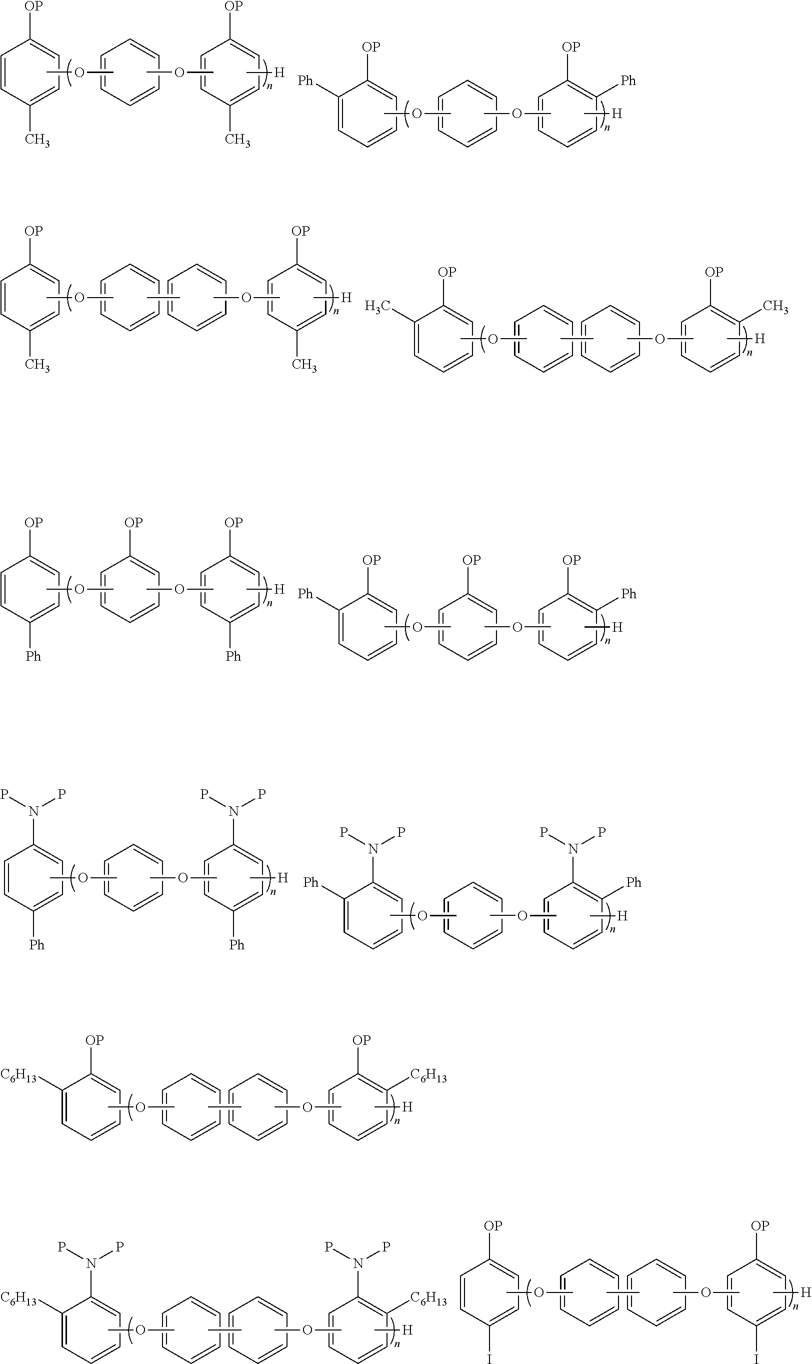

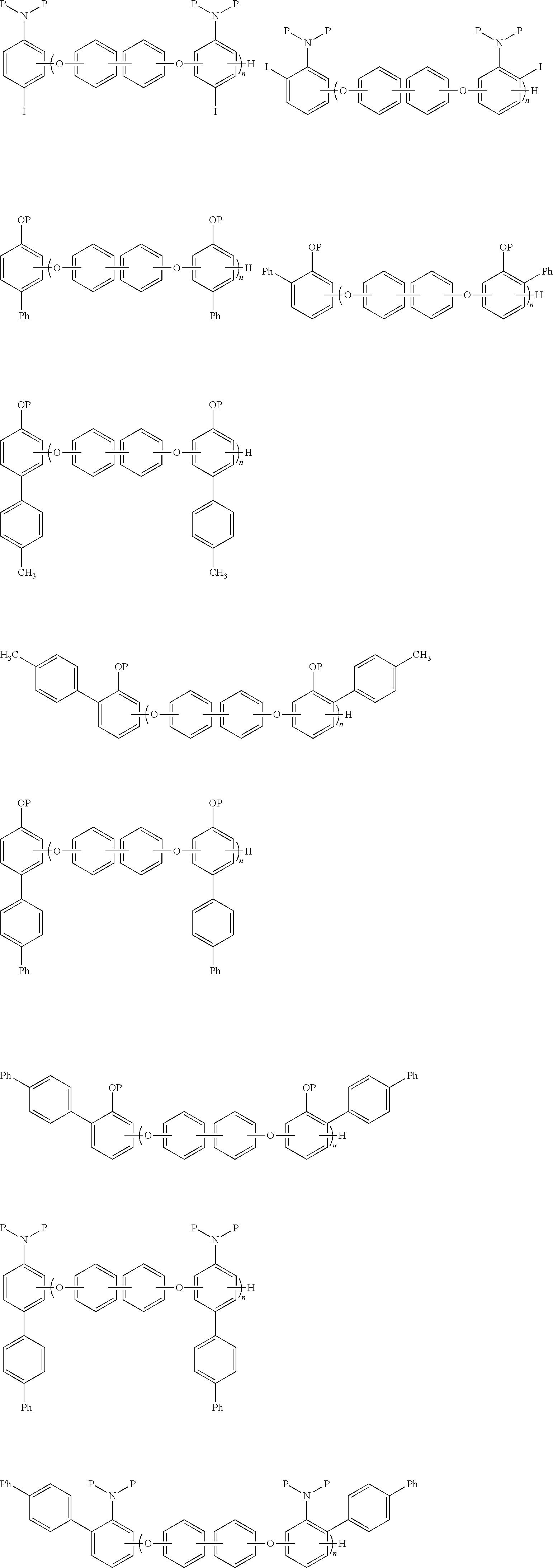

Examples of protecting reagents that can be used upon performing protection reaction include, but are not particularly limited to, methyl iodide, dimethyl carbonate, ethyl iodide, diethyl carbonate, bromo tert-butoxide, isobutene, benzyl bromide, di-tert-butyl dicarbonate, acetic anhydride, mesyl chloride, vinyl ethyl ether, dihydropyran, and chloromethylmethyl ether.

The compound and/or resin having a protecting group according to the present embodiment preferably has a high solubility in a solvent from the viewpoint of easier application to a wet process, etc. More specifically, in the case of using 1-methoxy-2-propanol (PGME) and/or propylene glycol monomethyl ether acetate (PGMEA) as a solvent, the oligomer preferably has a solubility of 10% by mass or more in the solvent. Here, the solubility in PGME and/or PGMEA is defined as “mass of the resin/(mass of the resin+mass of the solvent)×100 (% by mass)”.

The underlayer film formed by the method for forming an underlayer film for lithography of the present embodiment is applicable to a wet process and is excellent in heat resistance and smoothing properties. Furthermore, the composition of the present embodiment contains the oligomer of the present embodiment and can therefore form a film for lithography that is prevented from deteriorating during high temperature baking and is excellent in etching resistance against oxygen plasma etching or the like. Furthermore, the composition of the present embodiment is also excellent in adhesiveness to a resist layer and can therefore form an excellent resist pattern. Therefore, the composition of the present embodiment is suitably used for forming an underlayer film.

### [Solvent]

The underlayer film forming composition for lithography according to the present embodiment may contain a solvent, or if required, may be mixed with a solvent upon application. The solvent is not particularly limited as long as it is a solvent that can dissolves the compound and/or the resin of the present embodiment. Here, the compound and/or the resin of the present embodiment has excellent solubility in an organic solvent, as mentioned above, and therefore, various organic solvents are suitably used. Specific solvent include a solvent described in International Publication No. WO 2018/016614.

Among the solvents, from the viewpoint of safety, one or more selected from the group consisting of cyclohexanone, cyclopentanone, propylene glycol monomethyl ether, propylene glycol monomethyl ether acetate, ethyl lactate, methyl hydroxyisobutyrate and anisole are preferable.

The content of the solvent is not particularly limited and is preferably 100 to 10,000 parts by mass based on 100 parts by mass of the oligomer of the present embodiment, more preferably 200 to 5,000 parts by mass, and still more preferably 200 to 3,000 parts by mass, from the viewpoint of solubility and film formation.

The underlayer film forming composition for lithography according to the present embodiment preferably has a solution viscosity of 0.01 to 1.00 Pa·s (ICI viscosity, 150° C.), and more preferably 0.01 to 0.10 Pa·s, from the viewpoint of embedding properties to an uneven substrate and smoothing properties. From the similar viewpoint, the softening point (ring and ball method) is preferably −50 to 100° C., and more preferably −50 to 50° C.

### [Crosslinking Agent]

The underlayer film forming composition of the present embodiment may contain a crosslinking agent from the viewpoint of, for example, suppressing intermixing.

Examples of the crosslinking agent include, but are not particularly limited to, a phenol compound, an epoxy compound, a cyanate compound, an amino compound, a benzoxazine compound, an acrylate compound, a melamine compound, a guanamine compound, a glycoluril compound, a urea compound, an isocyanate compound, and an azide compound. Specific examples of these crosslinking agents include those described in International Publication No. 2018/016614 and International Publication No. 2013/024779. These crosslinking agents are used alone as one kind or in combination of two or more kinds. Among these, a fused aromatic ring-containing phenol compound is more preferable, from the viewpoint of improving etching resistance. Also, a methylol group-containing phenol compound is more preferable, from the viewpoint of improving smoothing properties.

The embedding properties and smoothing properties of the compound and/or resin having a protecting group according to the present embodiment are improved particularly when a methylol group-containing phenol compound is used as a crosslinking agent. This is because, since the above compound and/or resin and the crosslinking agent have a similar structure, the affinity becomes higher and the viscosity during coating is decreased.

The methylol group-containing phenol compound used as a crosslinking agent is preferably a compound represented by the following formula (11-1) or (11-2), from the viewpoint of improving smoothing properties.

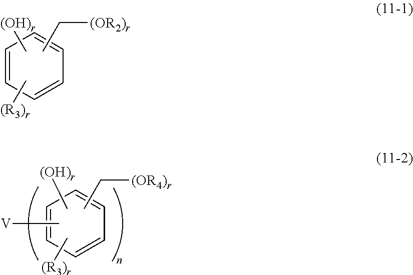

(In the formulas (11-1) and (11-2),
V is a single bond or a n-valent organic group;
R₂ and R₄ are each independently a hydrogen atom or an alkyl group having 1 to 10 carbon atoms;
R₃ and R₅ are each independently an alkyl group having 1 to 10 carbon atoms or an aryl group having 6 to 40 carbon atoms;
n is an integer of 2 to 10; and
each r is independently an integer of 0 to 6.)

Specific examples of the crosslinking agent represented by the general formula (11-1) or (11-2) include compounds represented by the following formulas. However, the crosslinking agent of the general formula (11-1) or (11-2) is not limited to the compounds represented by the following formulas.

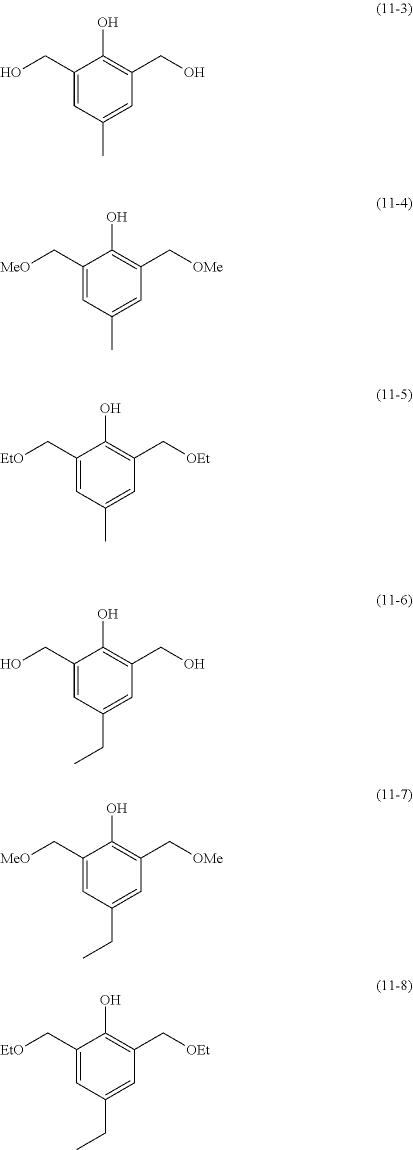

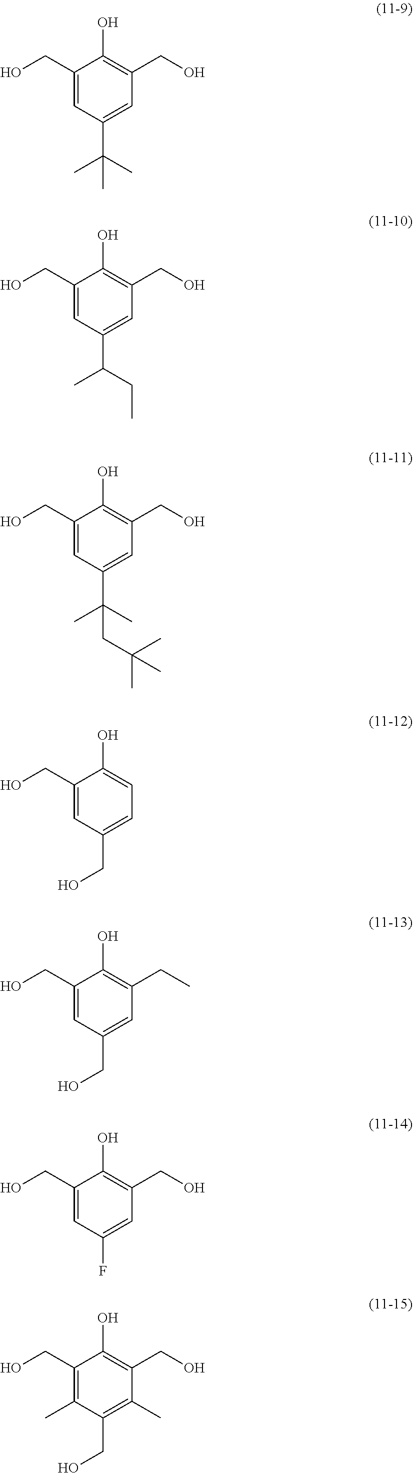

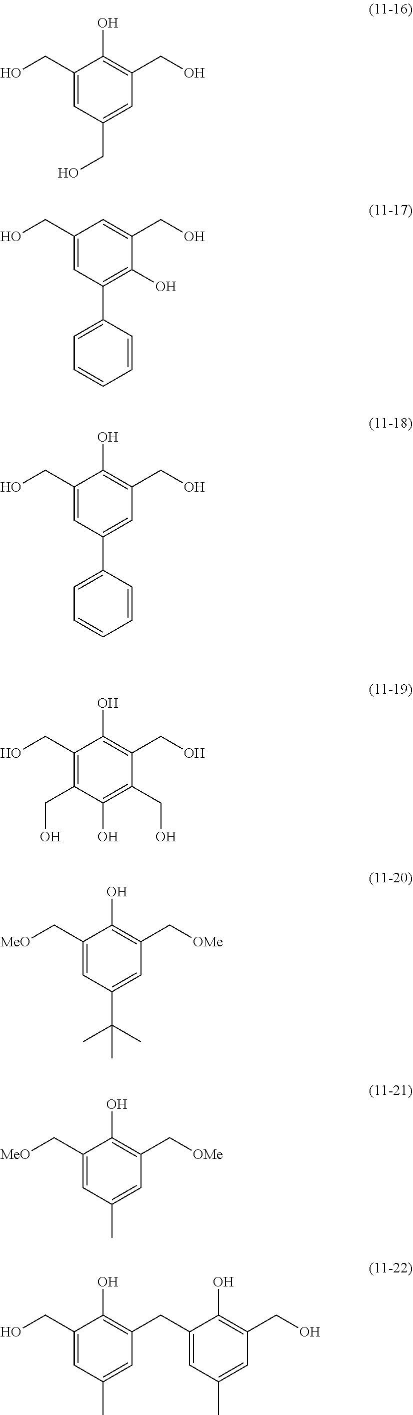

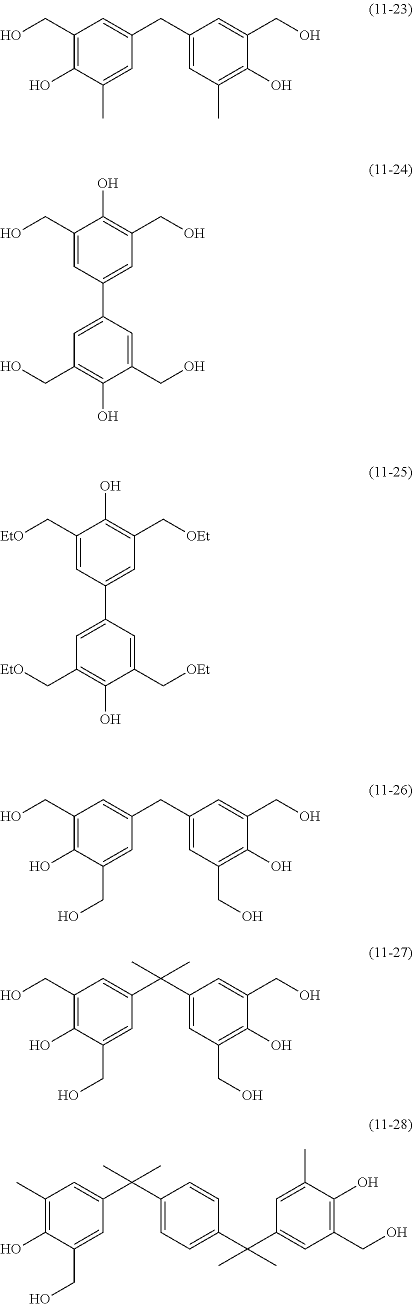

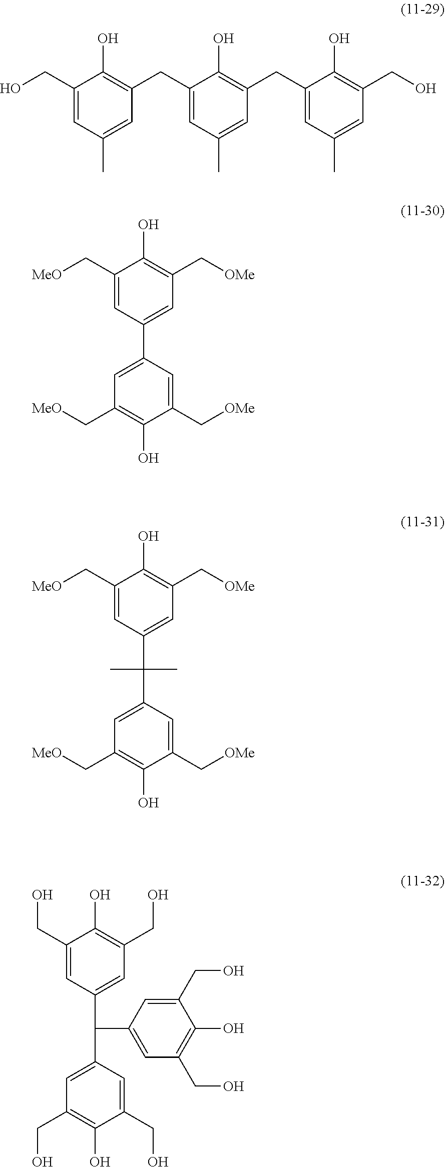

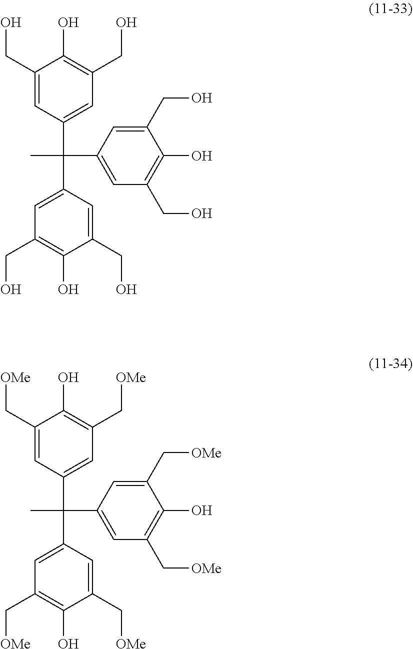

In the present embodiment, the content of the crosslinking agent is not particularly limited and is preferably 0.1 to 100 parts by mass based on 100 parts by mass of the underlayer film forming composition, more preferably 5 to 50 parts by mass, and still more preferably 10 to 40 parts by mass. By setting the content of the crosslinking agent to the above range, occurrence of a mixing event with a resist layer tends to be prevented. Also, an antireflection effect is enhanced, and film formability after crosslinking tends to be enhanced.

### [Crosslinking Promoting Agent]

The underlayer film forming composition of the present embodiment may contain a crosslinking promoting agent for accelerating crosslinking reaction (curing reaction), if required. Examples of the crosslinking promoting agent include a radical polymerization initiator.

The radical polymerization initiator may be a photopolymerization initiator that initiates radical polymerization by light, or may be a thermal polymerization initiator that initiates radical polymerization by heat. Examples of the radical polymerization initiator include at least one selected from the group consisting of a ketone-based photopolymerization initiator, an organic peroxide-based polymerization initiator and an azo-based polymerization initiator. Examples of such radical polymerization initiators include, but are not particularly limited to, those described in International Publication No. WO 2018/016614.

In the present embodiment, the content of the crosslinking promoting agent is not particularly limited and is preferably 0.1 to 100 parts by mass based on 100 parts by mass of the underlayer film forming composition, more preferably 0.5 to 10 parts by mass, and further preferably 0.5 to 5 parts by mass. By setting the content of the crosslinking promoting agent to the above range, occurrence of a mixing event with a resist layer tends to be prevented. Also, an antireflection effect is enhanced, and film formability after crosslinking tends to be enhanced.

### [Acid Generating Agent]

The underlayer film forming composition of the present embodiment may contain an acid generating agent from the viewpoint of, for example, further accelerating crosslinking reaction by heat. An acid generating agent that generates an acid by thermal decomposition, an acid generating agent that generates an acid by light irradiation, and the like are known, any of which can be used. As the acid generating agent, for example, those described in International Publication No. WO 2013/024779 can be used.

The content of the acid generating agent in the underlayer film forming composition is not particularly limited and is preferably 0.1 to 50 parts by mass, and more preferably 0.5 to 40 parts by mass, based on 100 parts by mass of the underlayer film forming composition. By setting the content of the acid generating agent to the above range, crosslinking reaction tends to be enhanced and occurrence of a mixing event with a resist layer tends to be prevented.

### [Basic Compound]

The underlayer film forming composition of the present embodiment may contain a basic compound from the viewpoint of, for example, improving storage stability.

The basic compound plays a role to prevent crosslinking reaction from proceeding due to a trace amount of an acid generated from the acid generating agent, that is, a role as a quencher against the acid. The storage stability of the underlayer film forming composition is improved. Examples of such a basic compound include, but are not particularly limited to, those described in International Publication No. WO 2013/024779.

The content of the basic compound in the underlayer film forming composition of the present embodiment is not particularly limited and is preferably 0.001 to 2 parts by mass, and more preferably 0.01 to 1 part by mass, based on 100 parts by mass of the underlayer film forming composition. By setting the content of the basic compound to the above range, storage stability tends to be enhanced without excessively deteriorating crosslinking reaction.

### [Further Additive Agent]

The underlayer film forming composition of the present embodiment may also contain an additional resin and/or compound for the purpose of conferring thermosetting or light curing properties or controlling absorbance. Examples of such an additional resin and/or compound include, without particular limitations, a naphthol resin, a xylene resin naphthol-modified resin, a phenol-modified resin of a naphthalene resin; a polyhydroxystyrene, a dicyclopentadiene resin, a resin containing (meth)acrylate, dimethacrylate, trimethacrylate, tetramethacrylate, a naphthalene ring such as vinylnaphthalene or polyacenaphthylene, a biphenyl ring such as phenanthrenequinone or fluorene, or a heterocyclic ring having a heteroatom such as thiophene or indene, and a resin containing no aromatic ring; and a resin or compound containing an alicyclic structure, such as a rosin-based resin, a cyclodextrin, an adamantine(poly)ol, a tricyclodecane(poly)ol, and a derivative thereof. The film forming material for lithography of the present embodiment may also contain a publicly known additive agent. Examples of the publicly known additive agent include, but are not limited to, a thermosetting and/or light curing catalyst, a polymerization inhibitor, a flame retardant, a filler, a coupling agent, a thermosetting resin, a light curable resin, a dye, a pigment, a thickener, a lubricant, an antifoaming agent, a leveling agent, an ultraviolet absorber, a surfactant, a colorant, and a nonionic surfactant.

### [Coating Step]

In the coating step implemented in the method for forming a resist underlayer film according to the present embodiment, a composition containing a resist underlayer film forming material selected from the group consisting of the above compounds or resins thereof is coated on a substrate.

Examples of the substrate that may be used in the present embodiment include, but are not particularly limited to, a semiconductor substrate made of silicon and the like on which a silicon oxide film, a silicon nitride film, or a silicon oxide nitride film is formed, a silicon nitride substrate, a quartz substrate, a glass substrate (including non-alkaline glass, low alkaline glass, and crystallized glass), and a glass substrate on which an ITO film is formed. Coating procedures in the coating step are not particularly limited, and for example, the composition according to the present embodiment can be coated on the aforementioned substrate by an appropriate coating method, for example, by a spinner, a coater.

### [Pre-Heat Treatment Step]

Pre-heat treatment step can be applied to the method for forming a resist underlayer film according to the present embodiment. In the step mentioned above, the coated composition is heated at 50° C. or more and 300° C. or less. That is, heating the substrate on which the composition according to the present embodiment is coated at a predetermined temperature causes a hardening reaction, so that a resist underlayer film precursor is formed.

The heating means in the pre-heat treatment step is not particularly limited, and for example, a hot plate or the like may be used. At this time, the heating conditions are 50° C. or more and 300° C. or less, and preferably 50° C. or more and 250° C. or less. In the pre-heat treatment step, heating at a temperature of 300° C. or less enables the improvement of the heat resistance of the film by hardening even in an air atmosphere, while suppressing the excess oxidation and the deterioration due to the sublimation of the resist underlayer film forming material. Therefore, a resist underlayer film having good flatness, a high carbon concentration and excellent etching resistance can be formed, while preventing the oxidation and decomposition of the film in the subsequent heat treatment step.

The heating time in the pre-heat treatment step is preferably 15 seconds or more, more preferably 30 seconds or more, and further preferably 45 seconds or more. The above heating time is preferably 20 minutes or less, more preferably 1,200 seconds or less, further preferably 600 seconds or less, and further more preferably 300 seconds or less from the viewpoint of avoiding the excess thermal history.

The atmosphere in the pre-heat treatment step may be air, and is preferably an inert gas atmosphere in which nitrogen, argon, or a mixture thereof is present. Here, the oxygen concentration in the pre-heat treatment step is preferably less than 20%, and more preferably less than 5%. As used herein, it is specified that the oxygen concentration is on the volume basis.

### [Heat Treatment Step]

The heat treatment step implemented in the method for forming a resist underlayer film according to the present embodiment is implemented after the pre-heat treatment step mentioned above. The heating conditions are a temperature of 250° C. or more and 800° C. or less, preferably 300° C. or more and 500° C. or less, and more preferably 300° C. or more and 450° C. or less.

The heat treatment step in the present embodiment may be performed in air, and is preferably performed in an inert gas atmosphere in which nitrogen, argon, or a mixture thereof is present. Here, the oxygen concentration in the pre-heat treatment step is preferably less than 20%, and more preferably less than 5%. By performing heat treatment in a low oxygen concentration atmosphere of an oxygen concentration of less than 5.0% and, as for the heating temperature, under such temperature conditions that the underlayer film is not thermally decomposed, the hardening reaction of the film can be progressed while suppressing excess oxidation, and as a result, the thermal decomposition temperature can be improved and the upper limit value of the baking temperature can be set higher than that upon baking in air.

The heating time in the heat treatment step is preferably 15 seconds or more and 20 minutes or less. The above heating time is more preferably 30 seconds or more, and further preferably 45 seconds or more. The above heating time is more preferably 1,200 seconds or less, further preferably 600 seconds or less, and further more preferably 300 seconds or less.

In the present embodiment, the resist underlayer film is formed through the above heat treatment step, but in the case where the composition according to the present embodiment contains a photosensitive acid generating agent, the resist underlayer film can also be formed by promoting hardening by a combination of exposure and heating. The radiation used for the exposure is arbitrarily selected from electromagnetic waves such as visible light, ultraviolet, far ultraviolet, X-ray, and γ-ray; and particle beams such as electron beam, molecular beam, and ion beam according to the type of radiation-sensitive acid generating agent.

The lower limit of the average thickness of the resist underlayer film to be formed is preferably 0.05 μm, more preferably 0.1 μm, and further preferably 0.2 μm. The upper limit of the above average thickness is preferably 5 μm, more preferably 3 μm, and further preferably 2 μm.

### [Resist Pattern Formation Method]

The resist pattern formation method of the present embodiment comprises: an underlayer film formation step of forming an underlayer film on a substrate using the underlayer film forming composition of the present embodiment; a photoresist layer formation step of forming at least one photoresist layer on the underlayer film formed through the underlayer film formation step; and a step of irradiating a predetermined region of the photoresist layer formed through the photoresist layer formation step with radiation for development. The resist pattern formation method of the present embodiment can be used for forming various patterns, and is preferably a method for forming an insulating film pattern.

### [Circuit Pattern Formation Method]

The circuit pattern formation method of the present embodiment comprises: an underlayer film formation step of forming an underlayer film on a substrate using the underlayer film forming composition of the present embodiment; an intermediate layer film formation step of forming an intermediate layer film on the underlayer film formed through the underlayer film formation step; a photoresist layer formation step of forming at least one photoresist layer on the intermediate layer film formed through the intermediate layer film formation step; a resist pattern formation step of irradiating a predetermined region of the photoresist layer formed through the photoresist layer formation step with radiation for development, thereby forming a resist pattern; an intermediate layer film pattern formation step of etching the intermediate layer film with the resist pattern formed through the resist pattern formation step as a mask, thereby forming an intermediate layer film pattern; an underlayer film pattern formation step of etching the underlayer film with the intermediate layer film pattern formed through the intermediate layer film pattern formation step as a mask, thereby forming an underlayer film pattern; and a substrate pattern formation step of etching the substrate with the underlayer film pattern formed through the underlayer film pattern formation step as a mask, thereby forming a pattern on the substrate.

The underlayer film for lithography of the present embodiment is formed from the underlayer film forming composition of the present embodiment. The formation method is not particularly limited and a publicly known method can be applied. The underlayer film can be formed by, for example, applying the underlayer film forming composition of the present embodiment onto a substrate by a publicly known coating method or printing method such as spin coating or screen printing, and then removing an organic solvent by volatilization or the like.

After preparing the underlayer film, it is preferable to prepare a silicon-containing resist layer or a single-layer resist made of hydrocarbon on the underlayer film in the case of a two-layer process, and to prepare a silicon-containing intermediate layer on the underlayer film and further prepare a silicon-free single-layer resist layer on the silicon-containing intermediate layer in the case of a three-layer process. In this case, a publicly known photoresist material can be used for forming this resist layer.

For the silicon-containing resist material for a two-layer process, a silicon atom-containing polymer such as a polysilsesquioxane derivative or a vinylsilane derivative is used as a base polymer, and a positive type photoresist material further containing an organic solvent, an acid generating agent, and if required, a basic compound or the like is preferably used, from the viewpoint of oxygen gas etching resistance. Here, a publicly known polymer that is used in this kind of resist material can be used as the silicon atom-containing polymer.

A polysilsesquioxane-based intermediate layer is preferably used as the silicon-containing intermediate layer for a three-layer process. By imparting effects as an antireflection film to the intermediate layer, there is a tendency that reflection can be effectively suppressed. For example, use of a material containing a large amount of an aromatic group and having high substrate etching resistance as the underlayer film in a process for exposure at 193 nm tends to increase a k value and enhance substrate reflection. However, the intermediate layer suppresses the reflection so that the substrate reflection can be 0.5% or less. The intermediate layer having such an antireflection effect is not limited, and polysilsesquioxane that crosslinks by an acid or heat in which a light absorbing group having a phenyl group or a silicon-silicon bond is introduced is preferably used for exposure at 193 nm.

Alternatively, an intermediate layer formed by chemical vapour deposition (CVD) may be used. The intermediate layer highly effective as an antireflection film prepared by CVD is not limited, and, for example, a SiON film is known. In general, the formation of an intermediate layer by a wet process such as spin coating or screen printing is more convenient and more advantageous in cost than CVD. The upper layer resist for a three-layer process may be positive type or negative type, and the same as a single-layer resist generally used can be used.

The underlayer film according to the present embodiment can also be used as an antireflection film for usual single-layer resists or an underlying material for suppression of pattern collapse. The underlayer film is excellent in etching resistance for an underlying process and can be expected to also function as a hard mask for an underlying process.

In the case of forming a resist layer from the above photoresist material, a wet process such as spin coating or screen printing is preferably used, as in the case of forming the above underlayer film. After coating with the resist material by spin coating or the like, prebaking is generally performed. This prebaking is preferably performed at 80 to 180° C. in the range of 10 to 300 seconds. Then, exposure, post-exposure baking (PEB), and development can be performed according to a conventional method to obtain a resist pattern. The thickness of the resist film is not particularly limited, and in general, is preferably 30 to 500 nm and more preferably 50 to 400 nm.

The exposure light can be arbitrarily selected and used according to the photoresist material to be used. General examples thereof can include a high energy ray having a wavelength of 300 nm or less, specifically, excimer laser of 248 nm, 193 nm, or 157 nm, soft x-ray of 3 to 20 nm, electron beam, and X-ray.

In a resist pattern formed by the above method, pattern collapse is suppressed by the underlayer film. Therefore, use of the underlayer film according to the present embodiment can produce a finer pattern and can reduce an exposure amount necessary for obtaining the resist pattern.

Next, etching is performed with the obtained resist pattern as a mask. Gas etching is preferably used as the etching of the underlayer film in a two-layer process. The gas etching is preferably etching using oxygen gas. In addition to oxygen gas, an inert gas such as He or Ar, or CO, CO₂, NH₃, SO₂, N₂, NO₂, or H₂ gas may be added. Alternatively, the gas etching may be performed with CO, CO₂, NH₃, N₂, NO₂, or H₂ gas without the use of oxygen gas. Particularly, the latter gas is preferably used for side wall protection in order to prevent the undercut of pattern side walls.

On the other hand, gas etching is also preferably used as the etching of the intermediate layer in a three-layer process. The same gas etching as described in the above two-layer process is applicable. Particularly, it is preferable to process the intermediate layer in a three-layer process by using chlorofluorocarbon-based gas and using the resist pattern as a mask. Then, as mentioned above, for example, the underlayer film can be processed by oxygen gas etching with the intermediate layer pattern as a mask.

Herein, in the case of forming an inorganic hard mask intermediate layer film as the intermediate layer, a silicon oxide film, a silicon nitride film, or a silicon oxynitride film (SiON film) is formed by CVD, ALD, or the like. A method for forming the nitride film is not limited, and, for example, a method described in Japanese Patent Laid-Open No. 2002-334869 or WO 2004/066377 can be used. Although a photoresist film can be formed directly on such an intermediate layer film, an organic antireflection film (BARC) may be formed on the intermediate layer film by spin coating and a photoresist film may be formed thereon.

A polysilsesquioxane-based intermediate layer is suitably used as the intermediate layer. By imparting effects as an antireflection film to the resist intermediate layer film, there is a tendency that reflection can be effectively suppressed. A specific material for the polysilsesquioxane-based intermediate layer is not limited, and, for example, a material described in Japanese Patent Laid-Open No. 2007-226170 or Japanese Patent Laid-Open No. 2007-226204 can be used.

The subsequent etching of the substrate can also be performed by a conventional method. For example, the substrate made of SiO₂ or SiN can be etched mainly using chlorofluorocarbon-based gas, and the substrate made of p-Si, Al, or W can be etched mainly using chlorine- or bromine-based gas. In the case of etching the substrate with chlorofluorocarbon-based gas, the silicon-containing resist of the two-layer resist process or the silicon-containing intermediate layer of the three-layer process is stripped at the same time with substrate processing. On the other hand, in the case of etching the substrate with chlorine- or bromine-based gas, the silicon-containing resist layer or the silicon-containing intermediate layer is separately stripped and in general, stripped by dry etching using chlorofluorocarbon-based gas after substrate processing.

A feature of the underlayer film of the present embodiment is that it is excellent in etching resistance of the substrates. The substrate can be arbitrarily selected for use from publicly known ones and is not particularly limited. Examples thereof include Si, α-Si, p-Si, SiO₂, SiN, SiON, W, TiN, and Al. The substrate may be a laminate having a film to be processed (substrate to be processed) on a base material (support). Examples of such a film to be processed include various low-k films such as Si, SiO₂, SiON, SiN, p-Si, α-Si, W, W—Si, Al, Cu, and Al—Si, and stopper films thereof. A material different from that for the base material (support) is generally used. The thickness of the substrate to be processed or the film to be processed is not particularly limited and is generally preferably about 50 to 1,000,000 nm, and more preferably 75 to 50,000 nm.

### [Resist Permanent Film]

The resist permanent film of the present embodiment contains the composition of the present embodiment. The resist permanent film prepared by coating with the composition of the present embodiment is suitable as a permanent film that also remains in a final product, if required, after formation of a resist pattern. Specific examples of the permanent film include, in relation to semiconductor devices, a solder resist, a package material, an underfill material, a package adhesive layer for circuit elements and the like, and an adhesive layer between integrated circuit elements and circuit substrates, and in relation to thin displays, a thin film transistor protecting film, a liquid crystal color filter protecting film, a black matrix, and a spacer. Particularly, the resist permanent film containing the composition of the present embodiment is excellent in heat resistance and humidity resistance and furthermore, also has the excellent advantage that contamination by sublimable components is reduced. Particularly, for a display material, a material that achieves all of high sensitivity, high heat resistance, and hygroscopic reliability with reduced deterioration in image quality due to significant contamination can be obtained.

In the case of using the underlayer film forming composition of the present embodiment for resist permanent film purposes, a curing agent as well as, if required, various additive agents such as an additional resin, a surfactant, a dye, a filler, a crosslinking agent, and a dissolution promoting agent can be added and dissolved in an organic solvent to prepare a composition for resist permanent films.

The underlayer film forming composition of the present embodiment can be prepared by compounding each of the above components and mixing them using a stirrer or the like. When the composition of the present embodiment contains a filler or a pigment, it can be prepared by dispersion or mixing using a dispersion apparatus such as a dissolver, a homogenizer, and a three-roll mill.

### [Method for Forming Underlayer Film for Lithography]

The method for forming an underlayer film for lithography of the present embodiment includes applying the underlayer film forming composition for lithography to an uneven substrate. The application method is not particularly limited, and a known coating method, printing method, or the like, such as spin coating and screen printing mentioned above, can be used.

Examples of the uneven substrate include, but are not limited to, a substrate having a line-and-space of 1 to 10,000 nm, a substrate having a trench with a width of 1 to 100,000, a pitch of 1 to 20,000 nm, a depth of 10 to 100,000 nm, and a substrate having a hole with a width of 1 to 100,000 nm, a pitch of 1 to 20,000 nm, and a depth of 10 to 100,000 nm.

### EXAMPLES

The present embodiment will be described in more detail with reference to synthesis examples, examples, and comparative examples below. However, the present invention is not limited to these examples by any means. That is, the material, amount used, proportion, treatment detail, treatment procedure, and the like shown in the examples below may be arbitrarily changed without departing from the gist of the present invention. The values of various production conditions and evaluation results in the examples below mean a preferred upper limit value or a preferred lower limit value in the embodiment of the present invention, and a preferred numerical value range may be a range specified by a combination of the upper limit value or lower limit value described above and a value in the following Examples or a combination of values in Examples.

### (Molecular Weight)

The weight average molecular weight (Mw) and dispersibility (Mw/Mn) of the oligomer of the present embodiment were determined under the following measurement conditions in terms of polystyrene by gel permeation chromatography (GPC) analysis.
Apparatus: Shodex GPC-101 model (manufactured by Showa Denko K.K.)
Column: KF-80M×3
Eluent: 1 mL/min THF
Temperature: 40° C.

### (Measurement of Softening Point)

The softening point was measured using the following equipment.
Equipment used: FP83HT dropping point and softening point measurement system manufactured by (Mettler-Toledo)
Measurement conditions: temperature increase rate of 2° C./min
Measurement method: Measurement was made in accordance with a manual of FP83HT. Specifically, a molten sample was poured into a sample cup and allowed to cool and solidify. The top and bottom of the cup which was filled with the sample were fitted into a cartridge, which was inserted into the furnace. The temperature when the resin was softened and flown down through the orifice and the lower end of the resin was passed through the optical path was detected with a photocell as the softening point.

### (Measurement of Melt Viscosity)

The melt viscosity at 150° C. was measured using the following equipment.

Equipment used: B type viscometer DV2T (manufactured by BROOKFIELD, EKO INSTRUMENTS CO., LTD.).

Measurement temperature: 150° C.

Measurement method: The temperature in the furnace of the B type viscometer was set to 150° C. and a predetermined amount of sample was weighed in a cup. The cup in which the sample was weighed was put in the furnace to melt the resin, and a spindle was inserted from the upper portion. The spindle was allowed to rotate, and the value at which the displayed viscosity value was stabilized was taken as the melt viscosity.

### (Synthesis Working Example X1) Synthesis of Resin XA

To a container (internal capacity: 200 ml) equipped with a stirrer, a condenser tube, and a burette, a raw material XA (5.0 g), 0.774 g (6.9 mmol) of tert-butoxypotassium and 20 mL of tetrahydrofuran were fed, and 3.16 g (27.6 mmol) of mesyl chloride was further added. The reaction solution was stirred at 40° C. for 6 hours and reacted. Then, 10 ml of 1% H₂SO₄ aqueous solution and 20 ml of ethyl acetate were added into the container, and subsequently, the aqueous layer was removed by liquid separation. Then, the organic solvent was removed by concentration, followed by drying to obtain 5.1 g of an oligomer (resin XA) having a structural unit represented by the following formula. The weight average molecular weight of the obtained oligomer measured in terms of polystyrene by GPC was 1250, and the dispersibility was 1.31.

¹H-NMR measurement was performed on the obtained oligomer. The peak near 9.1-9.4 ppm indicating the phenolic hydroxy group was not confirmed, and all the hydroxyl groups in the raw material XA were found to be protected by Ms groups (mesyl groups/methanesulfonyl groups). The softening point was 28° C.

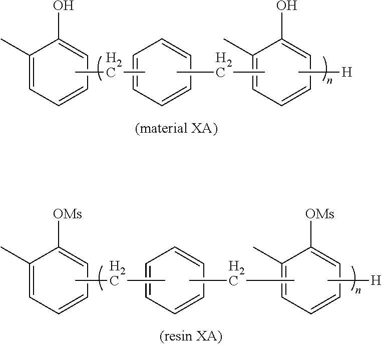

### (Synthesis Working Example X2) Synthesis of Resin XB

To a container (internal capacity: 200 ml) equipped with a stirrer, a condenser tube, and a burette, a raw material XB (5.0 g, manufactured by Meiwa Plastic Industries, Ltd.), 0.698 g (6.9 mmol) of triethylamine, and 20 mL of methylene chloride were fed, and 7.73 g (27.4 mmol) of trifluoromethanesulfonic anhydride was further added. The reaction solution was stirred at 0° C. for 6 hours and reacted. Then, 10 ml of 1% H₂SO₄ aqueous solution and 20 ml of ethyl acetate were added into the container, and subsequently, the aqueous layer was removed by liquid separation. Then, the organic solvent was removed by concentration, and the reaction solution was added dropwise to hexane. Subsequently, the hexane was removed, followed by drying to obtain 5.3 g of an oligomer (B-p-CBIF-AL) having a structural unit represented by the following formula. The weight average molecular weight of the obtained oligomer measured in terms of polystyrene by GPC was 1400, and the dispersibility was 1.46.

¹H-NMR measurement was performed on the obtained oligomer. The peak near 3.4-3.7 ppm indicating the proton of aniline was 52% as compared with the raw material, and the raw material XB was found to be protected by the Tf group (triflate group/trifluoromethylsulfonyl group). The softening point was 23° C.

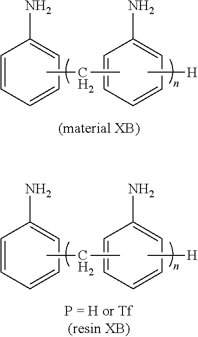

### (Synthesis Working Example X3) Synthesis of Resin XC

To a container (internal capacity: 200 ml) equipped with a stirrer, a condenser tube, and a burette, a raw material XC (5.0 g, manufactured by Meiwa Plastic Industries, Ltd.), 0.693 g (6.90 mmol) of triethylamine, and 20 mL of tetrahydrofuran were fed, and 2.80 g (27.4 mmol) of acetic anhydride was further added. The reaction solution was stirred at 40° C. for 2 hours and reacted. Then, 10 ml of 1% H₂SO₄ aqueous solution and 20 ml of ethyl acetate were added into the container, and subsequently, the aqueous layer was removed by liquid separation. Then, the organic solvent was removed by concentration, followed by drying to obtain 5.0 g of an oligomer (E-n-BBIF-AL) having a structural unit represented by the following formula. The weight average molecular weight of the obtained oligomer measured in terms of polystyrene by GPC was 1100, and the dispersibility was 1.33.

¹H-NMR measurement was performed on the obtained oligomer. The peak near 9.1-9.4 ppm indicating the phenolic hydroxy group was not confirmed, and 100% of the hydroxyl groups before reaction were found to be protected by Ac groups (acetyl groups). The softening point was 12° C.

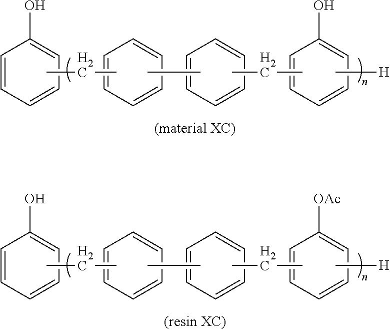

### (Synthesis Working Example Y1) Synthesis of Resin YA

To a container (internal capacity: 200 ml) equipped with a stirrer, a condenser tube, and a burette, a raw material YA (5.0 g, manufactured by Meiwa Plastic Industries, Ltd.), 7.56 g (54.7 mmol) of potassium carbonate, and 20 mL of dimethylformamide were fed, and 4.92 g (54.6 mmol) of dimethyl carbonate was further added. The reaction solution was stirred at 120° C. for 14 hours and reacted. Then, 10 ml of 1% H₂SO₄ aqueous solution and 20 ml of ethyl acetate were added into the container, and subsequently, the aqueous layer was removed by liquid separation. Then, the organic solvent was removed by concentration, followed by drying to obtain 5.1 g of an oligomer (resin YA) having a structural unit represented by the following formula. The weight average molecular weight of the obtained oligomer measured in terms of polystyrene by GPC was 900, and the dispersibility was 1.28.

¹H-NMR measurement was performed on the obtained oligomer. The peak near 3.4-3.7 ppm indicating the proton of aniline was not confirmed, and the raw material YA was found to be protected by the methyl group. The softening point was 9° C.

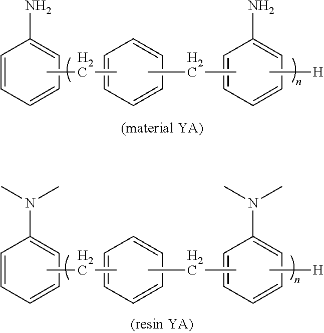

### (Synthesis Working Example Y2) Synthesis of Resin YB

To a container (internal capacity: 200 ml) equipped with a stirrer, a condenser tube, and a burette, a raw material YB (5.0 g, manufactured by Meiwa Plastic Industries, Ltd.), 1.73 g (6.9 mmol) of pyridinium p-toluenesulfonate, and 20 mL of tetrahydrofuran were fed, and 2.36 g (27.4 mmol) of ethylvinyl ether was further added. The reaction solution was stirred at 35° C. for 9 hours and reacted. Then, 10 ml of 10% aqueous sodium carbonate solution and 20 ml of ethyl acetate were added into the container, and subsequently, the aqueous layer was removed by liquid separation. Then, the organic solvent was removed by concentration, and the reaction solution was added dropwise to hexane. Subsequently, the hexane was removed, followed by drying to obtain 5.3 g of an oligomer (resin YB) having a structural unit represented by the following formula. The weight average molecular weight of the obtained oligomer measured in terms of polystyrene by GPC was 900, and the dispersibility was 1.32.

¹H-NMR measurement was performed on the obtained oligomer. The peak near 9.1-9.4 ppm indicating the phenolic hydroxy group was not confirmed, and 100% of the hydroxyl groups before reaction were found to be protected by EE groups (ethoxyethyl groups). The softening point was −14° C.

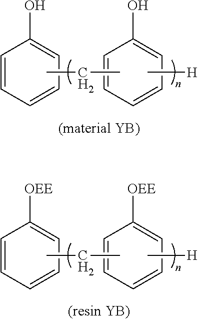

### (Synthesis Working Example Y3) Synthesis of Resin YC

To a container (internal capacity: 200 ml) equipped with a stirrer, a condenser tube, and a burette, a raw material YC (5.0 g, manufactured by Meiwa Plastic Industries, Ltd.), 1.73 g (6.9 mmol) of pyridinium p-toluenesulfonate, and 20 mL of tetrahydrofuran were fed, and 2.36 g (27.4 mmol) of propylvinyl ether was further added. The reaction solution was stirred at 40° C. for 2 hours and reacted. Then, 10 ml of 10% aqueous sodium carbonate solution and 20 ml of ethyl acetate were added into the container, and subsequently, the aqueous layer was removed by liquid separation. Then, the organic solvent was removed by concentration, followed by drying to obtain 5.0 g of an oligomer (resin YC) having a structural unit represented by the following formula. The weight average molecular weight of the obtained oligomer measured in terms of polystyrene by GPC was 1000, and the dispersibility was 1.28.

¹H-NMR measurement was performed on the obtained oligomer. The peak near 9.1-9.4 ppm indicating the phenolic hydroxy group was not confirmed, and 100% of the hydroxyl groups before reaction were found to be protected by EP groups (ethoxypropyl groups). The softening point was −20° C.

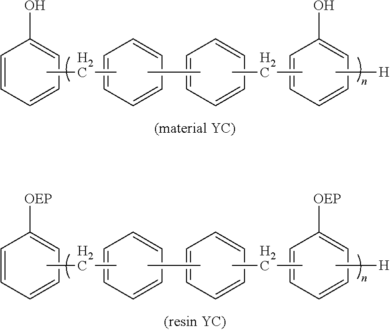

### (Synthesis Working Example Y4) Synthesis of Resin YD

To a container (internal capacity: 200 ml) equipped with a stirrer, a condenser tube, and a burette, a raw material YD (5.0 g), 0.698 g (6.9 mmol) of triethylamine, and 20 mL of tetrahydrofuran were fed, and 2.53 g (27.4 mmol) of epichlorohydrin was further added. The reaction solution was stirred at room temperature for 2 hours and reacted. Then, 10 ml of H₂O and 20 ml of ethyl acetate were added into the container, and subsequently, the aqueous layer was removed by liquid separation. Then, the organic solvent was removed by concentration, followed by drying to obtain 5.3 g of an oligomer (resin YD) having a structural unit represented by the following formula. The weight average molecular weight of the obtained oligomer measured in terms of polystyrene by GPC was 1200, and the dispersibility was 1.21.

¹H-NMR measurement was performed on the obtained oligomer. The peak near 9.1-9.4 ppm indicating the phenolic hydroxy group was not confirmed, and 100% of the hydroxyl groups before reaction were found to be protected by glycidyl groups. The softening point was 13° C.

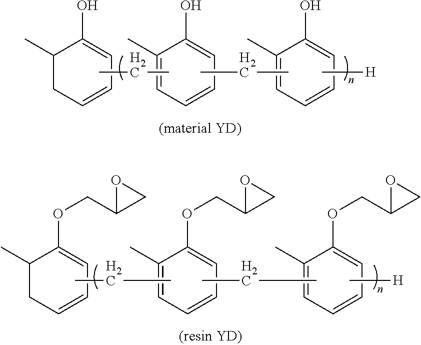

### Examples X1 to X3, Comparative Example X1, Examples Y1 to Y4, and Comparative Example Y1

For the above resins XA to XC, resins YA to YD and phenol novolac resins (PSM4357 manufactured by Gunei Chemical Industry Co., Ltd.) as Comparative Examples X1 and Y1, the solubility test and heat resistance evaluation shown below were carried out. The results are shown in Tables 1-1 and 1-2.

### (Evaluation of Solubility)

At 23° C., the oligomer of the present embodiment was dissolved in propylene glycol monomethyl ether acetate (PGMEA) or 1-methoxy-2-propanol (PGME) to form a 30 mass % solution. Subsequently, the solubility after leaving the solution to stand still at −20° C. for 30 days was evaluated according to the following criteria.
Evaluation A: no precipitate was visually confirmed
Evaluation C: precipitates were visually confirmed

### (Evaluation of Solution Viscosity)

At 23° C., the solution viscosity of a 30 mass % solution of the oligomer of the present embodiment in propylene glycol monomethyl ether acetate (PGMEA) was measured.

### [Evaluation Criteria]

A: 10 (mPa·s*g/cm³) or less
B: 10 to 20 (mPa·s*g/cm³)
C: 20 (mPa·s*g/cm³) or more

TABLE 1-1

| | Compound | Evaluation of | | Evaluation of |
|---|---|---|---|---|
| | or resin | solubility | | viscosity |
| | (parts by mass) | PGMEA | PGME | solution |
| Example X1 | Resin XA | A | A | A |
| | (30) | | | |
| Example X2 | Resin XB | A | A | A |
| | (30) | | | |
| Example X3 | Resin XC | A | A | A |
| | (30) | | | |
| Comparative | Phenol novolac | A | A | C |
| Example X1 | resin (30) | | | |

TABLE 1-2

| | Compound | Evaluation of | | Evaluation of |
|---|---|---|---|---|
| | or resin | solubility | | viscosity |
| | (parts by mass) | PGMEA | PGME | solution |
| Example Y1 | Resin YA | A | A | A |
| | (30) | | | |
| Example Y2 | Resin YB | A | A | A |
| | (30) | | | |
| Example Y3 | Resin YC | A | A | A |
| | (30) | | | |
| Example Y4 | Resin YD | A | A | A |
| | (30) | | | |
| Comparative | Phenol novolac | A | A | C |
| Example Y1 | resin (30) | | | |

### Examples X1-1 to X3-2, Comparative Examples X1-1 to X1-2, Examples Y1-1 to Y4-2, and Comparative Examples Y1-1 to Y1-2

Each underlayer film forming composition for lithography was prepared.

The following acid generating agent, crosslinking agent, and organic solvent were used.

Acid generating agent: a product manufactured by Midori Kagaku Co., Ltd., “di-tertiary butyl diphenyliodonium nonafluoromethanesulfonate” (in the table, designated as “DTDPI”)

Acid generating agent: pyridinium p-toluenesulfonate (in the table, designated as “PPTS”)

Crosslinking agent: a product manufactured by Sanwa Chemical Co., Ltd., “NIKALAC MX270” (in the table, designated as “NIKALAC”)
a product manufactured by Honshu Chemical Industry Co., Ltd., “TMOM-BP” (in the table, designated as “TMOM”)
Organic solvent: PGMEA/PGME=7:3
   PGMEA: propylene glycol monomethyl ether acetate (PGMEA)
   PGME: 1-methoxy-2-propanol

### [Curing Property Test]

A silicon substrate was spin coated with each underlayer film forming composition for lithography of Examples X1-1 to X3-2, Comparative Examples X1-1 to X1-2, Examples Y1-1 to Y4-2, and Comparative Examples Y1-1 to Y1-2, and then baked at 250° C. or 400° C. for 60 seconds to prepare each underlayer film. Each underlayer film obtained was immersed in PGMEA for 120 seconds and then dried at 110° C. for 60 seconds on a hot plate, and the state of each remaining film was confirmed. The results are shown in Tables 2-1 and 2-2. Curing properties were evaluated by the following evaluation criteria.

<Evaluation Criteria>
A: A remaining film was visually observed at both temperatures
C: No remaining film was visually observed at both temperatures

### [Reduction in Film Thickness]

A silicon substrate was spin coated with each underlayer film forming composition for lithography of Examples X1-1 to X3-2 and Comparative Examples X1-1 to X1-2. The film obtained was baked at 150° C. for 60 seconds, and then baked at 400° C. for 60 seconds, and the film thickness reduction rate was measured. The results are shown in Table 2-1.

Curing properties were evaluated by the following evaluation criteria.

<Evaluation Criteria>
A: reduction rate of 20% or less
B: reduction rate of 20 to 30%
C: reduction rate of 30% or more

A silicon substrate was spin coated with each underlayer film forming composition for lithography of Examples Y1-1 to Y4-2 and Comparative Examples Y1-1 to Y1-2. The film obtained was baked at 150° C. for 60 seconds, and then baked at 400° C. for 60 seconds, and the film thickness reduction rate was measured. The results are shown in Table 2-2.

Curing properties were evaluated by the following evaluation criteria.

<Evaluation Criteria>
A: reduction rate of 10% or less
B: reduction rate of 10 to 20%
C: reduction rate of 30% or more

TABLE 2-1

| | | | Acid | | | |
|---|---|---|---|---|---|---|
| | | Crosslinking | generating | | | |
| | Resin | agent | agent | | | Reduction |
| | (parts by | (parts by | (parts by | Solvent | Curing | in film |
| | mass) | mass) | mass) | (parts by mass) | property | thickness |
| Example X | Resin | NIKALAC | DTDPI | PGMEA/PGME = 7:3 | A | B |
| 1-1 | XA | (2.0) | (0.25) | (90) | | |
| | (10) | | | | | |
| Example X | Resin | TMOM | PPTS | PGMEA/PGME = 7:3 | A | A |
| 1-2 | XA | (2.0) | (0.25) | (90) | | |
| | (10) | | | | | |
| Example X | Resin | NIKALAC | DTDPI | PGMEA/PGME = 7:3 | A | B |
| 2-1 | XB | (2.0) | (0.25) | (90) | | |
| | (10) | | | | | |
| Example X | Resin | TMOM | PPTS | PGMEA/PGME = 7:3 | A | A |
| 2-2 | XB | (2.0) | (0.25) | (90) | | |
| | (10) | | | | | |
| Example X | Resin | NIKALAC | DTDPI | PGMEA/PGME = 7:3 | A | B |
| 3-1 | XC | (2.0) | (0.25) | (90) | | |
| | (10) | | | | | |
| Example X | Resin | TMOM | PPTS | PGMEA/PGME = 7:3 | A | A |
| 3-2 | XC | (2.0) | (0.25) | (90) | | |
| | (10) | | | | | |
| Comparative | Phenol | NIKALAC | DTDPI | PGMEA/PGME = 7:3 | C | C |
| Example X | novolac | (2.0) | (0.25) | (90) | | |
| 1-1 | resin | | | | | |
| | (10) | | | | | |
| Comparative | Phenol | TMOM | PPTS | PGMEA/PGME = 7:3 | C | C |
| Example X | novolac | (2.0) | (0.25) | (90) | | |
| 1-2 | resin | | | | | |
| | (10) | | | | | |

TABLE 2-2

| | Resin | Crosslinking | Acid generating | | | Reduction |
|---|---|---|---|---|---|---|
| | (parts by | agent | agent | Solvent | Curing | in film |
| | mass | (parts by mass) | (parts by mass) | (parts by mass) | property | thickness |
| Example Y | Resin YA | NIKALAC | DTDPI | PGMEA/PGME = 7:3 | A | B |
| 1-1 | (10) | (2.0 | (0.25) | (90) | | |
| Example Y | Resin YA | TMOM | PPTS | PGMEA/PGME = 7:3 | A | A |
| 1-2 | (10) | (2.0) | (0.25) | (90) | | |
| Example Y | Resin YB | NIKALAC | DTDPI | PGMEA/PGME = 7:3 | A | A |
| 2-1 | (10) | 2.0) | (0.25) | (90) | | |
| Example Y | Resin YB | TMOM | PPTS | PGMEA/PGME = 7:3 | A | A |
| 2-2 | (10) | (2.0) | (0.25) | (90) | | |
| Example Y | Resin YC | NIKALAC | DTDPI | PGMEA/PGME = 7:3 | A | A |
| 3-1 | (10) | (2.0) | (0.25) | (90) | | |
| Example Y | Resin YC | TMOM | PPTS | PGMEA/PGME = 7:3 | A | A |
| 3-2 | (10) | (2.0) | (0.25) | (90) | | |
| Example Y | Resin YD | NIKALAC | DTDPI | PGMEA/PGME = 7:3 | A | A |
| 4-1 | (10) | (2.0) | (0.25) | (90) | | |
| Example Y | Resin YD | TMOM | PPTS | PGMEA/PGME = 7:3 | A | A |
| 4-2 | (10) | (2.0) | (0.25) | (90) | | |
| Comparative | Phenol | NIKALAC | DTDPI | PGMEA/PGME = 7:3 | C | C |
| Example Y | novolac resin | (2.0) | (0.25) | (90) | | |
| 1-1 | (10) | | | | | |
| Comparative | Phenol | TMOM | PPTS | PGMEA/PGME = 7:3 | C | C |
| Example Y | novolac resin | (2.0 | (0.25) | (90) | | |
| 1-2 | (10) | | | | | |

### [Evaluation of Embedding Properties]

The embedding properties to an uneven substrate were evaluated by the following procedures.

A SiO₂ substrate having a line and space pattern of 60 nm was coated with each composition for underlayer film formation for lithography, and baked at 400° C. for 60 seconds to form a 100 nm film. The cross section of the obtained film was cut out and observed under an electron microscope to evaluate the embedding properties to an uneven substrate. The results are shown in Tables 3-1 and 3-2.

### <Evaluation Criteria>

A: The underlayer film was embedded without defects in the asperities of the SiO₂ substrate.
C: The underlayer film was not embedded with defects in the asperities of the SiO₂ substrate.

### [Evaluation of Smoothing Properties]

A SiO₂ uneven substrate having a trench with a width of 60 nm, a pitch of 60 nm, and a depth of 200 nm was coated with each film forming composition obtained above. Subsequently, it was calcined at 400° C. for 60 seconds under the air atmosphere to form an underlayer film with a film thickness of 100 nm. The shape of this underlayer film was observed with a scanning electron microscope (“S-4800” from Hitachi High-Technologies Corporation), and the difference between the minimum value of the film thickness on the trench and the maximum value of the film thickness on a part not having the trench (ΔFT) was measured. The results are shown in Tables 3-1 and 3-2.

### <Evaluation Criteria>

S: ΔFT<10 nm (best flatness)
A: 10 nm≤ΔFT<20 nm (good flatness)
B: 20 nm≤ΔFT<40 nm (partially good flatness)
C: 40 nm≤ΔFT (poor flatness)

TABLE 3-1

| | Resin | Crosslinking | Acid generating | | | |
|---|---|---|---|---|---|---|
| | (parts by | agent | agent | Solvent | Embedding | Smoothing |
| | mass | (parts by mass) | (parts by mass) | (parts by mass) | property | property |
| Example X | Resin XA | NIKALAC | DTDPI | PGMEA/PGME = 7:3 | A | A |
| 1-1 | (10) | (2.0 | (0.25) | (90) | | |
| Example X | Resin XA | TMOM | PPTS | PGMEA/PGME = 7:3 | A | S |
| 1-2 | (10) | (2.0) | (0.25) | (90) | | |
| Example X | Resin XB | NIKALAC | DTDPI | PGMEA/PGME = 7:3 | A | A |
| 2-1 | (10) | (2.0) | (0.25) | (90) | | |
| Example X | Resin XB | TMOM | PPTS | PGMEA/PGME = 7:3 | A | S |
| 2-2 | (10) | (2.0) | (0.25) | (90) | | |
| Example X | Resin XC | NIKALAC | DTDPI | PGMEA/PGME = 7:3 | A | S |
| 3-1 | (10) | (2.0) | (0.25) | (90) | | |
| Example X | Resin XC | TMOM | PPTS | PGMEA/PGME = 7:3 | A | S |
| 3-2 | (10) | (2.0 | (0.25) | (90) | | |
| Comparative | Phenol | NIKALAC | DTDPI | PGMEA/PGME = 7:3 | C | C |
| Example X | novolac | (2.0) | (0.25) | (90) | | |
| 1-1 | resir | | | | | |
| | (10) | | | | | |
| Comparative | Phenol | TMOM | PPTS | PGMEA/PGME = 7:3 | C | C |
| Example X | novolac | (2.0) | (0.25) | (90) | | |
| 1-2 | resin | | | | | |
| | (10) | | | | | |

TABLE 3-2

| | Resin | Crosslinking | Acid generating | | | |
|---|---|---|---|---|---|---|
| | (parts by | agent | agent | Solvent | Embedding | Smoothing |
| | mass | (parts by mass) | (parts by mass) | (parts by mass) | property | property |
| Example Y | Resin YA | NIKALAC | DTDPI | PGMEA/PGME = 7:3 | A | B |
| 1-1 | (10) | (2.0) | (0.25) | (90) | | |
| Example Y | Resin YA | TMOM | PPTS | PGMEA/PGME = 7:3 | A | A |
| 1-2 | (10) | (2.0) | (0.25) | (90) | | |
| Example Y | Resin YB | NIKALAC | DTDPI | PGMEA/PGME = 7:3 | A | A |
| 2-1 | (10) | 2.0) | (0.25) | (90) | | |
| Example Y | Resin YB | TMOM | PPTS | PGMEA/PGME = 7:3 | A | S |
| 2-2 | (10) | (2.0) | (0.25) | (90) | | |
| Example Y | Resin YC | NIKALAC | DTDPI | PGMEA/PGME = 7:3 | A | S |
| 3-1 | (10) | (2.0) | (0.25) | (90) | | |
| Example Y | Resin YC | TMOM | PPTS | PGMEA/PGME = 7:3 | A | S |
| 3-2 | (10) | (2.0) | (0.25) | (90) | | |
| Example Y | Resin YD | NIKALAC | DTDPI | PGMEA/PGME = 7:3 | A | A |
| 4-1 | (10) | (2.0 | (0.25) | (90) | | |
| Example Y | Resin YD | TMOM | PPTS | PGMEA/PGME = 7:3 | A | S |
| 4-2 | (10) | (2.0) | (0.25) | (90) | | |
| Comparative | Phenol | NIKALAC | DTDPI | PGMEA/PGME = 7:3 | C | C |
| Example Y | novolac | (2.0) | (0.25) | (90) | | |
| 1-1 | resin | | | | | |
| | (10) | | | | | |
| Comparative | Phenol | TMOM | PPTS | PGMEA/PGME = 7:3 | C | C |
| Example Y | novolac | (2.0) | (0.25) | (90) | | |
| 1-2 | resin | | | | | |
| | (10) | | | | | |

### [Evaluation of Crosslinkability]

A silicon substrate was spin coated with each underlayer film forming composition for lithography of Examples X1-1 to X3-2 and Comparative Examples X1-1 to X1-2. Each film obtained was baked at 150° C. for 60 seconds, then immersed in PGMEA for 120 seconds, and dried at 110° C. for 60 seconds on a hot plate, and subsequently, the film remaining rate was confirmed. Crosslinkability was evaluated by the following evaluation criteria. The results are shown in Table 4-1.

<Evaluation Criteria>
S: film remaining rate of 0%
A: film remaining rate of 0 to 10%
B: film remaining rate of 10 to 30%
C: film remaining rate of 30% or more

A silicon substrate was spin coated with each underlayer film forming composition for lithography of Examples Y1-1 to Y4-2 and Comparative Examples Y1-1 to Y1-2. Each film obtained was baked at 150° C. for 60 seconds, then immersed in PGMEA for 120 seconds, and dried at 110° C. for 60 seconds on a hot plate, and subsequently, the film remaining rate was confirmed. Crosslinkability was evaluated by the following evaluation criteria. The results are shown in Table 4-2.

<Evaluation Criteria>
S: film remaining rate of 90% or more
A: film remaining rate of 80 to 90%
B: film remaining rate of 70 to 80%
C: film remaining rate of 70% or less

### [Evaluation of Film Heat Resistance]

A silicon substrate was spin coated with each underlayer film forming composition for lithography of Examples X1-1 to X3-2 and Comparative Examples X1-1 to X1-2, and then baked at 400° C. for 60 seconds to prepare each underlayer film. The underlayer film obtained was calcined under N2 at 450° C. for 4 minutes, and the film thickness reduction rate was measured. The results are shown in Table 4. Film heat resistance was evaluated by the following evaluation criteria.

<Evaluation Criteria>
A: reduction rate of 20% or less
B: reduction rate of 20 to 30%
C: reduction rate of 30% or more

A silicon substrate was spin coated with each underlayer film forming composition for lithography of Examples Y1-1 to Y4-2 and Comparative Examples Y1-1 to Y1-2, and then baked at 400° C. for 60 seconds to prepare each underlayer film. The underlayer film obtained was calcined under N2 at 450° C. for 4 minutes, and the film thickness reduction rate was measured. The results are shown in Table 4-2. Film heat resistance was evaluated by the following evaluation criteria.

<Evaluation Criteria>
A: reduction rate of 10% or less
B: reduction rate of 10 to 20%
C: reduction rate of 20% or more

TABLE 4-1

| | Resin | Crosslinking | Acid generating | | | |
|---|---|---|---|---|---|---|
| | (parts by | agent | agent | Solvent | | Film heat |
| | mass | (parts by mass) | (parts by mass) | (parts by mass) | Crosslinkability | resistance |
| Example X | Resin | NIKALAC | DTDPI | PGMEA/PGME = 7:3 | A | B |
| 1-1 | XA | (2.0) | (0.25) | (90) | | |
| | (10) | | | | | |
| Example X | Resin | TMOM | PPTS | PGMEA/PGME = 7:3 | A | A |
| 1-2 | XA | (2.0) | (0.25) | (90) | | |
| | (10) | | | | | |
| Example X | Resin | NIKALAC | DTDPI | PGMEA/PGME = 7:3 | S | A |
| 2-1 | XB | (2.0) | (0.25) | (90) | | |
| | (10) | | | | | |
| Example X | Resin | TMOM | PPTS | PGMEA/PGME = 7:3 | S | A |
| 2-2 | XB | (2.0) | (0.25) | (90) | | |
| | (10) | | | | | |
| Example X | Resin | NIKALAC | DTDPI | PGMEA/PGME = 7:3 | S | B |
| 3-1 | XC | (2.0) | (0.25) | (90) | | |
| | (10) | | | | | |
| Example X | Resin | TMOM | PPTS | PGMEA/PGME = 7:3 | S | A |
| 3-2 | XC | (2.0) | (0.25) | (90) | | |
| | (10) | | | | | |
| Comparative | Phenol | NIKALAC | DTDPI | PGMEA/PGME = 7:3 | C | C |
| Example X | novolac | (2.0) | (0.25) | (90) | | |
| 1-1 | resin | | | | | |
| | (10) | | | | | |
| Comparative | Phenol | TMOM | PPTS | PGMEA/PGME = 7:3 | C | C |
| Example X | novolac | (2.0) | (0.25) | (90) | | |
| 1-2 | resin | | | | | |
| | (10) | | | | | |

TABLE 4-2

| | Resin | Crosslinking | Acid generating | | | |
|---|---|---|---|---|---|---|
| | (parts by | agent | agent | Solvent | | Film heat |
| | mass | (parts by mass) | (parts by mass) | (parts by mass) | Crosslinkability | resistance |
| Example Y | Resin | NIKALAC | DTDPI | PGMEA/PGME = 7:3 | A | B |
| 1-1 | YA | (2.0) | (0.25) | (90) | | |
| | (10) | | | | | |
| Example Y | Resin | TMOM | PPTS | PGMEA/PGME = 7:3 | A | A |
| 1-2 | YA | (2.0) | (0.25) | (90) | | |
| | (10) | | | | | |
| Example Y | Resin | NIKALAC | DTDPI | PGMEA/PGME = 7:3 | S | A |
| 2-1 | YB | (2.0) | (0.25) | (90) | | |
| | (10) | | | | | |
| Example Y | Resin | TMOM | PPTS | PGMEA/PGME = 7:3 | S | A |
| 2-2 | YB | (2.0) | (0.25) | (90) | | |
| | (10) | | | | | |
| Example Y | Resin | NIKALAC | DTDPI | PGMEA/PGME = 7:3 | S | A |
| 3-1 | YC | (2.0) | (0.25) | (90) | | |
| | (10) | | | | | |
| Example Y | Resin | TMOM | PPTS | PGMEA/PGME = 7:3 | S | A |
| 3-2 | YC | (2.0) | (0.25) | (90) | | |
| | (10) | | | | | |
| Example Y | Resin | NIKALAC | DTDPI | PGMEA/PGME = 7:3 | A | A |
| 4-1 | YD | (2.0) | (0.25) | (90) | | |
| | (10) | | | | | |
| Example Y | Resin | TMOM | PPTS | PGMEA/PGME = 7:3 | S | A |
| 4-2 | YD | (2.0) | (0.25) | (90) | | |
| | (10) | | | | | |
| Comparative | Phenol | NIKALAC | DTDPI | PGMEA/PGME = 7:3 | C | C |
| Example Y | novolac | (2.0) | (0.25) | (90) | | |
| 1-1 | resin | | | | | |
| | (10) | | | | | |
| Comparative | Phenol | TMOM | PPTS | PGMEA/PGME = 7:3 | C | C |
| Example Y | novolac | (2.0) | (0.25) | (90) | | |
| 1-2 | resin | | | | | |
| | (10) | | | | | |

For each of the obtained underlayer films, etching test was carried out under the following conditions to evaluate etching resistance.

### [Etching Test]

Etching apparatus: a product manufactured by Samco International, Inc., “RIE-10NR”
Output: 50 W
Pressure: 20 Pa
Time: 2 min
Etching gas
Ar gas flow rate:CF₄ gas flow rate:O₂ gas flow rate=50:5:5 (sccm)

### [Evaluation of Etching Resistance]

The evaluation of etching resistance was carried out by the following procedures.

The above etching test was carried out for the underlayer film containing the phenol novolac resin of Comparative Example X1-1, and the etching rate (etching speed) was measured. Next, for each of the underlayer films of Examples and Comparative Examples, the above etching test was conducted, and the etching rate at that time was measured. Then, the etching resistance for each of Examples and Comparative Example was evaluated according to the following evaluation criteria on the basis of the etching rate of the underlayer film containing a phenol novolac resin. The evaluation results are shown in Table 5-1.

The above etching test was carried out for the underlayer film containing the phenol novolac resin of Comparative Example Y1-1, and the etching rate (etching speed) was measured. Next, for each of the underlayer films of Examples and Comparative Examples, the above etching test was conducted, and the etching rate at that time was measured. Then, the etching resistance for each of Examples and Comparative Example was evaluated according to the following evaluation criteria on the basis of the etching rate of the underlayer film containing a phenol novolac resin. The evaluation results are shown in Table 5-2.

### <Evaluation Criteria>

A: The etching rate was less than −10% as compared with the underlayer film of novolac.
B: The etching rate was −10% to +5% as compared with the underlayer film of novolac.
C: The etching rate was more than +5% as compared with the underlayer film of novolac.

TABLE 5-1

| | | | Acid | | |
|---|---|---|---|---|---|
| | | Crosslinking | generating | | |
| | Resin | agent | agent | | |
| | (parts by | (parts by | (parts by | Solvent | Etching |
| | mass) | mass) | mass) | (parts by mass) | resistance |
| Example X | Resin XA | NIKALAC | DTDPI | PGMEA/PGME = 7:3 | A |
| 1-1 | (10) | (2.0) | (0.25) | (90) | |
| Example X | Resin XA | TMOM | PPTS | PGMEA/PGME = 7:3 | A |
| 1-2 | (10) | (2.0) | (0.25) | (90) | |
| Example X | Resin XB | NIKALAC | DTDPI | PGMEA/PGME = 7:3 | A |
| 2-1 | (10) | (2.0) | (0.25) | (90 | |
| Example X | Resin XB | TMOM | PPTS | PGMEA/PGME = 7:3 | A |
| 2-2 | (10) | (2.0) | (0.25) | (90) | |
| Example X | Resin XC | NIKALAC | DTDPI | PGMEA/PGME = 7:3 | B |
| 3-1 | (10) | (2.0) | (0.25) | (90) | |
| Example X | Resin XC | TMOM | PPTS | PGMEA/PGME = 7:3 | B |
| 3-2 | (10) | (2.0) | (0.25) | (90) | |
| Comparative | Phenol novolac | NIKALAC | DTDPI | PGMEA/PGME = 7:3 | — |
| Example | resin (10) | (2.0) | (0.25) | (90) | |
| X1-1 | | | | | |
| Comparative | Phenol novolac | TMOM | PPTS | PGMEA/PGME = 7:3 | B |
| Example X | resin (10) | (2.0) | (0.25) | (90) | |
| 1-2 | | | | | |

TABLE 5-2

| | | | Acid | | |
|---|---|---|---|---|---|
| | | Crosslinking | generating | | |
| | Resin | agent | agent | | |
| | (parts by | (parts by | (parts by | Solvent | Etching |
| | mass) | mass) | mass) | (parts by mass) | resistance |
| Example Y | Resin YA | NIKALAC | DTDPI | PGMEA/PGME = 7:3 | B |
| 1-1 | (10) | (2.0) | (0.25) | (90) | |
| Example Y | Resin YA | TMOM | PPTS | PGMEA/PGME = 7:3 | B |
| 1-2 | (10) | (2.0) | (0.25) | (90) | |
| Example Y | Resin YB | NIKALAC | DTDPI | PGMEA/PGME = 7:3 | A |
| 2-1 | (10) | (2.0) | (0.25) | (90) | |
| Example Y | Resin YB | TMOM | PPTS | PGMEA/PGME = 7:3 | A |
| 2-2 | (10) | (2.0) | (0.25) | (90) | |
| Example Y | Resin YC | NIKALAC | DTDPI | PGMEA/PGME = 7:3 | A |
| 3-1 | (10) | (2.0) | (0.25) | (90) | |
| Example Y | Resin YC | TMOM | PPTS | PGMEA/PGME = 7:3 | A |
| 3-2 | (10) | (2.0) | (0.25) | (90) | |
| Example Y | Resin YD | NIKALAC | DTDPI | PGMEA/PGME = 7:3 | B |
| 4-1 | (10) | (2.0) | (0.25) | (90) | |
| Example Y | Resin YD | TMOM | PPTS | PGMEA/PGME = 7:3 | A |
| 4-2 | (10) | (2.0) | (0.25) | (90) | |
| Comparative | Phenol novolac | NIKALAC | DTDPI | PGMEA/PGME = 7:3 | — |
| Example Y | resin (10) | (2.0) | (0.25) | (90) | |
| 1-1 | | | | | |
| Comparative | Phenol novolac | TMOM | PPTS | PGMEA/PGME = 7:3 | B |
| Example Y | resin (10) | (2.0) | (0.25) | (90) | |
| 1-2 | | | | | |

### Examples X4 to X9 and Examples Y5 to Y12

A SiO₂ substrate with a film thickness of 300 nm was coated with each solution of the underlayer film forming material for lithography prepared in the same manner as in each of the above Examples X1-1 to X3-2 and Examples Y1-1 to Y4-2, and baked at 150° C. for 60 seconds and further at 400° C. for 120 seconds to form each underlayer film with a film thickness of 70 nm. This underlayer film was coated with a resist solution for ArF and baked at 130° C. for 60 seconds to form a photoresist layer with a film thickness of 140 nm. The ArF resist solution used was prepared by compounding 5 parts by mass of a compound represented by the formula (xx) given below, 1 part by mass of triphenylsulfonium nonafluoromethanesulfonate, 2 parts by mass of tributylamine, and 92 parts by mass of PGMEA. For the compound represented by the formula (xx) given below, 4.15 g of 2-methyl-2-methacryloyloxyadamantane, 3.00 g of methacryloyloxy-γ-butyrolactone, 2.08 g of 3-hydroxy-1-adamantyl methacrylate, and 0.38 g of azobisisobutyronitrile were dissolved in 80 mL of tetrahydrofuran to prepare a reaction solution. This reaction solution was polymerized for 22 hours with the reaction temperature kept at 63° C. in a nitrogen atmosphere. Then, the reaction solution was added dropwise into 400 mL of n-hexane. The product resin thus obtained was solidified and purified, and the resulting white powder was filtered and dried overnight at 40° C. under reduced pressure to obtain a compound represented by the following formula.

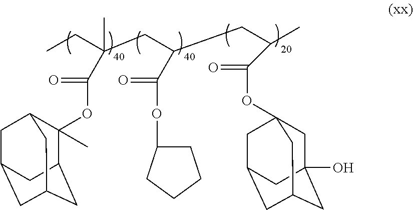

The numbers in the above formula (xx) indicate the ratio of each constitutional unit.

Subsequently, the photoresist layer was exposed using an electron beam lithography system (manufactured by ELIONIX INC.; ELS-7500, 50 keV), baked (PEB) at 115° C. for 90 seconds, and developed for 60 seconds in a 2.38 mass % tetramethylammonium hydroxide (TMAH) aqueous solution to obtain a positive type resist pattern.

Defects of the obtained resist patterns of 55 nm L/S (1:1) and 80 nm L/S (1:1) were observed, and the results are shown in Tables 6-1 and 6-2. In the tables, for the shape of the resist pattern after development, “good” means that no major defects were found in the formed resist patterns each having a line width of 55 nm L/S (1:1) and 80 nm L/S (1:1), and “poor” means that major defects were found in the formed resist pattern having either line width. In the tables, “resolution” is the minimum line width with no pattern collapse and good rectangularity, and “sensitivity” indicates the minimum amount of electron beam energy capable of forming a good pattern shape.

### Comparative Example X2 and Comparative Example Y2

The same operations were carried out except that no underlayer film was formed so that a photoresist layer was formed directly on a SiO₂ substrate to obtain a positive type resist pattern. The results are shown in Tables 6-1 and 6-2.

TABLE 6-1

| | Underlayer | | | Shape of resist |
|---|---|---|---|---|
| | film forming | Resolution | Sensitivity | pattern |
| | material | (nmL/S) | (μC/cm²) | after development |
| Example X4 | Example X | 55 | 10 | good |
| | 1-1 | | | |
| Example X5 | Example X | 55 | 10 | good |
| | 1-2 | | | |
| Example X6 | Example X | 55 | 10 | good |
| | 2-1 | | | |
| Example X7 | Example X | 55 | 10 | good |
| | 2-2 | | | |
| Example X8 | Example X | 55 | 10 | good |
| | 3-1 | | | |
| Example X9 | Example X | 55 | 10 | good |
| | 3-2 | | | |
| Comparative | | 80 | 26 | poor |
| Example X2 | | | | |

TABLE 6-2

| | Underlayer | | | Shape of resist |
|---|---|---|---|---|
| | film forming | Resolution | Sensitivity | pattern |
| | material | (nmL/S) | (μC/cm²) | after development |
| Example Y5 | Example Y | 55 | 10 | good |
| | 1-1 | | | |
| Example Y6 | Example Y | 55 | 10 | good |
| | 1-2 | | | |
| Example Y7 | Example Y | 55 | 10 | good |
| | 2-1 | | | |
| Example Y8 | Example Y | 55 | 10 | good |
| | 2-2 | | | |
| Example Y9 | Example Y | 55 | 10 | good |
| | 3-1 | | | |
| Example Y10 | Example Y | 55 | 10 | good |
| | 3-2 | | | |
| Example Y11 | Example Y | 55 | 10 | good |
| | 4-1 | | | |
| Example Y11 | Example Y | 55 | 10 | good |
| | 4-2 | | | |
| Comparative | — | 80 | 26 | poor |
| Example Y2 | | | | |

### Examples X10 to X14 and Examples Y13 to Y20

A SiO₂ substrate with a film thickness of 300 nm was coated with each solution of the underlayer film forming material for lithography prepared in the same manner as in each of Examples X1-1 to X3-2 and Examples Y1-1 to Y4-2, and baked at 240° C. for 60 seconds and further at 400° C. for 120 seconds to form each underlayer film with a film thickness of 80 nm. This underlayer film was coated with a silicon-containing intermediate layer material and baked at 200° C. for 60 seconds to form an intermediate layer film with a film thickness of 35 nm. This intermediate layer film was further coated with the above resist solution for ArF and baked at 130° C. for 60 seconds to form a photoresist layer with a film thickness of 150 nm. The silicon-containing intermediate layer material used was the silicon atom-containing polymer described in <Synthesis Example 1> of Japanese Patent Laid-Open No. 2007-226170. Subsequently, the photoresist layer was mask exposed using an electron beam lithography system (manufactured by ELIONIX INC.; ELS-7500, 50 keV), baked (PEB) at 115° C. for 90 seconds, and developed for 60 seconds in a 2.38 mass % tetramethylammonium hydroxide (TMAH) aqueous solution to obtain a 55 nm L/S (1:1) positive type resist pattern. Then, the silicon-containing intermediate layer film (SOG) was dry etched with the obtained resist pattern as a mask using RIE-10NR manufactured by Samco International, Inc. Subsequently, dry etching of the underlayer film with the obtained silicon-containing intermediate layer film pattern as a mask and dry etching of the SiO₂ film with the obtained underlayer film pattern as a mask were performed in order.

Respective etching conditions are as shown below.

Conditions for etching of resist intermediate layer film with resist pattern
Output: 50 W
Pressure: 20 Pa
Time: 1 min
Etching gas
Ar gas flow rate:CF₄ gas flow rate:O₂ gas flow rate=50:8:2 (sccm)
Conditions for etching of resist underlayer film with resist intermediate film pattern
Output: 50 W
Pressure: 20 Pa
Time: 2 min
Etching gas
Ar gas flow rate:CF₄ gas flow rate:O₂ gas flow rate=50:5:5 (sccm)
Conditions for etching of SiO₂ film with resist underlayer film pattern
Output: 50 W
Pressure: 20 Pa
Time: 2 min
Etching gas
Ar gas flow rate:C₅F₁₂ gas flow rate:C₂F₆ gas flow rate:O₂ gas flow rate=50:4:3:1 (sccm)

### [Evaluation]

The pattern cross section (that is, the shape of the SiO₂ film after etching) obtained as described above was observed by using a product manufactured by Hitachi, Ltd., “electron microscope (S-4800)”. The results are shown in Tables 7-1 and 7-2. In the table, “good” means that no major defects were found in the formed pattern cross section, and “poor” means that major defects were found in the formed pattern cross section.

TABLE 7-1

| | Underlayer film | | |
|---|---|---|---|
| | forming material | Shape of SiO₂ film | Appearance |
| Example X10 | Example X | rectangular | good |
| | 1-1 | | |
| Example X11 | Example X | rectangular | good |
| | 1-2 | | |
| Example X12 | Example X | rectangular | good |
| | 2-1 | | |
| Example X13 | Example X | rectangular | good |
| | 2-2 | | |
| Example X14 | Example X | rectangular | good |
| | 3-1 | | |
| Example X15 | Example X | rectangular | good |
| | 3-2 | | |

TABLE 7-2

| | Underlayer film | | |
|---|---|---|---|
| | forming material | Shape of SiO₂ film | Appearance |
| Example Y13 | Example Y | rectangular | good |
| | 1-1 | | |
| Example Y14 | Example Y | rectangular | good |
| | 1-2 | | |
| Example Y15 | Example Y | rectangular | good |
| | 2-1 | | |
| Example Y16 | Example Y | rectangular | good |
| | 2-2 | | |
| Example Y17 | Example Y | rectangular | good |
| | 3-1 | | |
| Example Y18 | Example Y | rectangular | good |
| | 3-2 | | |
| Example Y19 | Example Y | rectangular | good |
| | 4-1 | | |
| Example Y20 | Example Y | rectangular | good |
| | 4-2 | | |

### <Evaluation of Etching Defects on Laminated Film>

The obtained oligomer obtained in Synthesis Working Example was subjected to quality evaluation before and after the purification treatment. That is, the evaluation was carried out by transferring the resin film formed on a wafer using the solution of the underlayer film forming material for lithography prepared in the same manner as in each of Examples X1-1 to X3-2 and Examples Y1-1 to Y4-2 by etching to the substrate side, and then subjecting it to evaluation of defects.

A 12-inch silicon wafer was subjected to thermal oxidation treatment to obtain a substrate having a silicon oxide film having a thickness of 100 nm. The solution of the underlayer film forming material for lithography was formed on the substrate by adjusting the spin coating conditions so as to have a thickness of 100 nm, followed by baking at 150° C. for 1 minute, and then baking at 350° C. for 1 minute to prepare a laminated substrate laminated on silicon with a thermal oxide film.

Using TELIUS (manufactured by Tokyo Electron Limited) as an etching apparatus, the resin film was etched under the condition of CF₄/O₂/Ar to expose the substrate on the surface of the oxide film. Further, an etching treatment was performed under the condition that the oxide film was etched by 100 nm at the gas composition ratio of CF₄/Ar to prepare an etched wafer.

The prepared etched wafer was measured for the number of defects of 19 nm or more with a defect inspection device SP5 (manufactured by KLA-tencor), and was subjected to defect evaluation by etching treatment of the laminated film.
A: number of defects≤20
B: 20≤number of defects≤50
C: 50≤number of defects≤100
D: 100≤number of defects≤1,000
E: 1,000≤number of defects≤5,000
F: 5,000≤number of defects

### [Example XE01] Purification of Resin XA with Acid

In a four necked flask (capacity: 1000 mL, with a detachable bottom), 150 g of a solution (10% by mass) formed by dissolving the resin XA obtained in Synthesis Working Example X1 in PGMEA was charged, and was heated to 80° C. with stirring. Then, 37.5 g of an aqueous oxalic acid solution (pH 1.3) was added thereto, and the resultant mixture was stirred for 5 minutes and then left to stand still for 30 minutes. This separated the mixture into an oil phase and an aqueous phase, and the aqueous phase was thus removed. After repeating this operation once, 37.5 g of ultrapure water was charged to the obtained oil phase, and after stirring for 5 minutes, the mixture was left to stand for 30 minutes and the aqueous phase was removed. After repeating this operation three times, the residual water and PGMEA were concentrated and removed by heating to 80° C. and reducing the pressure in the flask to 200 hPa or less. Then, by diluting with PGMEA of EL grade (a reagent manufactured by Kanto Chemical Co., Inc.) such that the concentration of the PGMEA solution was adjusted to 10% by mass, a PGMEA solution of the resin XA with a reduced metal content was obtained. The resin solution thus prepared was filtered with a UPE filter having a nominal pore size of 3 nm, manufactured by Entegris Japan Co., Ltd., under a condition of 0.5 MPa, to prepare a solution sample, and then etching defect evaluation on the laminated film was carried out.

### [Example XE02] Purification 1 of Resin XA by Passing Through Filter

In a class 1000 clean booth, 500 g of a solution of 10% by mass concentration of the resin XA obtained in Synthesis Working Example X1 dissolved in propylene glycol monomethyl ether (PGME) was charged in a four necked flask (capacity: 1000 mL, with a detachable bottom), and then the air inside the flask was depressurized and removed, nitrogen gas was introduced to return it to atmospheric pressure, and the oxygen concentration inside was adjusted to less than 1% under the ventilation of 100 mL of nitrogen gas per minute, and the flask was heated to 30° C. with stirring. The solution was drawn out from the bottom-vent valve, and passed through a pressure tube made of fluororesin through a diaphragm pump at a flow rate of 100 mL per minute to a hollow fiber membrane filter (manufactured by KITZ MICRO FILTER CORPORATION, product name: Polyfix Nylon Series) made of nylon with a nominal pore size of 0.01 μm under a filtration pressure of 0.5 MPa by pressure filtration. By diluting the resin solution after filtration with PGMEA of EL grade (a reagent manufactured by Kanto Chemical Co., Inc.) such that the concentration of the PGMEA solution was adjusted to 10% by mass, a PGMEA solution of resin XA with a reduced metal content was obtained. The resin solution thus prepared was filtered with a UPE filter having a nominal pore size of 3 nm, manufactured by Entegris Japan Co., Ltd., under a condition of 0.5 MPa, to prepare a solution sample, and then etching defect evaluation on the laminated film was carried out. The oxygen concentration was measured with an oxygen concentration meter “OM-25MF10” manufactured by AS ONE Corporation (the same applies hereinafter).

### [Example XE03] Purification 2 of Resin XA by Passing Through Filter

As the purification step by the filter, IONKLEEN manufactured by Pall Corporation, a nylon filter manufactured by Pall Corporation, and a UPE filter with a nominal pore size of 3 nm manufactured by Entegris Japan Co., Ltd. were connected in series in this order to construct a filter line. In the same manner as in Example XE02, except that the prepared filter line was used instead of the 0.1 μm hollow fiber membrane filter made of nylon, the solution was passed by pressure filtration so that the condition of the filtration pressure was 0.5 MPa. By diluting with PGMEA of EL grade (a reagent manufactured by Kanto Chemical Co., Inc.) such that the concentration of the PGMEA solution was adjusted to 10% by mass, a PGMEA solution of the resin XA with a reduced metal content was obtained. The resin solution thus prepared was subjected to pressure filtration with a UPE filter having a nominal pore size of 3 nm, manufactured by Entegris Japan Co., Ltd., under a condition of the filtration pressure of 0.5 MPa, to prepare a solution sample, and then etching defect evaluation on the laminated film was carried out.

### Examples XE04 to XE09 and Examples YE01 to YE12

For the resin XB to resin XC and resin YA to resin YD prepared in Synthesis Working Examples X2 to X3 and Y1 to Y4, a solution sample purified by the same method as in Exampled XE01 to XE03 was prepared, and then an etching defect evaluation on the laminated film was carried out.

TABLE 8-1

| | Resin used | Oxide film |
|---|---|---|
| Example XE01 | Resin XA | A |
| Example XE02 | | A |
| Example XE03 | | A |
| Example XE04 | Resin XB | A |
| Example XE05 | | A |
| Example XE06 | | A |
| Example XE07 | Resin XC | A |
| Example XE08 | | A |
| Example XE09 | | A |

TABLE 8-2

| | Resin used | Oxide film |
|---|---|---|
| Example YE01 | Resin YA | A |
| Example YE02 | | A |
| Example YE03 | | A |
| Example YE04 | Resin YB | A |
| Example YE05 | | A |
| Example YE06 | | A |
| Example YE07 | Resin YC | A |
| Example YE08 | | A |
| Example YE09 | | A |
| Example YE10 | Resin YD | A |
| Example YE11 | | A |
| Example YE12 | | A |

### (Synthetic Example Z1) Synthesis of PBIF-AL

Into a four-necked flask equipped with a discharging spout at the lower part, phenol (311.9 g, 3.32 mol, manufactured by Tokyo Kasei Kogyo Co., Ltd.) and 4,4′-dichloromethylbiphenyl (200.0 g, 0.80 mol, manufactured by Tokyo Kasei Kogyo Co., Ltd.)) were fed under nitrogen. Subsequently, with rising temperature, the inside of the system became homogeneous at 80° C. and generation of HCl was started. The temperature was kept at 100° C. for 3 hours, and the mixture was further subjected to heat treatment at 150° C. for 1 hour. HCl generated in a reaction was volatilized to the outside as it is and trapped in alkaline water. At this stage, there was no residue of unreacted 4,4′-dichloromethylbiphenyl and it was confirmed by gas chromatography that all of them was reacted. After completion of the reaction, HCl and unreacted phenol remained in the system were removed to the outside of the system by reducing the pressure. Eventually, the pressure reduction treatment was performed at 30 torr to 150° C., whereby residual phenol became not detected by gas chromatography. While keeping this reaction product at 150° C., about 30 g of the reaction product was slowly added dropwise from the discharging spout at the lower part of the flask onto a stainless steel pad, the temperature of which was kept at room temperature by air cooling. The reaction product was quickly cooled to 30° C. in 1 minute on the stainless steel pad to obtain a solidified polymer. For preventing the surface temperature of the stainless steel pad from rising due to the heat of the polymer, the solid was removed and the stainless steel pad was cooled by air cooling. This air cooling and solidifying operation was repeated nine times. Subsequently, to remove impurities, 1-butanol (300 g per 100 g of the polymer) and toluene (600 g per 100 g of the polymer) were added to the polymer and dissolved. The solution was transferred into a separatory funnel, and the organic layer was washed twice with a 0.5% aqueous sodium hydroxide solution (250 g per 100 g of the polymer) and back extracted with a 8% aqueous sodium hydroxide solution (200 g per 100 g of the polymer). Ethyl acetate (400 g per 100 g of the polymer) and 20% sulfuric acid (108 g per 100 g of the polymer) were added thereto, followed by extraction and washing twice with pure water (200 g per 100 g of the polymer). Then, the organic solvent was removed by concentration and drying to obtain 213.3 g of an oligomer (PBIF-AL) having a structural unit represented by the following formula. The weight average molecular weight of the obtained oligomer measured in terms of polystyrene by GPC was 3100, and the dispersibility was 1.33. The viscosity was 0.06 Pa·s, and the softening point was 39° C.

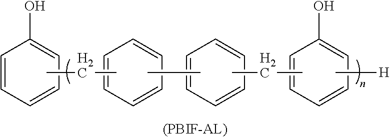

### (Synthesis Working Example Z1) Synthesis of M6-PBIF-AL

To a container (internal capacity: 200 ml) equipped with a stirrer, a condenser tube, and a burette, 5.0 g of PBIF-AL, 7.56 g (54.7 mmol) of potassium carbonate, and 20 mL of dimethylformamide were fed, and 4.92 g (54.6 mmol) of dimethyl carbonate was further added. The reaction solution was stirred at 120° C. for 14 hours and reacted. Then, 10 ml of 1% HCl aqueous solution and 20 ml of ethyl acetate were added into the container, and subsequently, the aqueous layer was removed by liquid separation. Then, the organic solvent was removed by concentration, followed by drying to obtain 5.1 g of an oligomer (M6-PBIF-AL) having a structural unit represented by the following formula. The weight average molecular weight of the obtained oligomer measured in terms of polystyrene by GPC was 2800, and the dispersibility was 1.31.

¹H-NMR measurement was performed on the obtained oligomer. The peak near 3.7-3.8 ppm indicating the methyl group was confirmed in an amount of 1.5 times the peak near 9.1-9.4 ppm indicating the phenolic hydroxy group, in terms of chemical amount, and 60% of the hydroxyl groups before reaction were found to be protected by methyl groups. The viscosity was 0.01 Pa·s, and the softening point was 25° C.

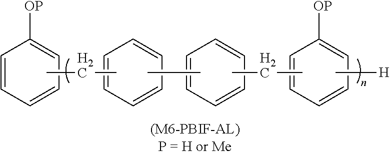

### (Synthetic Example Z2) Synthesis of p-CBIF-AL

Into a four-necked flask equipped with a discharging spout at the lower part, p-cresol (359.0 g, 3.32 mol, manufactured by Tokyo Kasei Kogyo Co., Ltd.) and 4,4′-dichloromethylbiphenyl (200.0 g, 0.80 mol, manufactured by Tokyo Kasei Kogyo Co., Ltd.)) were fed under nitrogen. Subsequently, with rising temperature, the inside of the system became homogeneous at 80° C. and generation of HCl was started. The temperature was kept at 100° C. for 3 hours, and the mixture was further subjected to heat treatment at 150° C. for 1 hour. HCl generated in a reaction was volatilized to the outside as it is and trapped in alkaline water. At this stage, there was no residue of unreacted 4,4′-dichloromethylbiphenyl and it was confirmed by gas chromatography that all of them was reacted. After completion of the reaction, HCl and unreacted phenol remained in the system were removed to the outside of the system by reducing the pressure. Eventually, the pressure reduction treatment was performed at 30 torr to 150° C., whereby residual phenol became not detected by gas chromatography. While keeping this reaction product at 150° C., about 30 g of the reaction product was slowly added dropwise from the discharging spout at the lower part of the flask onto a stainless steel pad, the temperature of which was kept at room temperature by air cooling. The reaction product was quickly cooled to 30° C. in 1 minute on the stainless steel pad to obtain a solidified polymer. For preventing the surface temperature of the stainless steel pad from rising due to the heat of the polymer, the solid was removed and the stainless steel pad was cooled by air cooling. This air cooling and solidifying operation was repeated nine times. Subsequently, to remove impurities, 1-butanol (300 g per 100 g of the polymer) and toluene (600 g per 100 g of the polymer) were added to the polymer and dissolved. The solution was transferred into a separatory funnel, and the organic layer was washed twice with a 0.5% aqueous sodium hydroxide solution (250 g per 100 g of the polymer) and back extracted with a 8% aqueous sodium hydroxide solution (200 g per 100 g of the polymer). Ethyl acetate (400 g per 100 g of the polymer) and 20% sulfuric acid (108 g per 100 g of the polymer) were added thereto, followed by extraction and washing twice with pure water (200 g per 100 g of the polymer). Then, the organic solvent was removed by concentration and drying to obtain 223.1 g of an oligomer (p-CBIF-AL) having a structural unit represented by the following formula. The weight average molecular weight of the obtained oligomer measured in terms of polystyrene by GPC was 2556, and the dispersibility was 1.21. The viscosity was 0.03 Pa·s, and the softening point was 35° C.

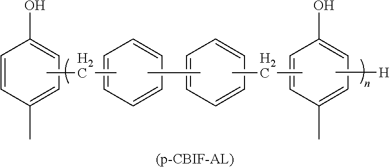

### (Synthesis Working Example Z2) Synthesis of B-p-CBIF-AL

To a container (internal capacity: 200 ml) equipped with a stirrer, a condenser tube, and a burette, 5.0 g of p-CBIF-AL, 0.768 g (6.84 mmol) of tert-butoxypotassium and 20 mL of tetrahydrofuran were fed, and 8.97 g (41.1 mmol) of di-tert-butyl dicarbonate was further added. The reaction solution was stirred at 40° C. for 2 hours and reacted. Then, 10 ml of H₂O and 20 ml of ethyl acetate were added into the container, and subsequently, the aqueous layer was removed by liquid separation. Then, the organic solvent was removed by concentration, and the reaction solution was added dropwise to hexane. Subsequently, the hexane was removed, followed by drying to obtain 5.3 g of an oligomer (B-p-CBIF-AL) having a structural unit represented by the following formula. The weight average molecular weight of the obtained oligomer measured in terms of polystyrene by GPC was 2500, and the dispersibility was 1.23.

¹H-NMR measurement was performed on the obtained oligomer. The peak near 9.1-9.4 ppm indicating the phenolic hydroxy group was not confirmed, and 100% of the hydroxyl groups before reaction were found to be protected by t-BOC groups (tert-butoxycarbonyl groups). The viscosity was 0.02 Pa·s, and the softening point was 29° C.

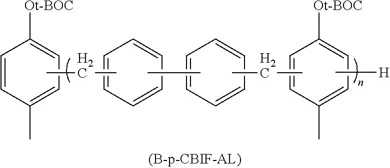

### (Synthetic Example Z3) Synthesis of n-BBIF-AL

Into a four-necked flask equipped with a discharging spout at the lower part, 4-butylphenol (498.7 g, 3.32 mol, manufactured by Tokyo Kasei Kogyo Co., Ltd.) and 4,4′-dichloromethylbiphenyl (200.0 g, 0.80 mol, manufactured by Tokyo Kasei Kogyo Co., Ltd.)) were fed under nitrogen. Subsequently, with rising temperature, the inside of the system became homogeneous at 80° C. and generation of HCl was started. The temperature was kept at 100° C. for 3 hours, and the mixture was further subjected to heat treatment at 150° C. for 1 hour. HCl generated in a reaction was volatilized to the outside as it is and trapped in alkaline water. At this stage, there was no residue of unreacted 4,4′-dichloromethylbiphenyl and it was confirmed by gas chromatography that all of them was reacted. After completion of the reaction, HCl and unreacted phenol remained in the system were removed to the outside of the system by reducing the pressure. Eventually, the pressure reduction treatment was performed at 30 torr to 150° C., whereby residual phenol became not detected by gas chromatography. While keeping this reaction product at 150° C., about 30 g of the reaction product was slowly added dropwise from the discharging spout at the lower part of the flask onto a stainless steel pad, the temperature of which was kept at room temperature by air cooling. The reaction product was quickly cooled to 30° C. in 1 minute on the stainless steel pad to obtain a solidified polymer. For preventing the surface temperature of the stainless steel pad from rising due to the heat of the polymer, the solid was removed and the stainless steel pad was cooled by air cooling. This air cooling and solidifying operation was repeated nine times. Subsequently, to remove impurities, 1-butanol (300 g per 100 g of the polymer) and toluene (600 g per 100 g of the polymer) were added to the polymer and dissolved. The solution was transferred into a separatory funnel, and the organic layer was washed twice with a 0.5% aqueous sodium hydroxide solution (250 g per 100 g of the polymer) and back extracted with a 8% aqueous sodium hydroxide solution (200 g per 100 g of the polymer). Ethyl acetate (400 g per 100 g of the polymer) and 20% sulfuric acid (108 g per 100 g of the polymer) were added thereto, followed by extraction and washing twice with pure water (200 g per 100 g of the polymer). Then, the organic solvent was removed by concentration and drying to obtain 267.5 g of an oligomer (n-BBIF-AL) having a structural unit represented by the following formula. The weight average molecular weight of the obtained oligomer measured in terms of polystyrene by GPC was 2349, and the dispersibility was 1.19. The viscosity was 0.02 Pa·s, and the softening point was 25° C.

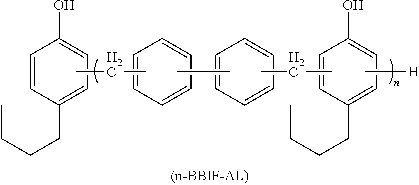

### (Synthesis Working Example Z3) Synthesis of E-n-BBIF-AL

To a container (internal capacity: 200 ml) equipped with a stirrer, a condenser tube, and a burette, 5.0 g of n-BBIF-AL, 1.73 g (6.9 mmol) of pyridinium p-toluenesulfonate, and 20 mL of methylene chloride were fed, and 2.36 g (27.4 mmol) of propylvinyl ether was further added. The reaction solution was stirred at 40° C. for 2 hours and reacted. Then, 10 ml of 10% aqueous sodium carbonate solution and 20 ml of ethyl acetate were added into the container, and subsequently, the aqueous layer was removed by liquid separation. Then, the organic solvent was removed by concentration, followed by drying to obtain 5.0 g of an oligomer (E-n-BBIF-AL) having a structural unit represented by the following formula. The weight average molecular weight of the obtained oligomer measured in terms of polystyrene by GPC was 2200, and the dispersibility was 1.20.

¹H-NMR measurement was performed on the obtained oligomer. The peak near 9.1-9.4 ppm indicating the phenolic hydroxy group was not confirmed, and 100% of the hydroxyl groups before reaction were found to be protected by EP groups (ethoxypropyl groups). The viscosity was 0.01 Pa·s, and the softening point was 20° C.

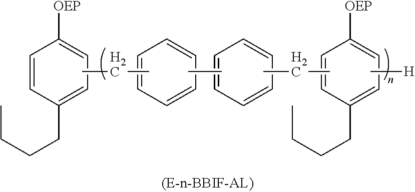

### (Synthetic Example Z4) Synthesis of NAFP-AL

To a 300 mL four necked flask, 1,4-bis(chloromethyl)benzene (28.8 g, 0.148 mol, manufactured by Tokyo Kasei Kogyo Co., Ltd.), 1-naphthol (30.0 g, 0.1368 mol, manufactured by Tokyo Kasei Kogyo Co., Ltd.), and para-toluenesulfonic acid monohydrate (5.7 g, 0.029 mol, manufactured by Tokyo Kasei Kogyo Co., Ltd.) were added under nitrogen, and 150.4 g of propylene glycol monomethyl ether acetate (hereinafter, abbreviated as PGMEA) was further fed into the mixture. Then, the mixture was stirred, and the temperature was raised to dissolve the mixture until reflux was confirmed, whereby polymerization was initiated. After 16 hours, the mixture was allowed to cool to 60° C. and then reprecipitated in 1600 g of methanol, and the obtained precipitate was filtered. Subsequently, to remove impurities, 1-butanol (300 g per 100 g of the polymer) and toluene (600 g per 100 g of the polymer) were added to the polymer and dissolved. The solution was transferred into a separatory funnel, and the organic layer was washed twice with a 0.5% aqueous sodium hydroxide solution (250 g per 100 g of the polymer) and back extracted with a 8% aqueous sodium hydroxide solution (200 g per 100 g of the polymer). Ethyl acetate (400 g per 100 g of the polymer) and 20% sulfuric acid (108 g per 100 g of the polymer) were added thereto, followed by extraction and washing twice with pure water (200 g per 100 g of the polymer). Then, the organic solvent was removed by concentration, followed by drying by a reduced pressure dryer at 60° C. for 16 hours to obtain 38.6 g of an oligomer (NAFP-AL) having a structural unit represented by the following formula (NAFP-AL). The weight average molecular weight of the obtained oligomer measured in terms of polystyrene by GPC was 2020, and the dispersibility was 1.86. The viscosity was 0.12 Pa·s, and the softening point was 68° C.

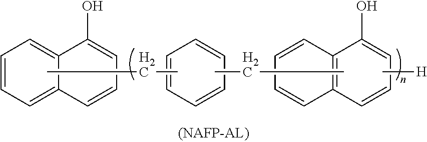

### (Synthesis Working Example Z4) Synthesis of Ms-NAFP-AL

To a container (internal capacity: 200 ml) equipped with a stirrer, a condenser tube, and a burette, 5.0 g of NAFP-AL, g (mmol) of triethylamine, and 20 mL of tetrahydrofuran were fed, and g (mmol) of mesyl chloride was further added. The reaction solution was stirred at room temperature for 2 hours and reacted. Then, 10 ml of H₂O and 20 ml of ethyl acetate were added into the container, and subsequently, the aqueous layer was removed by liquid separation. Then, the organic solvent was removed by concentration, followed by drying to obtain 5.3 g of an oligomer (Ms-NAFP-AL) having a structural unit represented by the following formula. The weight average molecular weight of the obtained oligomer measured in terms of polystyrene by GPC was 1900, and the dispersibility was 1.70.

¹H-NMR measurement was performed on the obtained oligomer. The peak near 9.1-9.4 ppm indicating the phenolic hydroxy group was not confirmed, and 100% of the hydroxyl groups before reaction were found to be protected by Ms groups (mesyl groups). The viscosity was 0.09 Pa·s, and the softening point was 56° C.

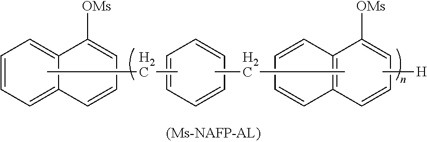

(Synthetic Example Z5) Synthesis of p-PBIF-AL

Into a four-necked flask equipped with a discharging spout at the lower part, 4-phenylphenol (565.1 g, 3.32 mol, manufactured by Tokyo Kasei Kogyo Co., Ltd.) and 4,4′-dichloromethylbiphenyl (200.0 g, 0.80 mol, manufactured by Tokyo Kasei Kogyo Co., Ltd.)) were fed under nitrogen. Subsequently, with rising temperature, the inside of the system became homogeneous at 80° C. and generation of HCl was started. The temperature was kept at 100° C. for 3 hours, and the mixture was further subjected to heat treatment at 150° C. for 1 hour. HCl generated in a reaction was volatilized to the outside as it is and trapped in alkaline water. At this stage, there was no residue of unreacted 4,4′-dichloromethylbiphenyl and it was confirmed by gas chromatography that all of them was reacted. After completion of the reaction, HCl and unreacted 4-phenylphenol remained in the system were removed to the outside of the system by reducing the pressure. Eventually, the pressure reduction treatment was performed at 30 torr to 180° C., whereby residual phenol became not detected by gas chromatography. While keeping this reaction product at 150° C., about 30 g of the reaction product was slowly added dropwise from the discharging spout at the lower part of the flask onto a stainless steel pad, the temperature of which was kept at room temperature by air cooling. The reaction product was quickly cooled to 30° C. in 1 minute on the stainless steel pad to obtain a solidified polymer. For preventing the surface temperature of the stainless steel pad from rising due to the heat of the polymer, the solid was removed and the stainless steel pad was cooled by air cooling. This air cooling and solidifying operation was repeated nine times. Subsequently, to remove impurities, 1-butanol (300 g per 100 g of the polymer) and toluene (600 g per 100 g of the polymer) were added to the polymer and dissolved. The solution was transferred into a separatory funnel, and the organic layer was washed twice with a 0.5% aqueous sodium hydroxide solution (250 g per 100 g of the polymer) and back extracted with a 8% aqueous sodium hydroxide solution (200 g per 100 g of the polymer). Ethyl acetate (400 g per 100 g of the polymer) and 20% sulfuric acid (108 g per 100 g of the polymer) were added thereto, followed by extraction and washing twice with pure water (200 g per 100 g of the polymer). Then, the organic solvent was removed by concentration and drying to obtain 267.5 g of an oligomer (p-PBIF-AL) having a structural unit represented by the following formula. The weight average molecular weight of the obtained oligomer measured in terms of polystyrene by GPC was 2349, and the dispersibility was 1.19. The viscosity was 0.10 Pa·s, and the softening point was 48° C.

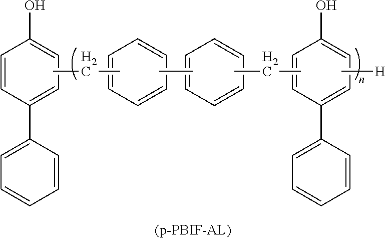

### (Synthesis Working Example Z5) Synthesis of Ac-p-PBIF-AL

To a container (internal capacity: 200 ml) equipped with a stirrer, a condenser tube, and a burette, 5.0 g of p-PBIF-AL, 0.693 g (6.90 mmol) of triethylamine, and 20 mL of tetrahydrofuran were fed, and 2.80 g (27.4 mmol) of acetic anhydride was further added. The reaction solution was stirred at 40° C. for 2 hours and reacted. Then, 10 ml of 1% HCl aqueous solution and 20 ml of ethyl acetate were added into the container, and subsequently, the aqueous layer was removed by liquid separation. Then, the organic solvent was removed by concentration, followed by drying to obtain 5.1 g of an oligomer (Ac-p-PBIF-AL) having a structural unit represented by the following formula. The weight average molecular weight of the obtained oligomer measured in terms of polystyrene by GPC was 2250, and the dispersibility was 1.24.

¹H-NMR measurement was performed on the obtained oligomer. The peak near 9.1-9.4 ppm indicating the phenolic hydroxy group was not confirmed, and 100% of the hydroxyl groups before reaction were found to be protected by Ac groups (acetyl groups). The viscosity was 0.01 Pa·s, and the softening point was 18° C.

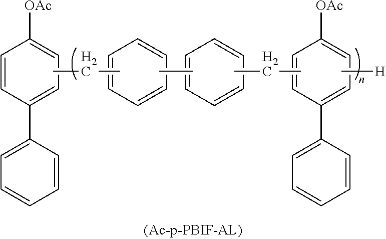

### (Synthetic Example Z6) Synthesis of MPF-AL

Into a four-necked flask equipped with a discharging spout at the lower part, phenol (311.9 g, 3.32 mol, manufactured by Tokyo Kasei Kogyo Co., Ltd.) and 1,4-bis(chloromethyl)benzene (140.0 g, 0.80 mol, manufactured by Tokyo Kasei Kogyo Co., Ltd.)) were fed under nitrogen. Subsequently, with rising temperature, the inside of the system became homogeneous at 80° C. and generation of HCl was started. The temperature was kept at 100° C. for 3 hours, and the mixture was further subjected to heat treatment at 150° C. for 1 hour. HCl generated in a reaction was volatilized to the outside as it is and trapped in alkaline water. At this stage, there was no residue of unreacted 4,4′-dichloromethylbenzene and it was confirmed by gas chromatography that all of them was reacted. After completion of the reaction, HCl and unreacted phenol remained in the system were removed to the outside of the system by reducing the pressure. Eventually, the pressure reduction treatment was performed at 30 torr to 150° C., whereby residual phenol became not detected by gas chromatography. While keeping this reaction product at 150° C., about 30 g of the reaction product was slowly added dropwise from the discharging spout at the lower part of the flask onto a stainless steel pad, the temperature of which was kept at room temperature by air cooling. The reaction product was quickly cooled to 30° C. in 1 minute on the stainless steel pad to obtain a solidified polymer. For preventing the surface temperature of the stainless steel pad from rising due to the heat of the polymer, the solid was removed and the stainless steel pad was cooled by air cooling. This air cooling and solidifying operation was repeated nine times to obtain 267.5 g of an oligomer (MPF-AL) having a structural unit represented by the following formula. The weight average molecular weight of the obtained oligomer measured in terms of polystyrene by GPC was 980, and the dispersibility was 1.12. The viscosity was 0.02 Pa·s, and the softening point was 42° C.

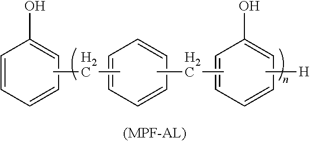

### (Synthesis Working Example Z6) Synthesis of tB-MPF-AL

To a container (internal capacity: 200 ml) equipped with a stirrer, a condenser tube, and a burette, 5.0 g of MPF-AL, 1.73 g (6.9 mmol) of pyridinium p-toluenesulfonate, and 20 mL of tetrahydrofuran were fed, and 10.2 g (27.4 mmol) of isobutene (ca. 15% tetrahydrofuran solution) was further added. The reaction solution was stirred at room temperature for 6 hours and reacted. Then, 10 ml of 10% aqueous sodium carbonate solution and 20 ml of ethyl acetate were added into the container, and subsequently, the aqueous layer was removed by liquid separation. Then, the organic solvent was removed by concentration, followed by drying to obtain 4.9 g of an oligomer (tB-MPF-AL) having a structural unit represented by the following formula. The weight average molecular weight of the obtained oligomer measured in terms of polystyrene by GPC was 900, and the dispersibility was 1.09.

¹H-NMR measurement was performed on the obtained oligomer. The peak near 9.1-9.4 ppm indicating the phenolic hydroxy group was not confirmed, and 100% of the hydroxyl groups before reaction were found to be protected by t-Bu groups (tert-butyl groups). The viscosity was 0.01 Pa·s, and the softening point was 17° C.

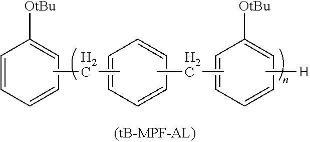

### Examples Z1 to 6 and Comparative Example Z1

For the aralkyl oligomers having the above protecting groups and the phenol novolac resin (PSM4357 manufactured by Gunei Chemical Industry Co., Ltd.) as Comparative Example Z1, the solubility test and heat resistance evaluation shown below were carried out. The results are shown in Table 9.

(Evaluation of solubility)

At 23° C., the oligomer of the present embodiment was dissolved in propylene glycol monomethyl ether acetate (PGMEA) to form a 10 mass % solution. Subsequently, the solubility after leaving the solution to stand still at 10° C. for 30 days was evaluated according to the following criteria.
Evaluation A: no precipitate was visually confirmed
Evaluation C: precipitates were visually confirmed

### (Evaluation of Heat Resistance)

EXSTAR 6000 TG-DTA apparatus manufactured by SII NanoTechnology Inc. was used. About 5 mg of a sample was placed in an unsealed container made of aluminum, and the temperature was raised to 500° C. at a temperature increase rate of 10° C./min in a nitrogen gas stream (300 ml/min), thereby measuring the amount of thermogravimetric weight loss. From a practical viewpoint, evaluation A or B described below is preferable.

### <Evaluation Criteria>

A: The amount of thermogravimetric weight loss at 400° C. is less than 10%
B: The amount of thermogravimetric weight loss at 400° C. is 10% to 25%
C: The amount of thermogravimetric weight loss at 400° C. is greater than 25%

### Examples Z1-1 to 6-3 and Comparative Example Z1-1

Next, underlayer film forming compositions for lithography were each prepared according to the composition shown in Table 10-1 and Table 10-2. Next, a silicon substrate was spin coated with each of these underlayer film forming compositions for lithography, and then baked at 240° C. for 60 seconds and further at 400° C. for 120 seconds to prepare each underlayer film with a film thickness of 200 nm. Subsequently, curing properties were evaluated by the following evaluation criteria.

### [Curing Property Test]

Each underlayer film obtained from the underlayer film forming compositions for lithography of Examples Z1-1 to 6-3 and Comparative Example Z1-1 was immersed in PGMEA for 120 seconds and then dried at 110° C. for 60 seconds on a hot plate, and the state of each remaining film was confirmed. The results are shown in Table 10-1 and Table 10-2.

<Evaluation Criteria>
A: A remaining film was visually observed
C: No remaining film was visually observed

The following acid generating agent, crosslinking agent, and organic solvent were used.

Acid generating agent: a product manufactured by Midori Kagaku Co., Ltd., “di-tertiary butyl diphenyliodonium nonafluoromethanesulfonate” (in the table, designated as “DTDPI”)
Acid generating agent: pyridinium p-toluenesulfonate (in the table, designated as “PPTS”)
Crosslinking agent: a product manufactured by Sanwa Chemical Co., Ltd., “NIKALAC MX270” (in the table, designated as “NIKALAC”)
   a product manufactured by Honshu Chemical Industry Co., Ltd., “TMOM-BP” (in the table, designated as “TMOM”)
Organic solvent: PGMEA/PGME=9:1
   PGMEA: propylene glycol monomethyl ether acetate (PGMEA)
   PGME: 1-methoxy-2-propanol

For each of the obtained underlayer films, etching test was carried out under the following conditions to evaluate etching resistance. The evaluation results are shown in Table 10-1 and Table 10-2.

### [Etching Test]

Etching apparatus: a product manufactured by Samco International, Inc., “RIE-10NR”
Output: 50 W
Pressure: 20 Pa
Time: 2 min
Etching gas
Ar gas flow rate:CF₄ gas flow rate:O₂ gas flow rate=50:5:5 (sccm)

### [Evaluation of Etching Resistance]

The evaluation of etching resistance was carried out by the following procedures.

First, an underlayer film containing a phenol novolac resin was prepared under the same conditions as in Example Z1-1 except that a phenol novolac resin (PSM4357 manufactured by Gunei Chemical Industry Co., Ltd.) was used instead of the oligomer used in Example Z1-1. Then, the above etching test was carried out for this underlayer film containing a phenol novolac resin, and the etching rate (etching speed) was measured. Next, for each of the underlayer films of Examples and Comparative Example, the above etching test was carried out, and the etching rate was measured. Then, the etching resistance for each of Examples and Comparative Example was evaluated according to the following evaluation criteria on the basis of the etching rate of the underlayer film containing a phenol novolac resin.

### <Evaluation Criteria>

S: The etching rate was less than −15% as compared with the underlayer film of novolac.
A: The etching rate was less than −10% as compared with the underlayer film of novolac.
B: The etching rate was −10% to +5% as compared with the underlayer film of novolac.
C: The etching rate was more than +5% as compared with the underlayer film of novolac.

### [Evaluation of Embedding Properties to Uneven Substrate]

The embedding properties to an uneven substrate were evaluated by the following procedures.

A SiO₂ substrate having a film thickness of 80 nm and a line and space pattern of 60 nm was coated with a composition for underlayer film formation for lithography, and baked at 400° C. for 60 seconds to form a 90 nm underlayer film. The cross section of the obtained film was cut out and observed under an electron microscope to evaluate the embedding properties to an uneven substrate. The results are shown in Table 11-1 and Table 11-2.

### <Evaluation Criteria>

A: The underlayer film was embedded without defects in the asperities of the SiO₂ substrate having a line and space pattern of 60 nm.
C: The underlayer film not was embedded with defects in the asperities of the SiO₂ substrate having a line and space pattern of 60 nm.

### [Evaluation of Flatness]

Onto a SiO₂ substrate having difference in level on which trenches with a width of 100 nm, a pitch of 150 nm, and a depth of 150 nm (aspect ratio: 1.5) and trenches with a width of 5 μm and a depth of 180 nm (open space) were mixedly present, each of the obtained compositions for film formation was coated. Subsequently, it was calcined at 400° C. for 120 seconds under the air atmosphere to form a resist underlayer film having a film thickness of 200 nm. The shape of this resist underlayer film was observed with a scanning electron microscope (“S-4800” from Hitachi High-Technologies Corporation), and the difference between the maximum value and the minimum value of the film thickness of the resist underlayer film on the trench or space (ΔFT) was measured. The results are shown in Table 11-1 and Table 11-2.

### <Evaluation Criteria>

S: ΔFT<10 nm (best flatness)
A: 10 nm≤ΔFT<20 nm (good flatness)
B: 20 nm≤ΔFT<40 nm (partially good flatness)
C: 40 nm≤ΔFT (poor flatness)

TABLE 9

| | Compound | Evaluation | Evaluation |
|---|---|---|---|
| | or resin | of | of heat |
| | (parts by mass) | solubility | resistance |
| Example Z1 | M6-PBIF-AL | A | B |
| | (10) | | |
| Example Z2 | B-p-CBIF-AL | A | B |
| | (10) | | |
| Example Z3 | E-n-BBIF-AL | A | B |
| | (10) | | |
| Example Z4 | Ms-NAFP-AL | A | A |
| | (10) | | |
| Example Z5 | Ac-p-PBIF-AL | A | A |
| | (10) | | |
| Example Z6 | tB-MPF-AL | A | B |
| | (10) | | |
| Comparative | Phenol novolac resin | A | C |
| Example Z1 | (10) | | |

TABLE 10-1

| | | | Acid | | | |
|---|---|---|---|---|---|---|
| | | Crosslinking | generating | | | |
| | | agent | agent | | | |
| | Resin | (parts by | (parts by | Solvent | Curing | Etching |
| | (parts by mass) | mass) | mass) | (parts by mass) | property | resistance |
| Example Z | M6-PBIF-AL | — | — | PGMEA/PGME = 9:1 | A | B |
| 1-1 | (10) | | | (10) | | |
| Example Z | M6-PBIF-AL | NIKALAC(0.5) | PPTS | PGMEA/PGME = 9:1 | A | B |
| 1-2 | (10) | | (0.5) | (10) | | |
| Example Z | M6-PBIF-AL | TMOM(0.5) | PPTS | PGMEA/PGME = 9:1 | A | B |
| 1-3 | (10) | | (0.5) | (10) | | |
| Example Z | B-p-CBIF-AL | — | — | PGMEA/PGME = 9:1 | A | A |
| 2-1 | (10) | | | (10) | | |
| Example Z | B-p-CBIF-AL | NIKALAC(0.5) | DTDP | PGMEA/PGME = 9:1 | A | B |
| 2-2 | (10) | | (0.5) | (10) | | |
| Example Z | B-p-CBIF-AL | TMOM(0.5) | PPTS | PGMEA/PGME = 9:1 | A | B |
| 2-3 | (10) | | (0.5) | (10) | | |
| Example Z | E-n-BBIF-AL(10) | — | — | PGMEA/PGME = 9:1 | A | B |
| 3-1 | | | | (10) | | |
| Example Z | E-n-BBIF-AL(10) | NIKALAC(0.5) | DTDPI | PGMEA/PGME = 9:1 | A | B |
| 3-2 | | | (0.5) | (10) | | |
| Example Z | E-n-BBIF-AL(10) | TMOM(0.5) | PPTS | PGMEA/PGME = 9:1 | A | B |
| 3-3 | | | (0.5) | (10) | | |
| Comparative | Phenol | — | — | PGMEA/PGME = 9:1 | C | — |
| Example Z | novolac resin | | | (10) | | |
| 1-1 | (10) | | | | | |

TABLE 10-2

| | | | Acid | | | |
|---|---|---|---|---|---|---|
| | | Crosslinking | generating | | | |
| | | agent | agent | | | |
| | Resin | (parts by | (parts by | Solvent | Curing | Etching |
| | (parts by mass) | mass) | mass) | (parts by mass) | property | resistance |
| Example Z | Ms-NAFP-AL | — | — | PGMEA/PGME = 9:1 | A | S |
| 4-1 | (10) | | | (10) | | |
| Example Z | Ms-NAFP-AL | NIKALAC(0.5) | PPTS | PGMEA/PGME = 9:1 | A | A |
| 4-2 | (10 | | (0.5) | (10) | | |
| Example Z | Ms-NAFP-AL | TMOM(0.5) | DTDPI | PGMEA/PGME = 9:1 | A | A |
| 4-3 | (10) | | (0.5) | (10) | | |
| Example Z | Ac-p-PBIF-AL | — | — | PGMEA/PGME = 9:1 | A | A |
| 5-1 | (10) | | | (10) | | |
| Example Z | Ac-p-PBIF-AL | NIKALAC(0.5) | DTDPI | PGMEA/PGME = 9:1 | A | B |
| 5-2 | (10) | | (0.5) | (10) | | |
| Example Z | Ac-p-PBIF-AL | TMOM(0.5) | PPTS | PGMEA/PGME = 9:1 | A | B |
| 5-3 | (10) | | (0.5) | (10) | | |
| Example Z | tB-MPF-AL | — | — | PGMEA/PGME = 9:1 | A | A |
| 6-1 | (10) | | | (10) | | |
| Example Z | tB-MPF-AL | NIKALAC(0.5) | DTDPI | PGMEA/PGME = 9:1 | A | B |
| 6-2 | (10) | | (0.5) | (10) | | |
| Example Z | tB-MPF-AL | TMOM(0.5) | PPTS | PGMEA/PGME = 9:1 | A | B |
| 6-3 | (10) | | (0.5) | (10) | | |
| Comparative | Phenol | — | — | PGMEA/PGME = 9:1 | C | — |
| Example Z | novolac resin | | | (10) | | |
| 1-1 | (10) | | | | | |

TABLE 11-1

| | | | Acid | | | |
|---|---|---|---|---|---|---|
| | | Crosslinking | generating | | | |
| | | agent | agent | | | |
| | Resin | (parts by | (parts by | Solvent | Curing | Etching |
| | (parts by mass) | mass) | mass) | (parts by mass) | property | resistance |
| Example Z | M6-PBIF-AL | — | — | PGMEA/PGME = 9:1 | A | S |
| 1-1 | (10) | | | (10) | | |
| Example Z | M6-PBIF-AL | NIKALAC(0.5) | PPTS | PGMEA/PGME = 9:1 | A | A |
| 1-2 | (10) | | (0.5) | (10) | | |
| Example Z | M6-PBIF-AL | TMOM(0.5) | PPTS | PGMEA/PGME = 9:1 | A | S |
| 1-3 | (10) | | (0.5) | (10) | | |
| Example Z | B-p-CBIF-AL | — | — | PGMEA/PGME = 9:1 | A | A |
| 2-1 | (10) | | | (10) | | |
| Example Z | B-p-CBIF-AL | NIKALAC(0.5) | DTDPI | PGMEA/PGME = 9:1 | A | B |
| 2-2 | (10) | | (0.5) | (10) | | |
| Example Z | B-p-CBIF-AL | TMOM(0.5) | PPTS | PGMEA/PGME = 9:1 | A | A |
| 2-3 | (10) | | (0.5) | (10) | | |
| Example Z | E-n-BBIF- | — | — | PGMEA/PGME = 9:1 | A | A |
| 3-1 | AL(10) | | | (10) | | |
| Example Z | E-n-BBIF- | NIKALAC(0.5) | DTDPI | PGMEA/PGME = 9:1 | A | A |
| 3-2 | AL(10) | | (0.5) | (10) | | |
| Example Z | E-n-BBIF- | TMOM(0.5) | PPTS | PGMEA/PGME = 9:1 | A | A |
| 3-3 | AL(10) | | (0.5) | (10) | | |
| Comparative | Phenol | — | — | PGMEA/PGME = 9:1 | C | — |
| Example Z | novolac resin | | | (10) | | |
| 1-1 | (10) | | | | | |

TABLE 11-2

| | | | Acid | | | |
|---|---|---|---|---|---|---|
| | | Crosslinking | generating | | | |
| | | agent | agent | | | |
| | Resin | (parts by | (parts by | Solvent | Embedding | |
| | (parts by mass) | mass) | mass) | (parts by mass) | property | Flatness |
| Example Z | Ms-NAFP-AL | — | — | PGMEA/PGME = 9:1 | A | B |
| 4-1 | (10) | | | (10) | | |
| Example Z | Ms-NAFP-AL | NIKALAC(0.5) | PPTS | PGMEA/PGME = 9:1 | A | B |
| 4-2 | (10) | | (0.5) | (10) | | |
| Example Z | Ms-NAFP-AL | TMOM(0.5) | DTDPI | PGMEA/PGME = 9:1 | A | B |
| 4-3 | (10) | | (0.5) | (10) | | |
| Example Z | Ac-p-PBIF-AL | — | — | PGMEA/PGME = 9:1 | A | A |
| 5-1 | (10) | | | (10) | | |
| Example Z | Ac-p-PBIF-AL | NIKALAC(0.5) | DTDPI | PGMEA/PGME = 9:1 | A | A |
| 5-2 | (10) | | (0.5) | (10) | | |
| Example Z | Ac-p-PBIF-AL | TMOM(0.5) | PPTS | PGMEA/PGME = 9:1 | A | S |
| 5-3 | (10) | | (0.5) | (10) | | |
| Example Z | tB-MPF-AL | — | — | PGMEA/PGME = 9:1 | A | S |
| 6-1 | (10) | | | (10) | | |
| Example Z | tB-MPF-AL | NIKALAC(0.5) | DTDPI | PGMEA/PGME = 9:1 | A | A |
| 6-2 | (10) | | (0.5) | (10) | | |
| Example Z | tB-MPF-AL | TMOM(0.5) | PPTS | PGMEA/PGME = 9:1 | A | S |
| 6-3 | (10) | | (0.5) | (10) | | |
| Comparative | Phenol | — | — | PGMEA/PGME = 9:1 | C | — |
| Example Z | novolac resin | | | (10) | | |
| 1-1 | (10) | | | | | |

### Examples Z4 to 9

A SiO₂ substrate with a film thickness of 300 nm was coated with the solution of the underlayer film forming material for lithography prepared in each of the above Examples Z1-1 to 6-3, and baked at 240° C. for 60 seconds and further at 400° C. for 120 seconds to form each underlayer film with a film thickness of 70 nm. This underlayer film was coated with a resist solution for ArF and baked at 130° C. for 60 seconds to form a photoresist layer with a film thickness of 140 nm. The ArF resist solution used was prepared by compounding 5 parts by mass of a compound represented by the formula (11) given below, 1 part by mass of triphenylsulfonium nonafluoromethanesulfonate, 2 parts by mass of tributylamine, and 92 parts by mass of PGMEA. For the compound represented by the formula (11) given below, 4.15 g of 2-methyl-2-methacryloyloxyadamantane, 3.00 g of methacryloyloxy-γ-butyrolactone, 2.08 g of 3-hydroxy-1-adamantyl methacrylate, and 0.38 g of azobisisobutyronitrile were dissolved in 80 mL of tetrahydrofuran to prepare a reaction solution. This reaction solution was polymerized for 22 hours with the reaction temperature kept at 63° C. in a nitrogen atmosphere. Then, the reaction solution was added dropwise into 400 mL of n-hexane. The product resin thus obtained was solidified and purified, and the resulting white powder was filtered and dried overnight at 40° C. under reduced pressure to obtain a compound represented by the following formula.

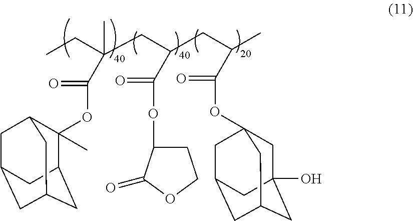

The numbers in the above formula (11) indicate the ratio of each constitutional unit.

Subsequently, the photoresist layer was exposed using an electron beam lithography system (manufactured by ELIONIX INC.; ELS-7500, 50 keV), baked (PEB) at 115° C. for 90 seconds, and developed for 60 seconds in a 2.38 mass % tetramethylammonium hydroxide (TMAH) aqueous solution to obtain a positive type resist pattern.

Defects of the obtained resist patterns of 55 nm L/S (1:1) and 80 nm L/S (1:1) were observed, and the results are shown in Table 12. In the table, “good” means that no major defects were found in the formed resist pattern, and “poor” means that major defects were found in the formed resist pattern.

### Comparative Example Z2

The same operations as in Example Z7 were carried out except that no underlayer film was formed so that a photoresist layer was formed directly on a SiO₂ substrate to obtain a positive type resist pattern. The results are shown in Table 12.

TABLE 12

| | Underlayer film | Resolution | Sensitivity | Shape of resist pattern |
|---|---|---|---|---|
| | forming material | (nmL/S) | (HC/cm²) | after development |
| Example Z4 | Example Z1-1 | 55 | 10 | good |
| Example Z5 | Example Z1-2 | 55 | 10 | good |
| Example Z6 | Example Z1-3 | 55 | 10 | good |
| Example Z7 | Example Z2-1 | 55 | 10 | good |
| Example Z8 | Example Z2-2 | 55 | 10 | good |
| Example Z9 | Example Z2-3 | 55 | 10 | good |
| Example Z10 | Example Z3-1 | 55 | 10 | good |
| Example Z11 | Example Z3-2 | 55 | 10 | good |
| Example Z12 | Example Z3-3 | 55 | 10 | good |
| Example Z13 | Example Z4-1 | 55 | 10 | good |
| Example Z14 | Example Z4-2 | 55 | 10 | good |
| Example Z15 | Example Z4-3 | 55 | 10 | good |
| Example Z16 | Example Z5-1 | 55 | 10 | good |
| Example Z17 | Example Z5-2 | 55 | 10 | good |
| Example Z18 | Example Z5-3 | 55 | 10 | good |
| Example Z19 | Example Z6-1 | 55 | 10 | good |
| Example Z20 | Example Z6-2 | 55 | 10 | good |
| Example Z21 | Example Z6-3 | 55 | 10 | good |
| Comparative | — | 80 | 26 | poor |
| Example Z2 | | | | |

As is evident from Table 9, Examples Z1 to 6 using any of the oligomers having an aralkyl structure of the present embodiment were confirmed to be good in terms of any of solubility and heat resistance. On the other hand, in Comparative Example Z1 using the phenol novolac resin was poor in heat resistance.

As is evident from Table 10-1 and Table 10-2 as well as Table 11-1 and Table 11-2, the underlayer film formed using any of underlayer film forming compositions for lithography comprising an oligomer having an aralkyl structure of the present embodiment (Example Z1-1 to Example Z6-3) were confirmed to be not only excellent in curing properties and etching resistance, but also good in terms of both embedding properties and smoothing properties, as compared with the underlayer film comprising the phenol novolac resin of Comparative Example Z1-1. The underlayer film self-cures without the need for a crosslinking agent and an acid generating agent, so that it can express particularly excellent flatness.

As is evident from Table 12, Examples Z4 to 21 using any of the oligomers having an aralkyl structure of the present embodiment were confirmed to have a good resist pattern shape after development and have no major defects found. Further, each of Examples Z4 to 21 was confirmed to be significantly excellent in both resolution and sensitivity, as compared with Comparative Example Z2 which does not form an underlayer film. Here, a good resist pattern shape after development indicates that the underlayer film forming materials for lithography used in Examples Z4 to 21 have good adhesiveness to a resist material (photoresist material and the like).

### Examples Z22 to 39

A SiO₂ substrate with a film thickness of 300 nm was coated with each solution of the underlayer film forming materials for lithography of Examples Z1-1 to 6-3, and baked at 240° C. for 60 seconds and further at 400° C. for 120 seconds to form each underlayer film with a film thickness of 80 nm. This underlayer film was coated with a silicon-containing intermediate layer material and baked at 200° C. for 60 seconds to form an intermediate layer film with a film thickness of 35 nm. This intermediate layer film was further coated with the above resist solution for ArF and baked at 130° C. for 60 seconds to form a photoresist layer with a film thickness of 150 nm. The silicon-containing intermediate layer material used was the silicon atom-containing polymer described in <Synthesis Example Z1> of Japanese Patent Laid-Open No. 2007-226170. Subsequently, the photoresist layer was mask exposed using an electron beam lithography system (manufactured by ELIONIX INC.; ELS-7500, 50 keV), baked (PEB) at 115° C. for 90 seconds, and developed for 60 seconds in a 2.38 mass % tetramethylammonium hydroxide (TMAH) aqueous solution to obtain a 55 nm L/S (1:1) positive type resist pattern. Then, the silicon-containing intermediate layer film (SOG) was dry etched with the obtained resist pattern as a mask using RIE-10NR manufactured by Samco International, Inc. Subsequently, dry etching of the underlayer film with the obtained silicon-containing intermediate layer film pattern as a mask and dry etching of the SiO₂ film with the obtained underlayer film pattern as a mask were performed in order.

Respective etching conditions are as shown below.

Conditions for Etching of Resist Intermediate Layer Film with Resist Pattern
Output: 50 W
Pressure: 20 Pa
Time: 1 min
Etching gas
Ar gas flow rate:CF₄ gas flow rate:O₂ gas flow rate=50:8:2 (sccm)

Conditions for Etching of Resist Underlayer Film with Resist Intermediate Film Pattern
Output: 50 W
Pressure: 20 Pa
Time: 2 min
Etching gas
Ar gas flow rate:CF₄ gas flow rate:O₂ gas flow rate=50:5:5 (sccm)

Conditions for Etching of SiO₂ Film with Resist Underlayer Film Pattern
Output: 50 W
Pressure: 20 Pa
Time: 2 min
Etching gas
Ar gas flow rate:C₅F₁₂ gas flow rate:C₂F₆ gas flow rate:O₂ gas flow rate=50:4:3:1 (sccm)

### [Evaluation]

The pattern cross section (that is, the shape of the SiO₂ film after etching) obtained as described above was observed by using a product manufactured by Hitachi, Ltd., “electron microscope (S-4800)”. The observation results are shown in Table 13. In the table, “good” means that no major defects were found in the formed pattern cross section, and “poor” means that major defects were found in the formed pattern cross section.

TABLE 13

| | Underlayer film | Shape of SiO₂ | |
|---|---|---|---|
| | forming material | film | Appearance |
| Example | Example Z1-1 | rectangular | good |
| Z22 | | | |
| Example | Example Z1-2 | rectangular | good |
| Z23 | | | |
| Example | Example Z1-3 | rectangular | good |
| Z24 | | | |
| Example | Example Z2-1 | rectangular | good |
| Z25 | | | |
| Example | Example Z2-2 | rectangular | good |
| Z26 | | | |
| Example | Example Z2-3 | rectangular | good |
| Z27 | | | |
| Example | Example Z3-1 | rectangular | good |
| Z28 | | | |
| Example | Example Z3-2 | rectangular | good |
| Z29 | | | |
| Example | Example Z3-3 | rectangular | good |
| Z30 | | | |
| Example | Example Z4-1 | rectangular | good |
| Z31 | | | |
| Example | Example Z4-2 | rectangular | good |
| Z32 | | | |
| Example | Example Z4-3 | rectangular | good |
| Z33 | | | |
| Example | Example Z5-1 | rectangular | good |
| Z34 | | | |
| Example | Example Z5-2 | rectangular | good |
| Z35 | | | |
| Example | Example Z5-3 | rectangular | good |
| Z36 | | | |
| Example | Example Z6-1 | rectangular | good |
| Z37 | | | |
| Example | Example Z6-2 | rectangular | good |
| Z38 | | | |
| Example | Example Z6-3 | rectangular | good |
| Z39 | | | |

### (Example Z40) Purification of M6-PBIF-AL with Acid

In a four necked flask (capacity: 1000 mL, with a detachable bottom), 150 g of a solution (10% by mass) formed by dissolving M6-PBIF-AL obtained in Synthesis Working Example Z1 in EL-MIBK (methyl isobutyl ketone) was charged, and was heated to 80° C. with stirring. Then, 37.5 g of an aqueous oxalic acid solution (pH 1.3) was added thereto, and the resultant mixture was stirred for 5 minutes and then left to stand still for 30 minutes. This separated the mixture into an oil phase and an aqueous phase, and the aqueous phase was thus removed. After repeating this operation once, 37.5 g of ultrapure water was charged to the obtained oil phase, and after stirring for 5 minutes, the mixture was left to stand for 30 minutes and the aqueous phase was removed. After repeating this operation three times, PGMEA of EL grade (a reagent manufactured by Kanto Chemical Co., Inc.) was put therein, and the residual water and MIBK were concentrated and removed by heating to 80° C. and reducing the pressure in the flask to 100 hPa or less. Then, by diluting with PGMEA of EL grade (a reagent manufactured by Kanto Chemical Co., Inc.) such that the concentration of the PGMEA solution was adjusted to 10% by mass, a PGMEA solution of M6-PBIF-AL with a reduced metal content was obtained.

### (Example Z3) Purification of M6-PBIF-AL with Ultrapure Water

In the same manner as of Example Z40 except that ultrapure water was used instead of the aqueous oxalic acid solution, and by adjusting the concentration to 10% by mass, a PGMEA solution of M6-PBIF-AL was obtained.

For the 10 mass % PGMEA solution of M6-PBIF-AL before the treatment, and the solutions obtained in Example Z40 and Comparative Example Z3, the contents of various metals were measured by ICP-MS. The measurement results are shown in Table 14.

TABLE 14

| | Metal content (ppb) | | | | | |
|---|---|---|---|---|---|---|
| | Na | Mg | K | Fe | Cu | Zn |
| M6-PBIF-AL | >99 | 32.9 | >99 | >99 | 13.4 | 16.4 |
| before treatment | | | | | | |
| Example Z40 | 0.9 | 1.0 | 0.2 | 1.1 | 0.5 | 0.4 |
| Comparative | 2.2 | 1.1 | 1.4 | >99 | 2.8 | 3.9 |
| Example Z3 | | | | | | |

1. An underlayer film forming composition for lithography comprising a compound having a protecting group.

2. The underlayer film forming composition for lithography according to claim 1, wherein the compound comprises one or more selected from the group consisting of a polyphenol, an aniline-based compound, and a resin.

3. The underlayer film forming composition for lithography according to claim 1, wherein the compound comprises a compound and/or resin represented by the following formula (1): 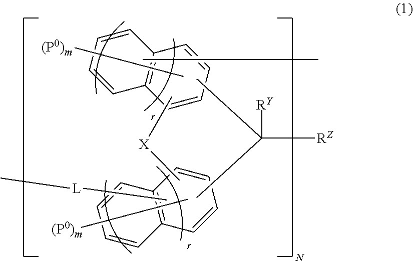
wherein
each R^{Y} is independently a hydrogen atom, a linear, branched, or cyclic alkyl group having 1 to 30 carbon atoms, or an aryl group having 6 to 30 carbon atoms;
R^{Z} is an N-valent group having 1 to 60 carbon atoms or a single bond;
each P⁰ is independently selected from the group consisting of a halogen atom, a nitro group, an alkyl group having 1 to 30 carbon atoms, an alkenyl group having 2 to 30 carbon atoms, an alkynyl group having 2 to 30 carbon atoms, an aryl group having 6 to 40 carbon atoms, a hydroxyl group, an amino group, a group obtained by replacing a hydrogen atom of a hydroxyl group with a protecting group, a group obtained by replacing a hydrogen atom of an amino group with a protecting group, and a functional group of a combination thereof, wherein at least one P⁰ is a group obtained by replacing a hydrogen atom of a hydroxyl group with a protecting group or a group obtained by replacing a hydrogen atom of an amino group with a protecting group, and the protecting group is optionally an eliminatable protecting group;
each X independently represents an oxygen atom or a sulfur atom, or not a crosslink;
L is a single bond, a linear or branched alkylene group having 1 to 30 carbon atoms and optionally having a substituent, or not a crosslink;
each m is independently an integer of 0 to 9,
wherein at least one m is an integer of 1 to 9;
N is an integer of 1 to 4; and
each r is independently an integer of 0 to 2.

4. The underlayer film forming composition for lithography according to claim 1, wherein the compound comprises a compound and/or resin represented by the following formula (2): 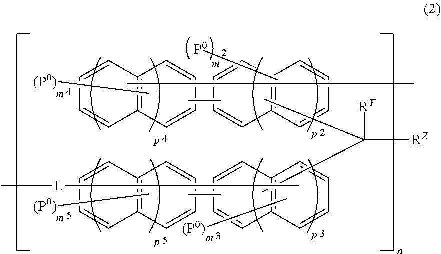
wherein
R^{Y}, R^{Z}, P⁰, and L are synonymous with the definition in the formula (1);
m² and m³ are each independently an integer of 0 to 8, and m⁴ and m⁵ are each independently an integer of 0 to 9, provided that m², m³, m⁴, and m⁵ are not 0 at the same time;
n is as defined in N in the formula (1), wherein when n is an integer of 2 or larger, structural formulas within n parentheses [ ] are the same or different; and
p² to p⁵ are as defined in r in the formula (1).

5. The underlayer film forming composition for lithography according to claim 1, wherein the compound comprises a compound and/or resin represented by the following formula (3): 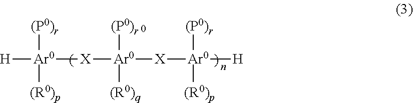
wherein
each P⁰ is independently selected from the group consisting of a halogen atom, a nitro group, an alkyl group having 1 to 30 carbon atoms, an alkenyl group having 2 to 30 carbon atoms, an alkynyl group having 2 to 30 carbon atoms, an aryl group having 6 to 40 carbon atoms, a hydroxyl group, an amino group, a group obtained by replacing a hydrogen atom of a hydroxyl group with a protecting group, a group obtained by replacing a hydrogen atom of an amino group with a protecting group, and a functional group of a combination thereof, wherein at least one P⁰ is a group obtained by replacing a hydrogen atom of a hydroxyl group with a protecting group or a group obtained by replacing a hydrogen atom of an amino group with a protecting group, and the protecting group is optionally an eliminatable protecting group;
each Ar⁰ independently represents a phenylene group, a naphthylene group, an anthrylene group, a phenanthrylene group, a pyrylene group, a fluorirene group, a biphenylene group, a diphenylmethylene group, or a terphenylene group;
R⁰ is a substituent on Ar⁰, and each R⁰ is independently the same or different groups and represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group;
X represents a linear or branched alkylene group or an oxygen atom;
n represents an integer of 0 to 500;
each r independently represents an integer of 1 to 3;
r⁰ represents an integer of 0 to 2;
each p independently represents a positive integer; and
q represents a positive integer.

6. The underlayer film forming composition for lithography according to claim 5, wherein the compound and/or resin represented by the formula (3) is represented by the following formula (3-1A) or the following formula (3-1B): 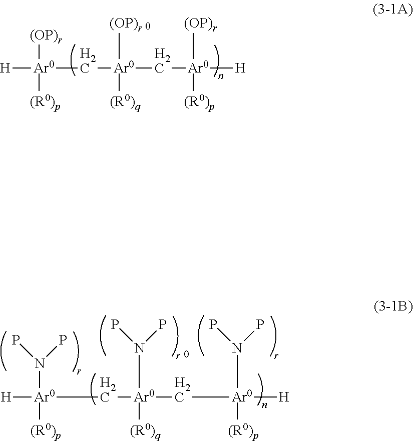
wherein Ar⁰, R⁰, p, q, r, r⁰, and n are synonymous with the definition in the formula (3); and
each P is independently a hydrogen atom or a protecting group, wherein at least one P is the protecting group, and the protecting group is optionally an eliminatable protecting group.

7. The underlayer film forming composition for lithography according to claim 6, wherein the compound and/or resin represented by the formula (3-1A) or the formula (3-1B) is represented by the following formula (3-2A) or the following formula (3-2B): 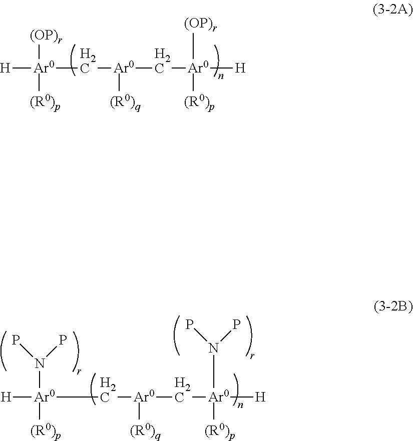
wherein Ar⁰, P, R⁰, p, q, r, and n are synonymous with the definition in the formula (3-1A) or the formula (3-1B).

8. The underlayer film forming composition for lithography according to claim 5, wherein the compound and/or resin represented by the following formula (3) is represented by the following formula (3-10A) or the following formula (3-10B): 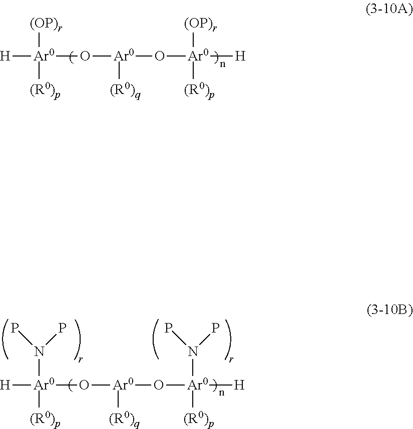
wherein Ar⁰, R⁰, p, q, r, and n are synonymous with the definition in the formula (3); and
each P is independently a hydrogen atom or a protecting group, wherein at least one P is a protecting group, and the protecting group is optionally an eliminatable protecting group.

9. The underlayer film forming composition for lithography according to claim 5, wherein the compound and/or resin represented by the following formula (3) is represented by the following formula (3-11A) or the following formula (3-11B): 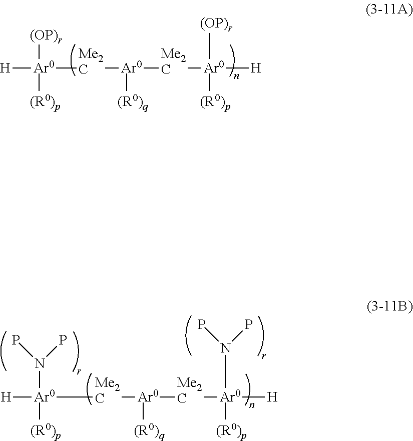
wherein Ar⁰, R⁰, p, q, r, and n are synonymous with the definition in the formula (3); and
each P is independently a hydrogen atom or a protecting group, wherein at least one P is a protecting group, and the protecting group is optionally an eliminatable protecting group.

10. The underlayer film forming composition for lithography according to claim 1, wherein the protecting group is an electron-withdrawing protecting group that reduces the electron density at a specific position in a molecule by an inductive effect or a resonance effect; and
the electron-withdrawing protecting group is one or more selected from the group consisting of a carbonyl-based protecting group, a sulfonyl-based protecting group, and an acyl-based protecting group.

11. The underlayer film forming composition for lithography according to claim 10, wherein the electron-withdrawing protecting group is one or more selected from the group consisting of a substituted or unsubstituted alkylcarbonyl group having 2 to 20 carbon atoms, a substituted or unsubstituted arylcarbonyl group having 6 to 20 carbon atoms, a substituted or unsubstituted alkoxycarbonyl group having 2 to 20 carbon atoms, a substituted or unsubstituted alkylsulfonyl group having 1 to 10 carbon atoms, a substituted or unsubstituted arylsulfonyl group having 6 to 20 carbon atoms, and a substituted or unsubstituted acyl group having 2 to 13 carbon atoms.

12. The underlayer film forming composition for lithography according to claim 10, wherein the electron-withdrawing protecting group is one or more selected from the group consisting of an acetyl group, a trifluoroacetyl group, a benzoyl group, a mesyl group, a nosyl group, and a triflate group.

13. The underlayer film forming composition for lithography according to claim 1, wherein the protecting group is an electron-donating protecting group that increases the electron density at a specific position in a molecule by an inductive effect or a resonance effect; and
the electron-donating protecting group is one or more selected from the group consisting of an alkyl-based protecting group, a benzyl-based protecting group, an acetal-based protecting group, a trityl-based protecting group, a silyl-based protecting group, and a glycidyl group.

14. The underlayer film forming composition for lithography according to claim 13, wherein the electron-donating protecting group is one or more selected from the group consisting of a substituted or unsubstituted alkyl group having 1 to 20 carbon atoms, a substituted or unsubstituted benzyl group having 7 to 20 carbon atoms, a substituted or unsubstituted alkoxyalkyl group having 2 to 20 carbon atoms, a substituted or unsubstituted tetrahydropyranyl group having 2 to 20 carbon atoms, a substituted or unsubstituted alkylthioalkyl group having 2 to 20 carbon atoms, a substituted or unsubstituted trityl group having 19 to 30 carbon atoms, a substituted or unsubstituted silyl group having 3 to 20 carbon atoms, and a glycidyl group.

15. The underlayer film forming composition for lithography according to claim 13, wherein the electron-donating protecting group is one or more selected from the group consisting of a methyl group, a tert-butyl group, a normal hexyl group, an octyl group, an ethoxyethyl group, an ethoxypropyl group, and a glycidyl group.

16. The underlayer film forming composition for lithography according to claim 1, wherein the compound has a weight average molecular weight of 500 to 10,000.

17. The underlayer film forming composition for lithography according to claim 1, wherein a weight ratio of a low molecular weight component having a molecular weight of less than 500 is less than 1% in the compound.

18. The underlayer film forming composition for lithography according to claim 1, further comprising an acid generating agent.

19. The underlayer film forming composition for lithography according to claim 1, further comprising a crosslinking agent.

20. The compound and/or resin used in the underlayer film forming composition for lithography according to claim 1.

21. An underlayer film for lithography obtained by using the underlayer film forming composition for lithography according to claim 1.

22. A method for forming a resist pattern comprising the steps of:
forming an underlayer film on a substrate using the underlayer film forming composition for lithography according to claim 1;
forming at least one photoresist layer on the underlayer film; and
irradiating a predetermined region of the photoresist layer with radiation for development.

23. A method for forming a circuit pattern, comprising the steps of:
forming an underlayer film on a substrate using the underlayer film forming composition for lithography according to claim 1;
forming an intermediate layer film on the underlayer film using a resist intermediate layer film material containing a silicon atom;
forming at least one photoresist layer on the intermediate layer film;
irradiating a predetermined region of the photoresist layer with radiation for development, thereby forming a resist pattern;
etching the intermediate layer film with the resist pattern as a mask;
etching the underlayer film with the obtained intermediate layer film pattern as an etching mask; and
etching the substrate with the obtained underlayer film pattern as an etching mask, thereby forming a pattern on the substrate.

24. A method for forming an underlayer film for lithography, comprising a step of applying the underlayer film forming composition for lithography according to claim 1 to an uneven substrate.

25. The formation method according to claim 24, wherein the underlayer film forming composition for lithography has a viscosity of 0.01 to 1.00 Pa·s.

26. The formation method according to claim 24, wherein the underlayer film forming composition for lithography has a softening point of −50 to 100° C.
